(19) United States
(12) Patent Application Publication
(10) Pub. No.: US 2014/0183463 A1
(43) Pub. Date: Jul. 3, 2014

(54) CONDENSED CYCLIC COMPOUND AND ORGANIC LIGHT-EMITTING DEVICE COMPRISING THE SAME

(71) Applicant: Samsung Display Co., Ltd., Yongin-City (KR)

(72) Inventors: Eun-Young Lee, Yongin-City (KR); Seok-Hwan Hwang, Yongin-City (KR); Young-Kook Kim, Yongin-City (KR); Hye-Jin Jung, Yongin-City (KR); Jun-Ha Park, Yongin-City (KR); Jin-O Lim, Yongin-City (KR); Sang-Hyun Han, Yongin-City (KR); Eun-Jae Jeong, Yongin-City (KR); Soo-Yon Kim, Yongin-City (KR); Jong-Hyuk Lee, Yongin-City (KR)

(73) Assignee: SAMSUNG DISPLAY CO., LTD., Yongin-City (KR)

(21) Appl. No.: 13/972,861

(22) Filed: Aug. 21, 2013

(30) Foreign Application Priority Data
Dec. 31, 2012 (KR) 10-2012-0158525

(51) Int. Cl. H01L 51/00; H01L 51/50

(52) U.S. Cl. CPC H01L 51/0058; H01L 51/50; H01L 51/0067; H01L 51/0074; H01L 51/0072; H01L 51/0094
USPC 257/40; 570/129; 546/285; 549/43; 568/632; 548/446; 556/489; 546/255; 544/180; 585/27

(57) ABSTRACT

A condensed cyclic compound is represented by Formula 1, and an organic light-emitting device includes the condensed cyclic compound.

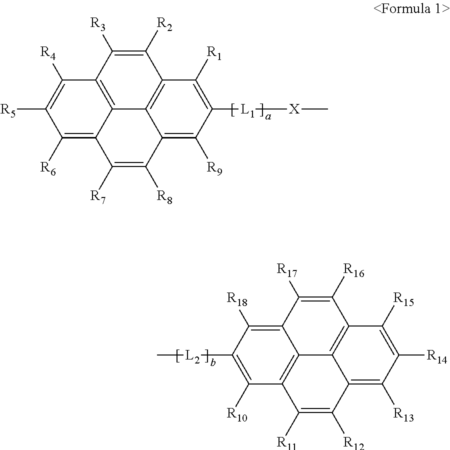

The organic light-emitting device may include an organic layer containing the condensed-cyclic compound of Formula 1 and has low driving voltage, high emission efficiency, and long lifespan characteristics.

### CROSS-REFERENCE TO RELATED APPLICATION

This application claims priority to and the benefit of Korean Patent Application No. 10-2012-0158525, filed on Dec. 31, 2012 in the Korean Intellectual Property Office, the entire content of which is incorporated herein by reference.

### BACKGROUND

1. Technical Field

One or more embodiments of the present invention relate to a condensed cyclic compound and an organic light-emitting device including the condensed cyclic compound,

2. Description of the Related Art

Organic light-emitting devices (OLEDs) are self-emitting devices, having advantages such as wide viewing angles, good contrast, quick response speeds, high brightness, and good driving voltage characteristics. Additionally, OLEDs can provide multicolored images.

A typical OLED has a structure including a substrate, and an anode, a hole transport layer (HTL), an emission layer (EML), an electron transport layer (ETL), and a cathode are sequentially stacked on the substrate. In this regard, the HTL, the EML, and the ETL are organic thin films formed of organic compounds.

An operating principle of an OLED having the above-described structure is as follows. When a voltage is applied between the anode and the cathode, holes injected from the anode move to the EML via the HTL, and electrons injected from the cathode move to the EML via the ETL. The holes and electrons recombine in the EML to generate excitons. When the excitons drop from an excited state to a ground state, light is emitted.

Therefore, there has been a demand for the development of novel materials for organic light-emitting devices with high luminance, high efficiency, and long lifetime.

### SUMMARY

One or more embodiments of the present invention include a novel condensed cyclic compound for organic light-emitting devices having low voltage, high luminance, high efficiency, high color purity, and long lifetime. Embodiments of the present invention are directed to an organic light-emitting device having an organic layer containing the condensed cyclic compound.

Additional aspects will be set forth in part in the description which follows and, in part, will be apparent from the description, or may be learned by practice of the presented embodiments.

According to one or more embodiments of the present invention, a condensed cyclic compound is represented by Formula 1 below.

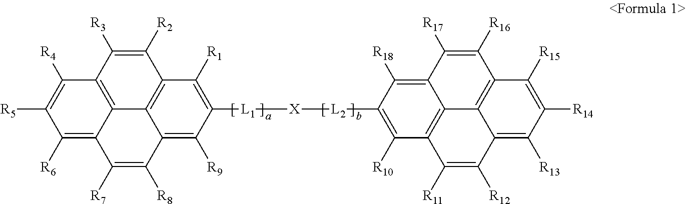

In Formula 1, X is one of a silylene group, a substituted or unsubstituted C₆-C₆₀ arylene group, or a substituted or unsubstituted C₃-C₆₀ heteroarylene group. L₁ and L₂ are each independently one of a substituted or unsubstituted C₆-C₆₀ arylene group, or a substituted or unsubstituted C₃-C₆₀ heteroarylene group. a is an integer from 0 to 2, and when a is 2, the L₁s may be identical to or different from each other. b is an integer from 0 to 2, and when b is 2, the L₂s may be identical to or different from each other. R₁ to R₁₈ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀, cycloalkyl group, a substituted or unsubstituted cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, —Si(R₂₁)(R₂₂)(R₂₃), or —N(R₂₄)(R₂₅), where R₂₁ to R₂₅ are each independently a substituted or unsubstituted C₁-C₆₀ alkyl group, a substituted or unsubstituted C₆-C₆₀ aryl group, or a substituted or unsubstituted C₂-C₆₀ heteroaryl group.

According to one or more embodiments of the present invention, an organic light-emitting device includes: a substrate; a first electrode on the substrate; a second electrode facing the first electrode; and an organic layer between the first electrode and the second electrode. The organic layer includes at least one layer, and includes at least one of the condensed cyclic compounds described above.

### BRIEF DESCRIPTION OF THE DRAWING

These and/or other aspects will become apparent and more readily appreciated from the following description of the embodiments, taken in conjunction with the accompanying drawing in which:

FIG. 1 schematically illustrates the structure of an organic light-emitting device according to an embodiment of the present invention.

### DETAILED DESCRIPTION

Reference will now be made to certain embodiments, examples of which are illustrated in the accompanying drawings, where like reference numerals refer to like elements throughout. In this regard, the disclosed embodiments may have different forms and should not be construed as being limited to the descriptions set forth herein. Accordingly, the embodiments are merely described below with reference to the figures, to explain aspects of the present description. As used herein, the term “and/or” includes any and all combinations of one or more of the associated listed items. Expressions such as “at least one of” when preceding a list of elements, modify the entire list of elements and do not modify the individual elements of the list.

According to an embodiment of the present invention, a condensed cyclic compound is represented by Formula 1 below.

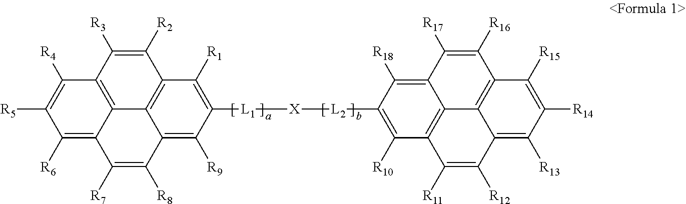

in Formula 1, X is one of a silylene group, a substituted or unsubstituted C₆-C₆₀ arylene group, or a substituted or unsubstituted C₃-C₆₀ heteroarylene group. L₁ and L₂ are each independently one of a substituted or unsubstituted C₆-C₆₀ arylene group, or a substituted or unsubstituted C₃-C₆₀ heteroarylene group, a is an integer from 0 to 2, and when a is 2, the L₁s are identical to or different from each other. b is an integer from 0 to 2, and when b is 2, the L₂s are identical to or different from each other. R₁ to R₁₈ are each independently a hydrogen atom, a deuterium atom, a halogen atom, a hydroxyl group, a cyano group, a nitro group, an amino group, an amidino group, a hydrazine, a hydrazone, a carboxyl group or, a salt thereof, a sulfonic acid group or a salt thereof, a phosphoric acid group or a salt, thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, —Si(R₂₁)(R₂₂)(R₂₃), or —N(R₂₄)(R₂₅), where R₂₁ to R₂₅ are each independently a substituted or unsubstituted C₁-C₆₀ alkyl group, a substituted or unsubstituted C₆-C₆₀) aryl group, or a substituted or unsubstituted C₂-C₆₀ heteroaryl group.

In some embodiments, X in Formula 1 may be a silylene group, a substituted or unsubstituted phenylene group, a substituted or unsubstituted naphthylene group, a substituted or unsubstituted phenanthrenylene group, a substituted or unsubstituted phenalenylene group, a substituted or unsubstituted pyrenylene group, a substituted or unsubstituted chrysenylene group, a substituted or unsubstituted anthrylene group, a substituted or unsubstituted pentalenylene group, a substituted or unsubstituted indenylene group, a substituted or unsubstituted azulenylene group, a substituted or unsubstituted heptalenylene group, a substituted or unsubstituted indacenylene group, a substituted or unsubstituted acenaphthylene group, a substituted or unsubstituted fluoranthenylene group, a substituted or unsubstituted triphenylenylene group, a substituted or unsubstituted naphthacenylene group, a substituted or unsubstituted picenylene group, a substituted or unsubstituted perylenylene group, a substituted or unsubstituted pentaphenylene group, a substituted or unsubstituted hexacenylene group, a substituted or unsubstituted fluorenylene group, a substituted or unsubstituted spiro-fluorenylene group, a substituted or unsubstituted carbazolylene group, a substituted or unsubstituted dibenzopuranylene group, a substituted or unsubstituted dibenzothiophenylene group, a substituted or unsubstituted pyridylene group, a substituted or unsubstituted pyridazinylene group, a substituted or unsubstituted triazinylene group, a substituted or unsubstituted pyrrolylene group, a substituted or unsubstituted pyrazolylene group, a substituted or unsubstituted imidazolylene group, a substituted or unsubstituted imidazolinylene group, a substituted or unsubstituted triazolylene group, a substituted or unsubstituted tetrazolylene group, a substituted or unsubstituted imidazopyridinylene group, a substituted or unsubstituted imidazopyrimidinylene group, a substituted or unsubstituted pyrazinylene group, a substituted or unsubstituted pyrimidinylene group, a substituted or unsubstituted indolylene group, a substituted or unsubstituted purinylene group, a substituted or unsubstituted quinolinylene group, a substituted or unsubstituted phthalazinylene group, a substituted or unsubstituted indolizinylene group, a substituted or unsubstituted naphthyridinylene group, a substituted or unsubstituted quinazolinylene group, a substituted or unsubstituted cinnolinylene group, a substituted or unsubstituted indazolylene group, a substituted or unsubstituted phenazinylene group, a substituted or unsubstituted phenanthridinylene group, a substituted or unsubstituted pyranylene group, a substituted or unsubstituted chromenylene group, a substituted or unsubstituted furanylene group, a substituted or unsubstituted benzofuranylene group, a substituted or unsubstituted thiophenylene group, a substituted or unsubstituted benzothiophenylene group, a substituted or unsubstituted isothiazolylene group, a substituted or unsubstituted benzoimidazolylene group, a substituted or unsubstituted isoxazolylene group, or a substituted or unsubstituted oxadiazolylene group.

In some other embodiments, X in Formula 1 above may be at least one of the groups represented by Formulae 2A to 2P, but is not limited thereto.

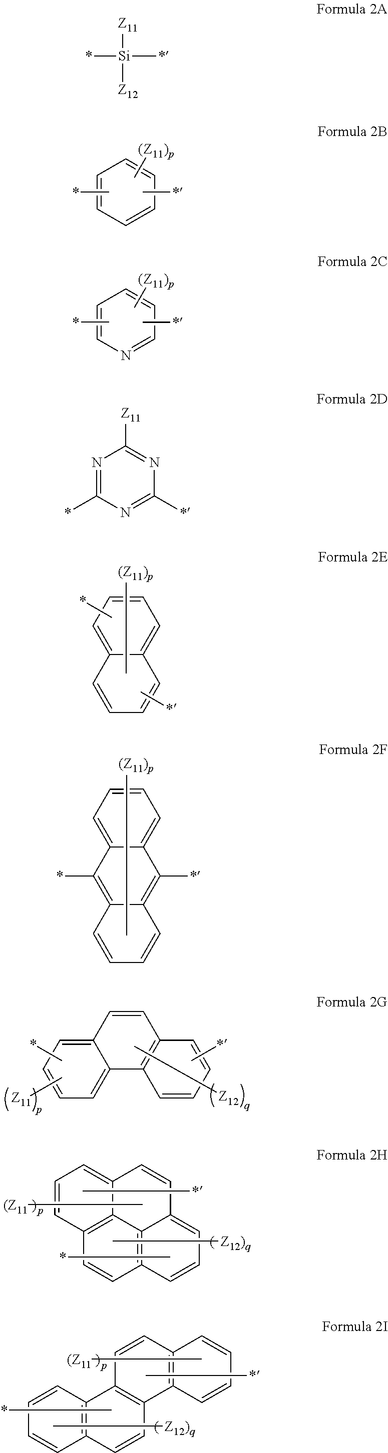

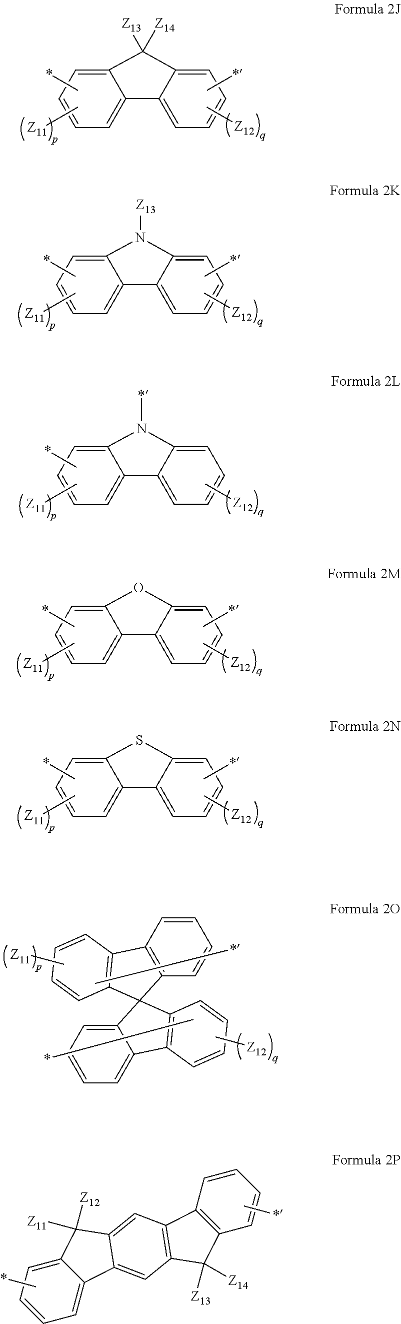

In Formulae 2A to 2P, Z₁₁ to Z₁₄ may be each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, a C₂-C₂₀ heteroaryl group; a C₁-C₂₀ alkyl group or a C₁-C₂₀ alkoxy group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof; or a C₆-C₂₀ aryl group or a C₂-C₂₀ heteroaryl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, or a C₂-C₂₀ heteroaryl group. * indicates a binding site with L₁ or a pyrenyl group, and *′ indicates a binding site with L₂ or a pyrenyl group.

In some other embodiments, in Formulae 2A to 2P, Z₁₁ to Z₁₄ may be each independently one of a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a propyl group, a butyl group, a pentyl group, a methoxy group, an ethoxy group, a propoxy group, a butoxy group, a pentoxy group, a phenyl group, a naphthyl group, an anthryl group, a phenanthrenyl group, a pyrenyl group, a fluorenyl group, a pyridinyl group, a pyrimidinyl group, a triazinyl group, a quinolyl group, a carbazolyl group; a methyl group, an ethyl group, a propyl group, a butyl group, a pentyl group, a methoxy group, an ethoxy group, a propoxy group, a butoxy group, or a pentoxy group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof; a phenyl group, a naphthyl group, an anthryl group, a phenanthrenyl group, a pyrenyl group, a fluorenyl group, a pyridinyl group, a pyrimidinyl group, a triazinyl group, a quinolyl group, or a carbazolyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, or a C₁-C₂₀ alkoxy group.

For example, X in Formula 1 above may be a group represented by one of Formulae 3A to 3I, but is not limited thereto.

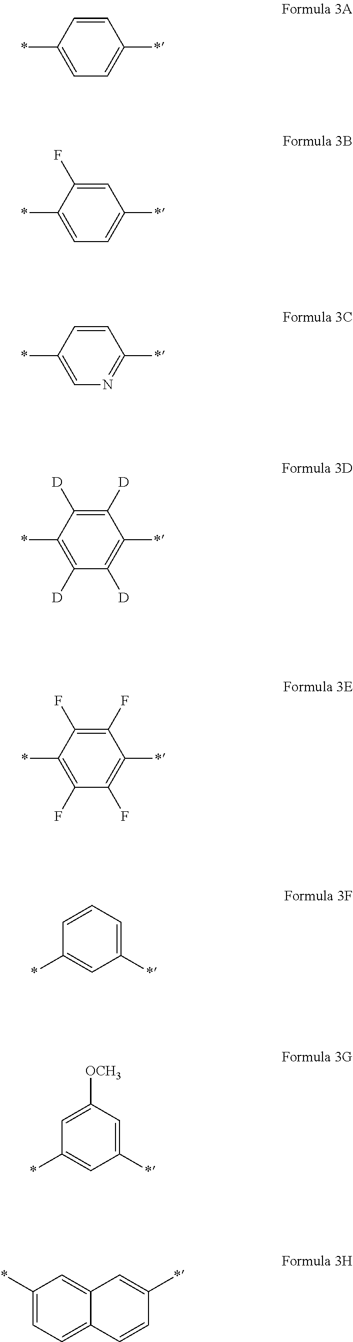

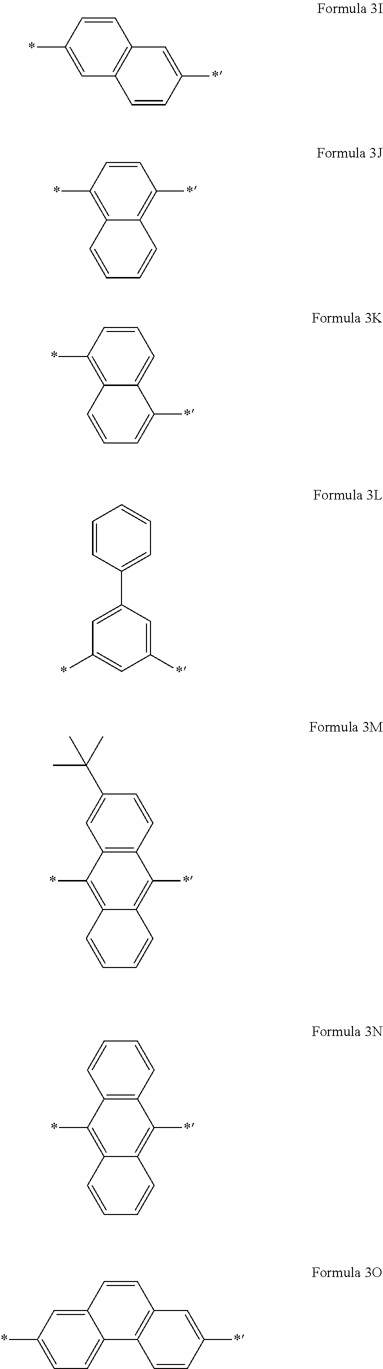

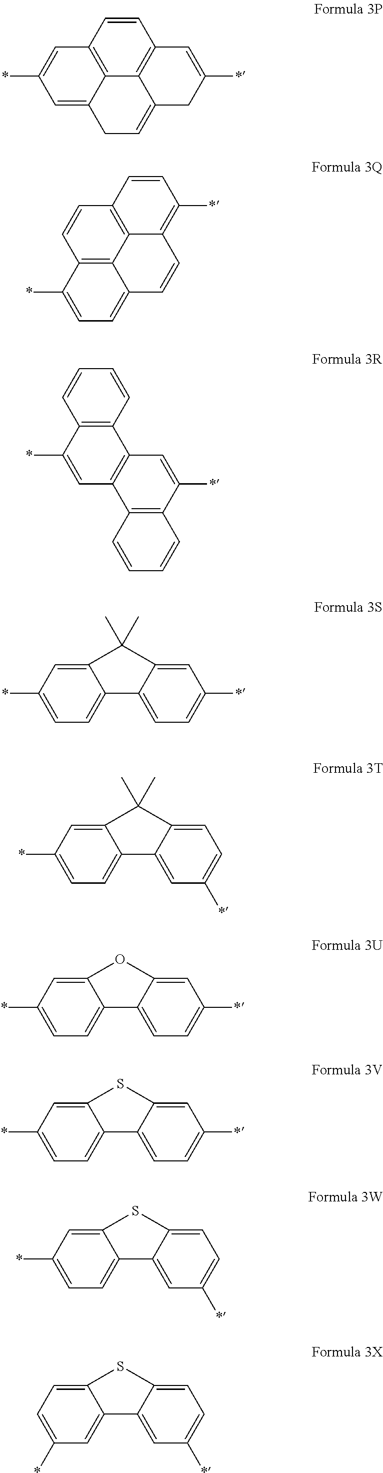

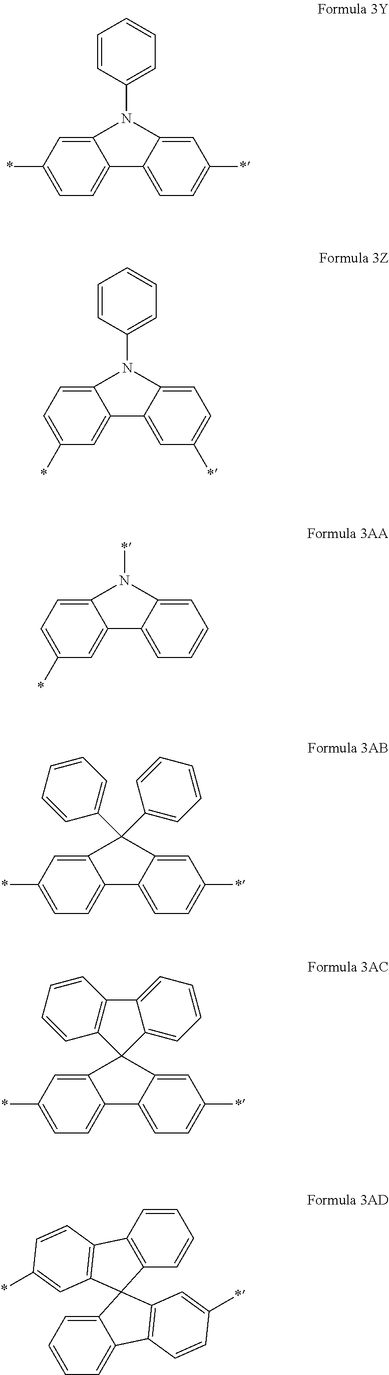

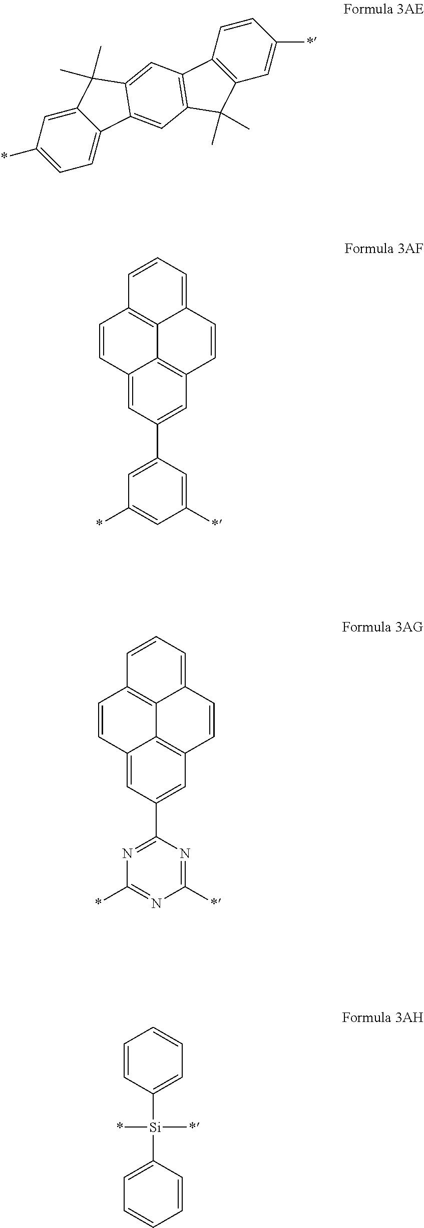

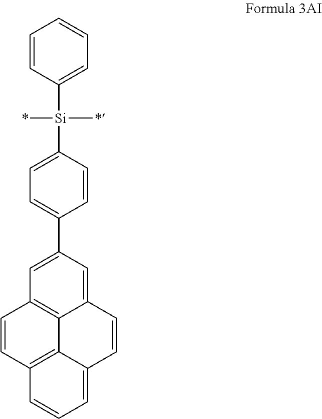

In Formulae 3A to 3I, * indicates a binding site with L₁ or a pyrenyl group in Formula 1; and *′ indicates a binding site with L₂ or a pyrenyl group in Formula 1.

In Formula 1, L₁ and L₂ may be each independently a substituted or unsubstituted phenylene group, a substituted or unsubstituted naphthylene group, a substituted or unsubstituted phenanthrenylene group, a substituted or unsubstituted phenalenylene group, a substituted or unsubstituted pyrenylene group, a substituted or unsubstituted chrysenylene group, a substituted or unsubstituted anthrylene group, a substituted or unsubstituted pentalenylene group, a substituted or unsubstituted indenylene group, a substituted or unsubstituted azulenylene group, a substituted or unsubstituted heptalenylene group, a substituted or unsubstituted indacenylene group, a substituted or unsubstituted acenaphthylene group, a substituted or unsubstituted fluoranthenylene group, a substituted or unsubstituted triphenylenylene group, a substituted or unsubstituted naphthacenylene group, a substituted or unsubstituted picenylene group, a substituted or unsubstituted perylenylene group, a substituted or unsubstituted pentaphenylene group, a substituted or unsubstituted hexacenylene group, a substituted or unsubstituted fluorenylene group, a substituted or unsubstituted carbazolylene group, a substituted or unsubstituted dibenzopuranylene group, a substituted or unsubstituted dibenzothiophenylene group, a substituted or unsubstituted pyridylene group, a substituted or unsubstituted pyridazinylene group, a substituted or unsubstituted triazinylene group, a substituted or unsubstituted pyrrolylene group, a substituted or unsubstituted pyrazolylene group, a substituted or unsubstituted imidazolylene group, a substituted or unsubstituted imidazolinylene group, a substituted or unsubstituted triazolylene group, a substituted or unsubstituted tetrazolylene group, a substituted or unsubstituted imidazopyridinylene group, a substituted or unsubstituted imidazopyrimidinylene group, a substituted or unsubstituted pyrazinylene group, a substituted or unsubstituted pyrimidinylene group, a substituted or unsubstituted indolylene group, a substituted or unsubstituted purinylene group, a substituted or unsubstituted quinolinylene group, a substituted or unsubstituted phthalazinylene group, a substituted or unsubstituted indolizinylene group, a substituted or unsubstituted naphthyndinylene group, a substituted or unsubstituted quinazolinylene group, a substituted or unsubstituted cinnolinylene group, a substituted or unsubstituted indazolylene group, a substituted or unsubstituted phenazinylene group, a substituted or unsubstituted phenanthridinylene group, a substituted or unsubstituted pyranylene group, a substituted or unsubstituted chromenylene group, a substituted or unsubstituted furanylene group, a substituted or unsubstituted benzofuranylene group, a substituted or unsubstituted thiophenylene group, a substituted or unsubstituted benzothiophenylene group, a substituted or unsubstituted isothiazolylene group, a substituted or unsubstituted benzoimidazolylene group, a substituted or unsubstituted isoxazolylene group, or a substituted or unsubstituted oxadiazolylene group.

For example, L₁ and L₂ may be each independently a group represented by one of Formulae 4A to 4C below, but are not limited thereto.

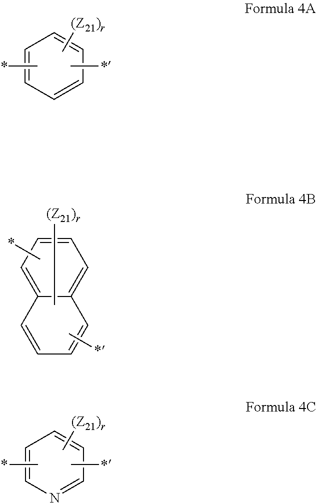

In Formulae 4A to 4C, Z₂₁ is one of a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀, alkoxy group, a C₆-C₂₀ aryl group, a C₂-C₂₀ heteroaryl group; a C₁-C₂₀ alkyl group or a C₁-C₂₀ alkoxy group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof; a C₆-C₂₀ aryl group or a C₂-C₂₀ heteroaryl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, C₁-C₂₀ alkyl group, a C₁-C₂₀ alkoxy group, a C₆-C₂₀ aryl group, or a C₂-C₂₀ heteroaryl group. * and *′ indicate binding sites.

For example, L₁ and L₂ may be each independently one of the groups represented by Formulae 5A to 5G below.

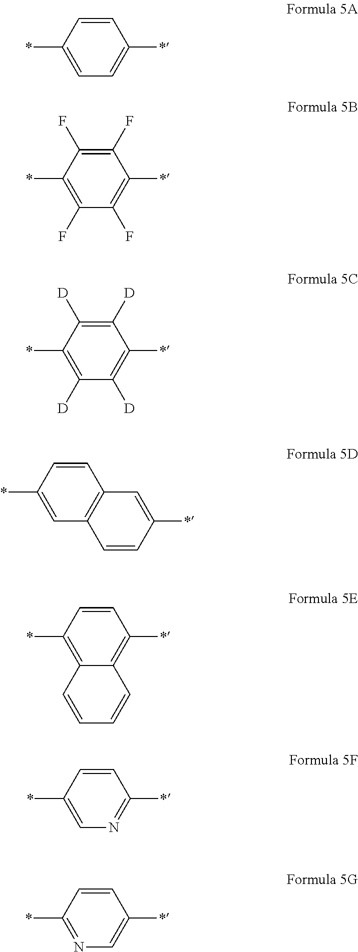

In Formulae 5A to 5G, * indicates a binding site with a pyrenyl group, L₁, or L₂ in Formula 1; and *′ indicates a binding site with X, L₁, or L₂ in Formula 1.

In Formula 1 above, R₁ to R₁₈ may be each independently one of a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, C₁-C₁₀ alkyl group, or a C₁-C₁₀ alkoxy group, a phenyl group, a naphthyl group, an anthryl group, a fluorenyl group, a dibenzofuranyl group, or a dibenzothiophenyl group; or a C₁-C₁₀ alkyl group, a C₁-C₁₀ alkoxy group, a phenyl group, a naphthyl group, an anthryl group, a fluorenyl group, a dibenzofuranyl group, or a dibenzothiophenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric add group or a salt thereof.

For example, R₁ to R₁₈ in Formula 1 may be each independently one of a hydrogen atom, a deuterium atom, a halogen atom, a methyl group, an ethyl group, a propyl group, a butyl group, a methoxy group, an ethoxy group, a propoxy group, a butoxy group, or a pentoxy group.

In some embodiments, in the condensed cyclic compound of Formula 1 above, i) a=0 and b=0, ii) a=0 and b=1, iii) a=1 and b=0, or iv) a=1 and b=1.

In some other embodiments, in the condensed cyclic compound of Formula 1 above, X may be one of a silylene group, a phenylene group, a naphthylene group, a phenanthrenylene group, an anthrylene group, a pyrenylene group, a chrysenylene group, a fluorenylene group, a carbazolylene group, a dibenzopuranylene group, a dibenzothiophenylene group, a pyridylene group, and a triazinylene group; or a silylene group, a phenylene group, a naphthylene group, a phenanthrenylene group, an anthrylene group, a pyrenylene group, a chrysenylene group, a fluorenylene group, a carbazolylene group, a dibenzopuranylene group, a dibenzothiophenylene group, a pyridylene group, or a triazinylene group substituted with at least one of a deuterium atom, a halogen atom, C₁-C₂₀ alkyl group, and a C₁-C₂₀ alkoxy group, a C₁-C₂₀ aryl group;

L₁ and L₂ may be each independently a phenylene group, a naphthylene group, a phenanthrenylene group, an anthrylene group, a pyrenylene group, a chrysenylene group, a fluorenylene group, a carbazolylene group, a dibenzopuranylene group, a dibenzothiophenylene group, a pyridylene group, or a triazinylene group; or a silylene group, a phenylene group, a naphthylene group, a phenanthrenylene group, an anthrylene group, a pyrenylene group, a chrysenylene group, a fluorenylene group, a carbazolylene group, a dibenzopuranylene group, a dibenzothiophenylene group, a pyridylene group, or a triazinylene group substituted with at least one of a deuterium atom, a halogen atom, a C₁-C₂₀ alkyl group, a C₁-C₂₀ alkoxy group, or a C₁-C₂₀ aryl group.

a and b may be each independently 0 or 1.

R₁ to R₁₈ may be each independently one of a hydrogen atom, a deuterium atom, a halogen atom, a methyl group, an ethyl group, a propyl group, a butyl group, a methoxy group, an ethoxy group, a propoxy group, a butoxy group, a pentoxy group, a C₆-C₂₀ aryl group, or a C₂-C₂₀ heteroaryl group.

In some embodiments, in the condensed cyclic compound of Formula 1 above, X may be one of the groups represented by Formulae 2A to 2P below.

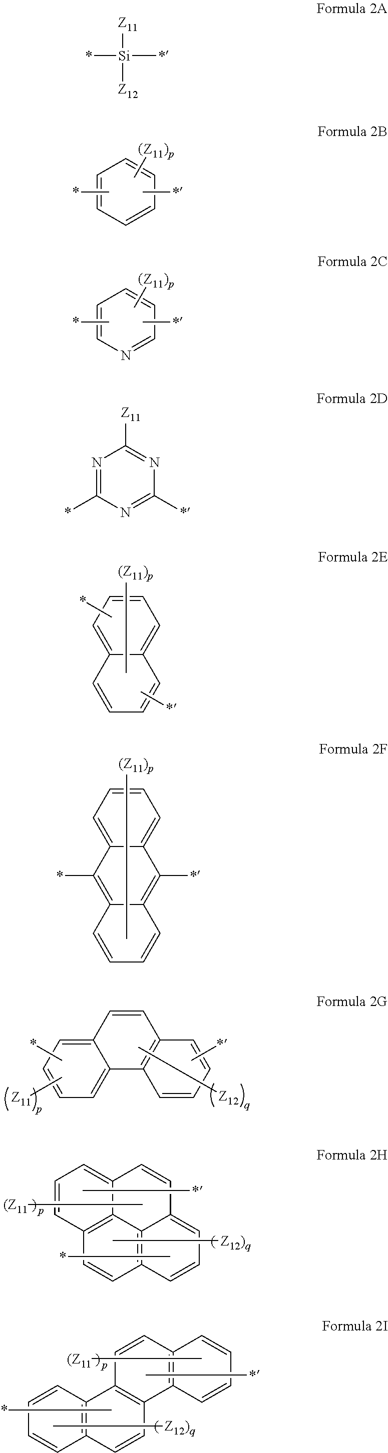

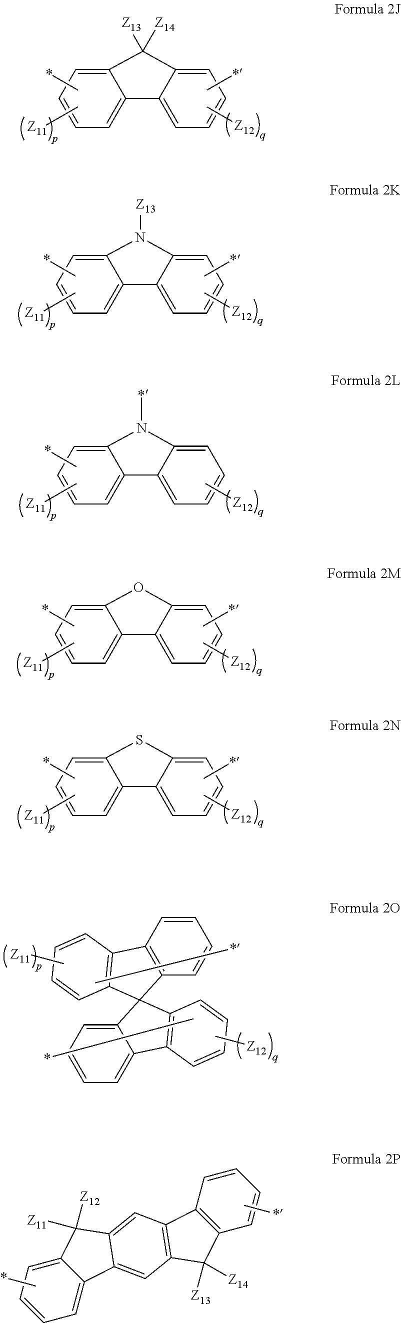

In Formulae 2A to 2P, Z₁₁ to Z₁₄ may be each independently one of a hydrogen atom, a deuterium atom, a halogen atom, a cyano group, a nitro group, a methyl group, an ethyl group, a propyl group, a butyl group, a methoxy group, an ethoxy group, a propoxy group, a butoxy group, a phenyl group, a naphthyl group, an anthryl group, a phenanthrenyl group, a pyrenyl group, a fluorenyl group, a pyridinyl group, a pyrimidinyl group, a triazinyl group, a quinolyl group, or a carbazolyl group. * and *′ indicate binding sites.

L₁ and L₂ may be each independently one of the groups represented by Formulae 4A to 4C, below.

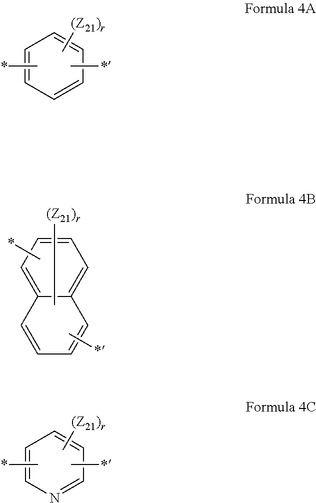

In Formulae 4A to 4C, Z₂₁ may be one of a hydrogen atom, a deuterium atom, a halogen atom, a cyano group, a nitro group, an amino group, a C₁-C₂₀ alkyl group, or a C₁-C₂₀ alkoxy group. * and *′ indicate binding sites.

a and b may be each independently 0 or 1.

R₁ to R₁₈ may be each independently one of a hydrogen atom, a deuterium atom, a halogen atom, a methyl group, an ethyl group, a propyl group, a butyl group, a methoxy group, an ethoxy group, a propoxy group, or a butoxy group.

The condensed cyclic compound represented by Formula 1 above may be one of the compounds represented by Compounds 1 to 71 below, but is not limited thereto:

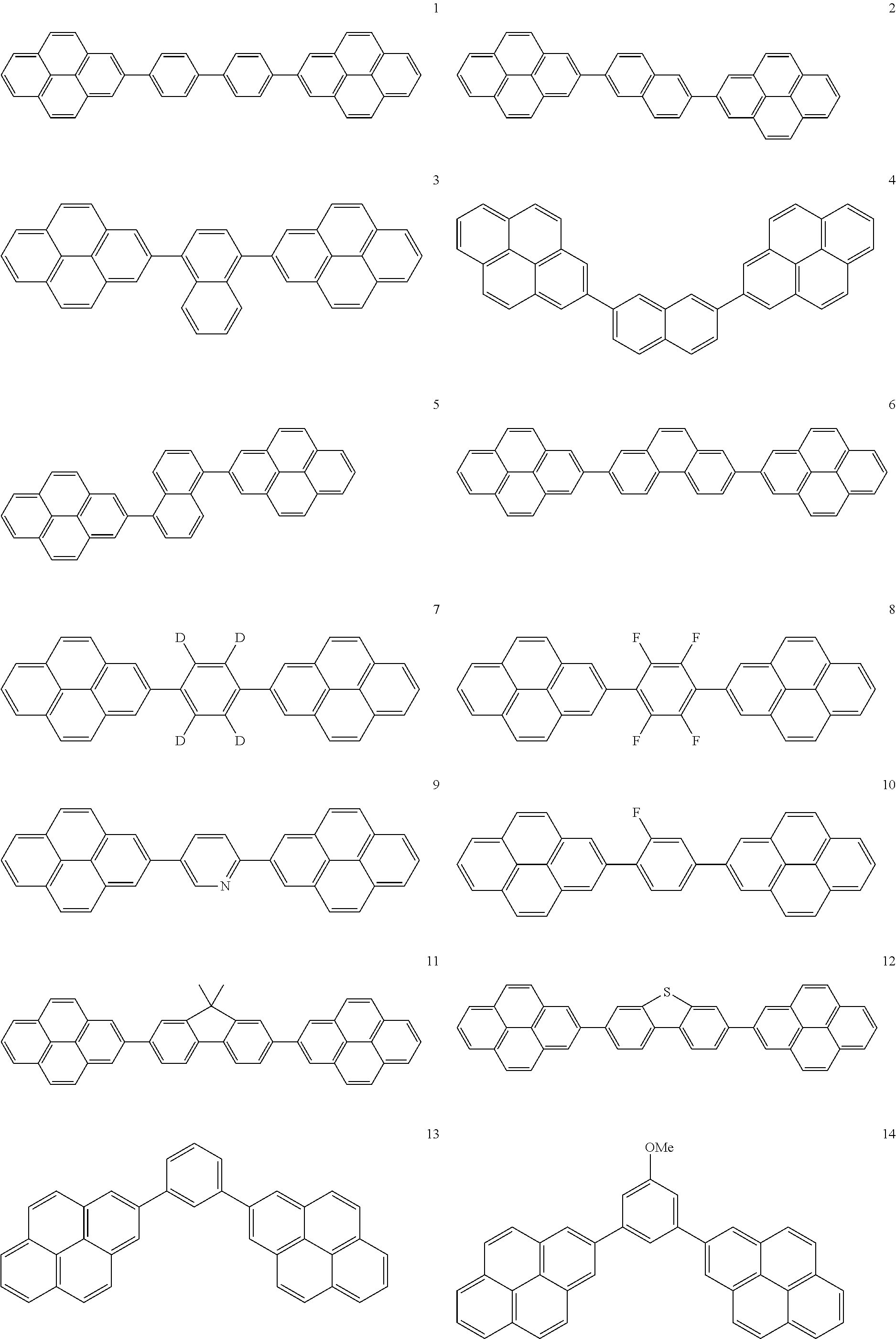

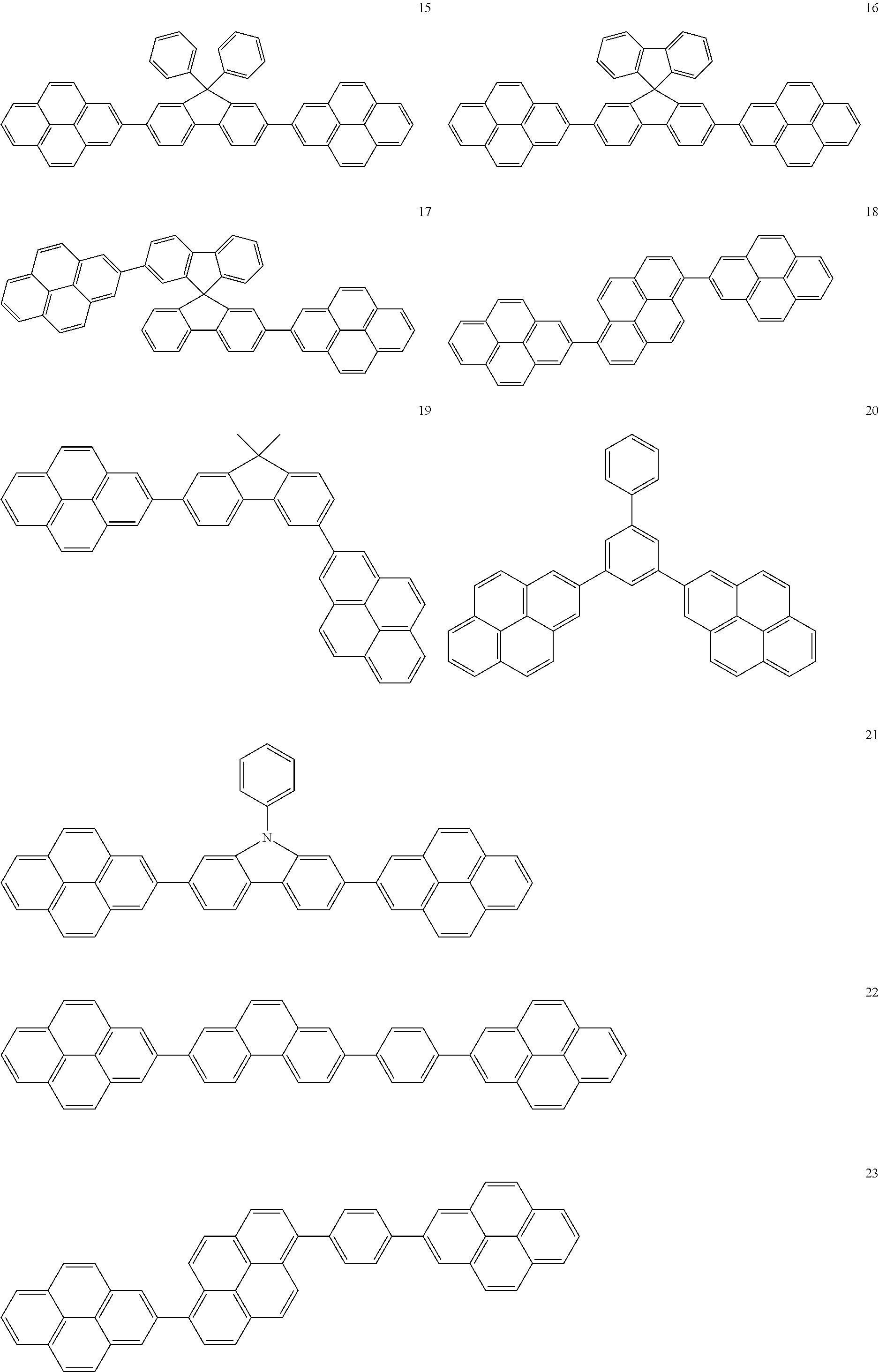

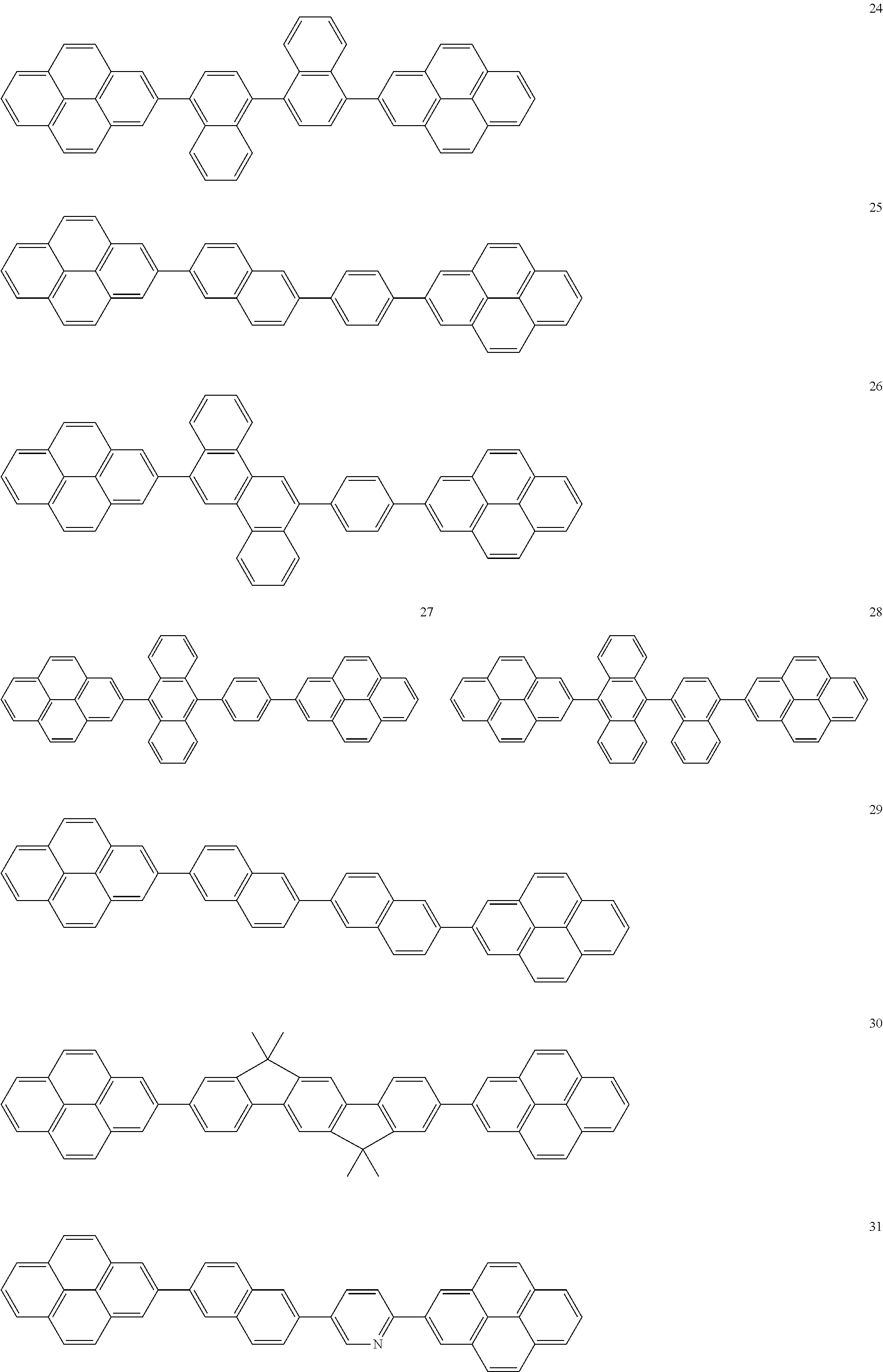

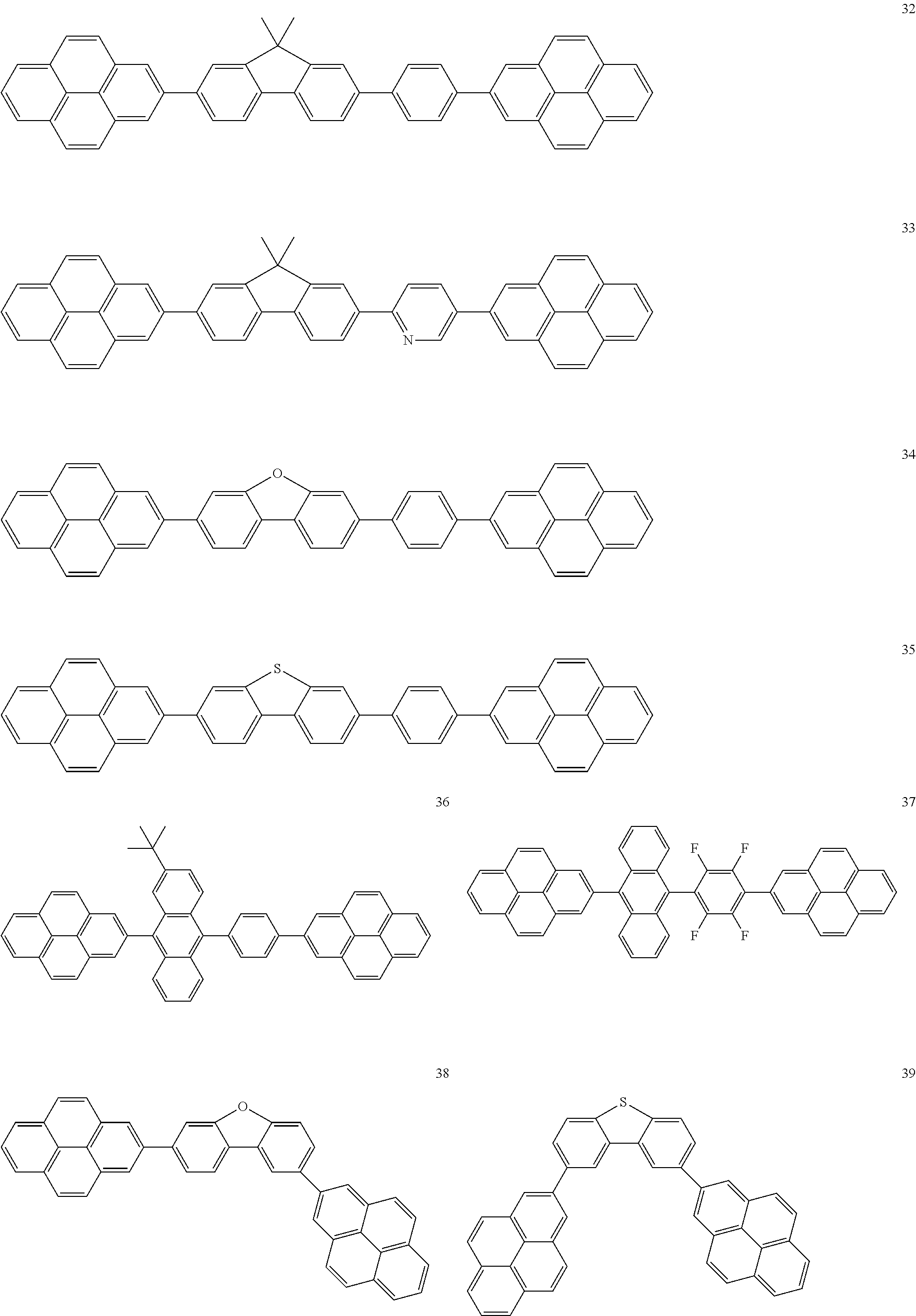

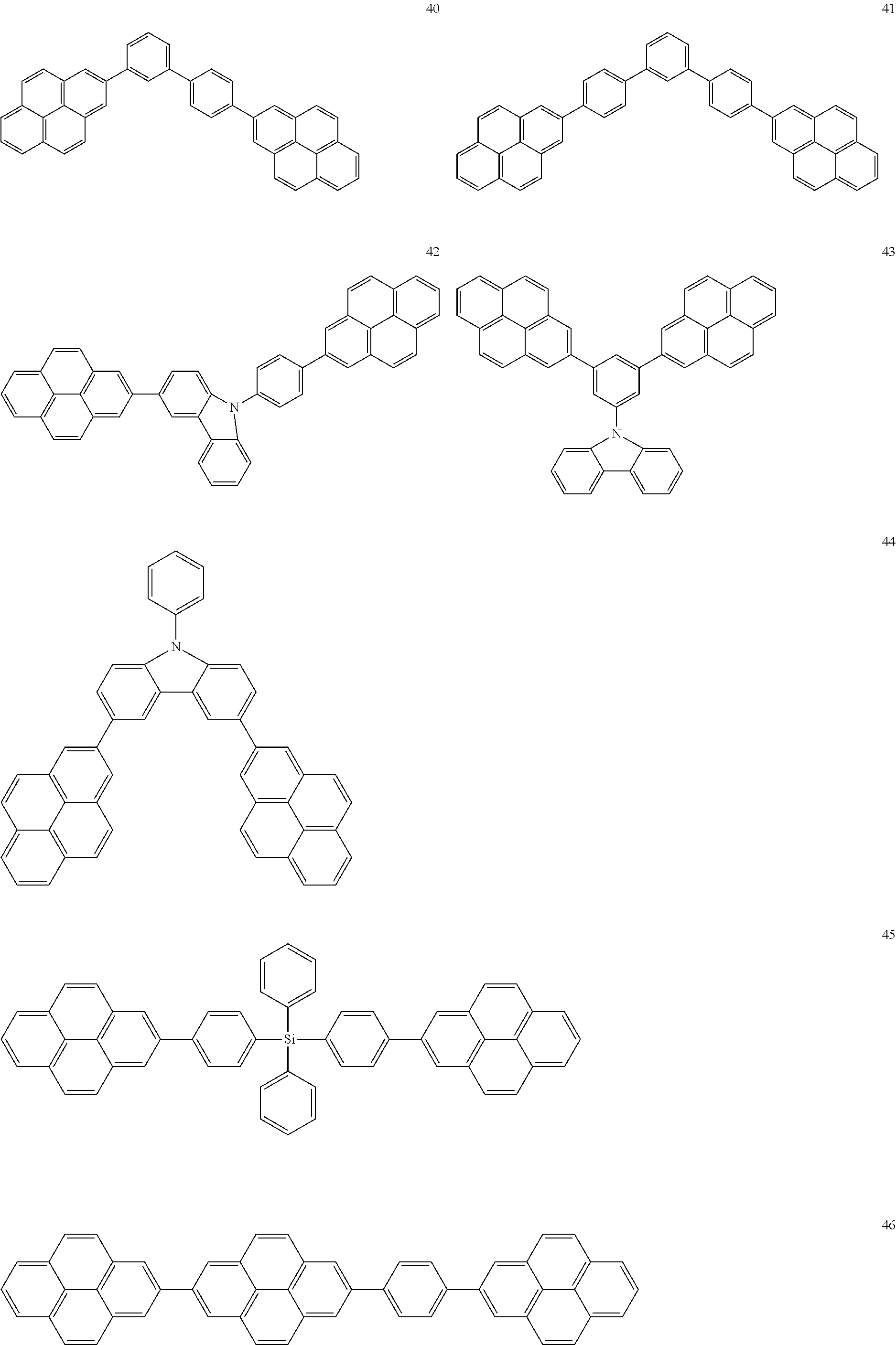

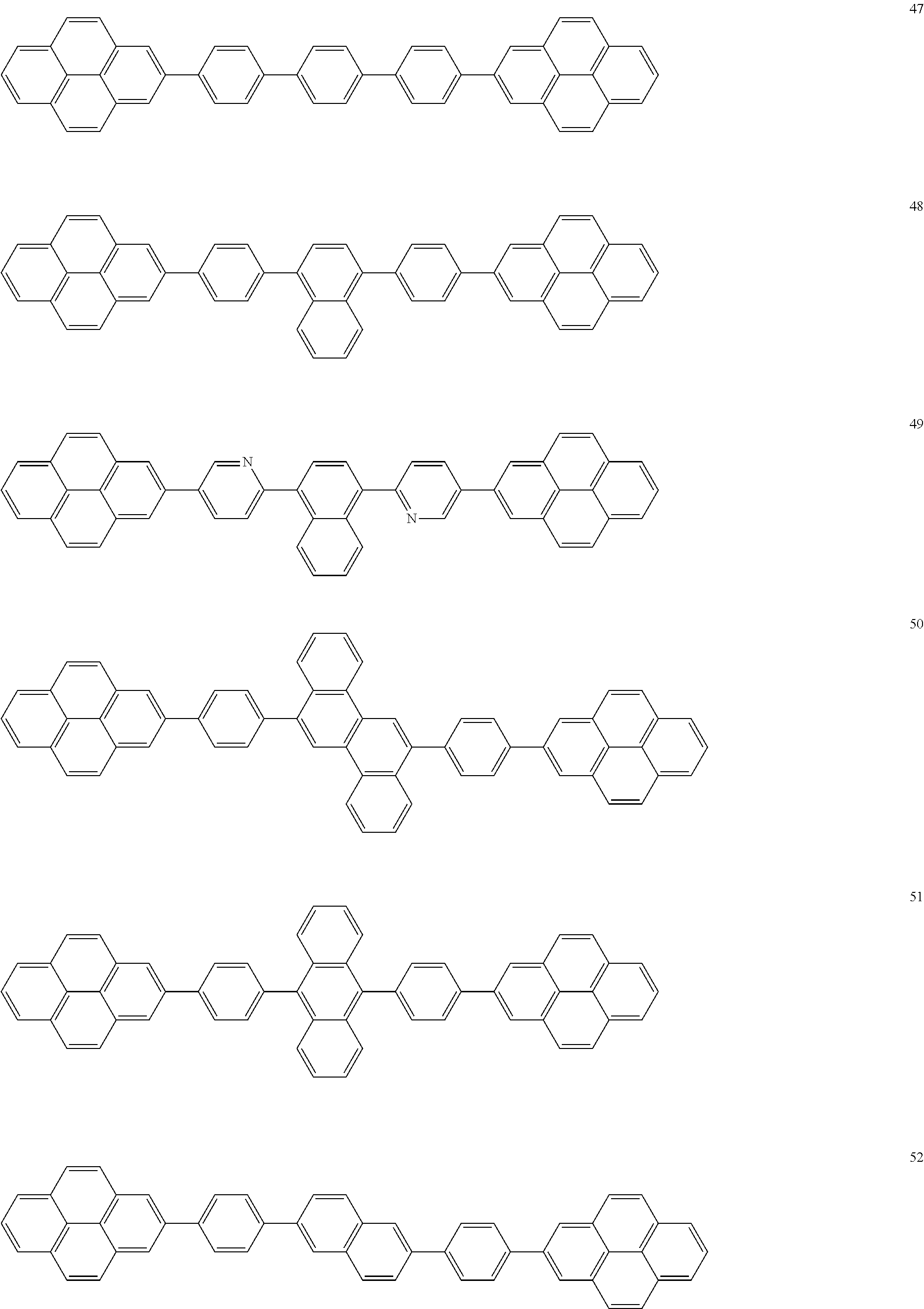

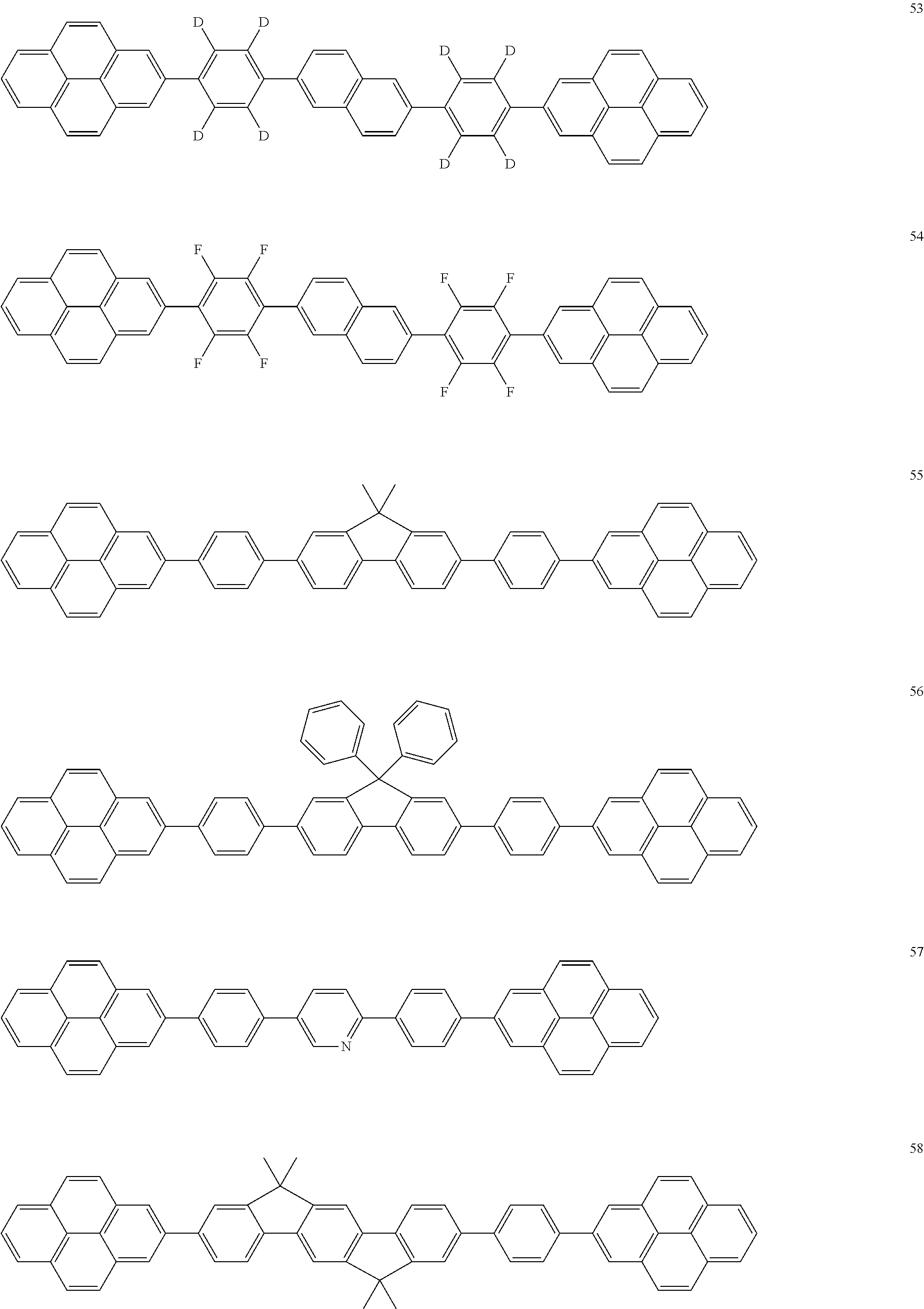

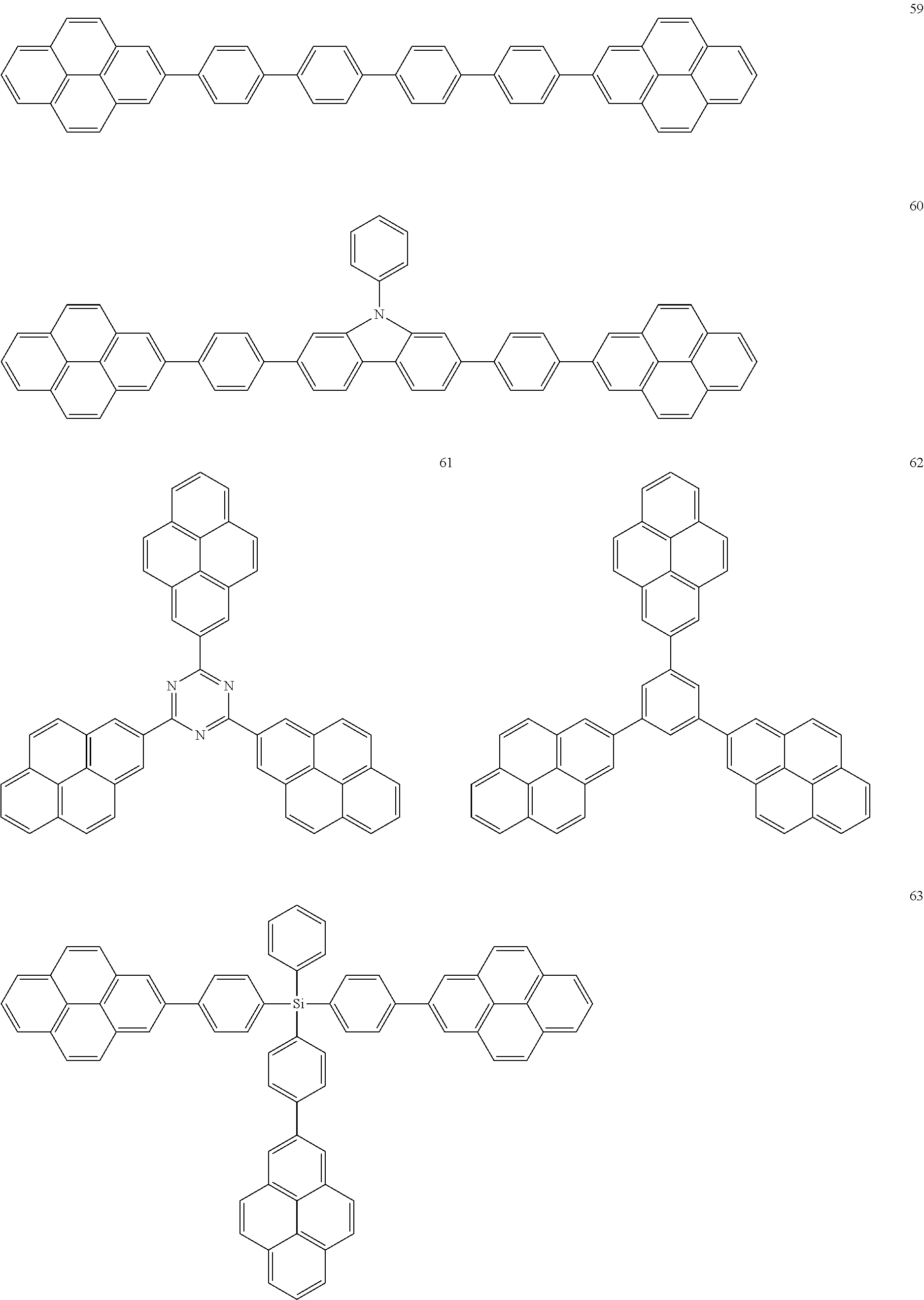

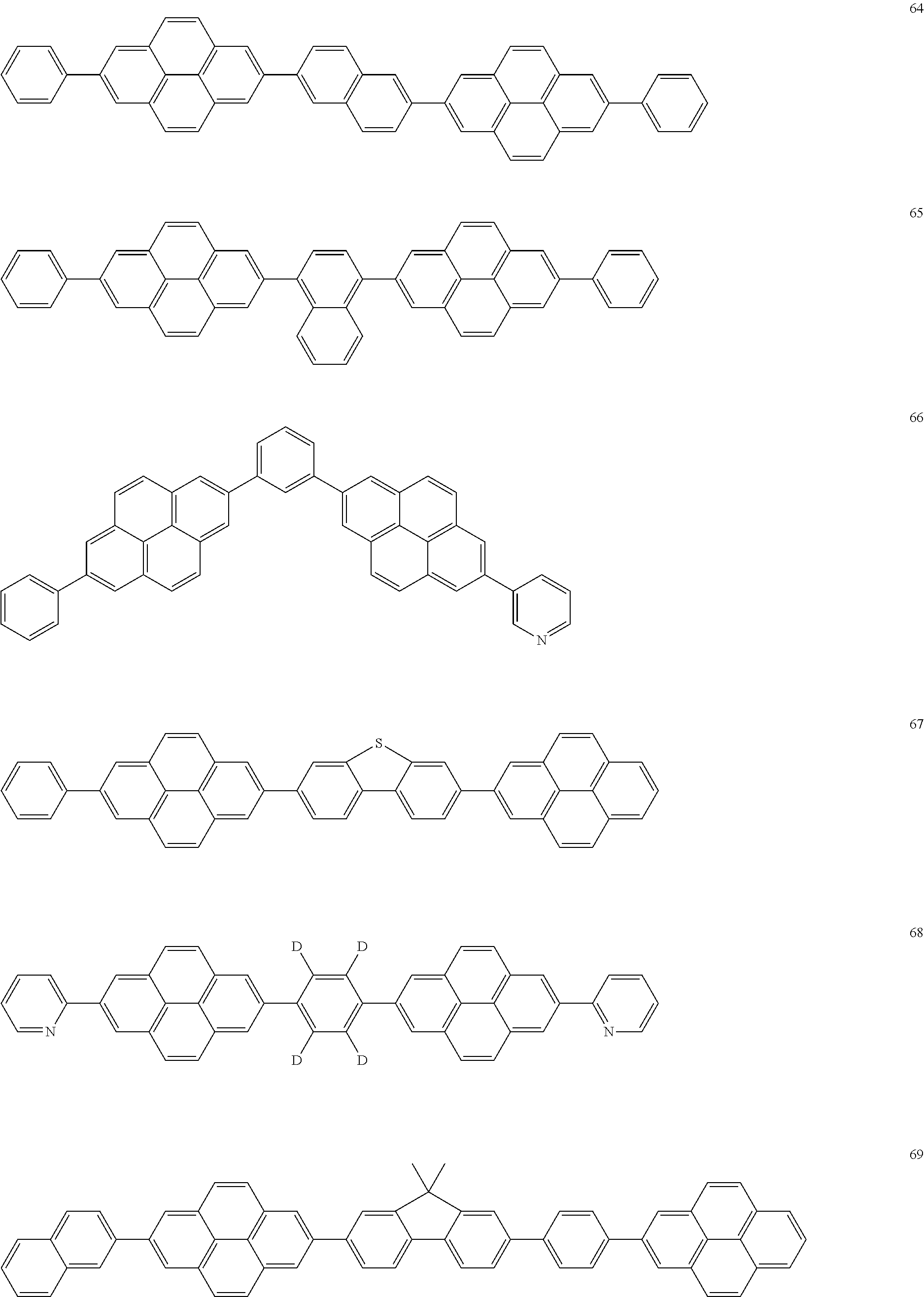

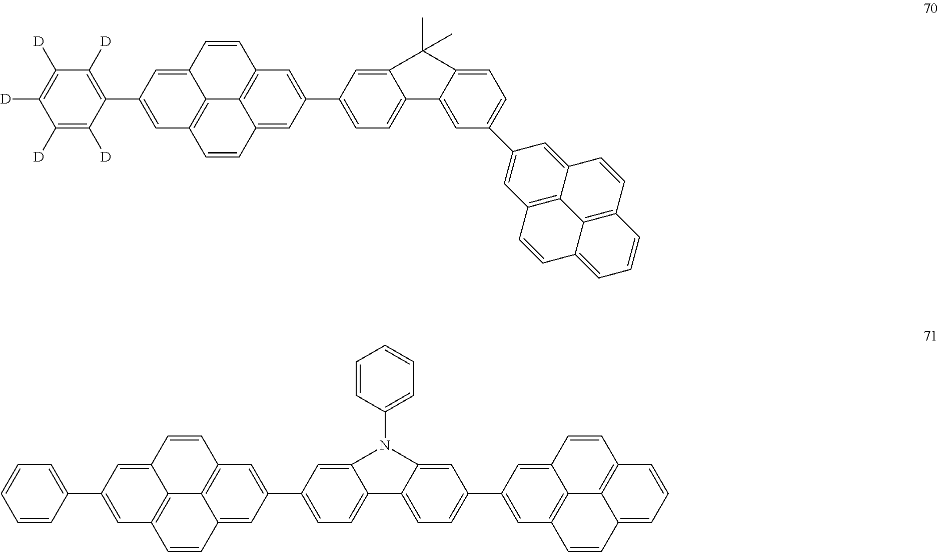 [SMILES: [2H]c1c([2H])c([2H])c(-c2cc3ccc4cc(-c5ccc6c(c5)C(C)(C)c5ccc(-c7cc8ccc9cccc%10ccc(c7)c8c9%10)cc5-6)cc5ccc(c2)c3c45)c([2H])c1[2H] ; c1ccc(-c2cc3ccc4cc(-c5ccc6c7ccc(-c8cc9ccc%10cccc%11ccc(c8)c9c%10%11)cc7n(-c7ccccc7)c6c5)cc5ccc(c2)c3c45)cc1]

The condensed cyclic compound of Formula 1 above may be used as an emitting material, an electron injecting material, and/or an electron transporting material for organic light-emitting devices. The condensed cyclic compound(s) of Formula 1 has a high glass transition temperature (Tg) or a high melting point due to the inclusion of the condensed ring in the molecular structure thereof. Thus, the condensed cyclic compound of Formula 1 above has high heat resistance against Joule's heat generated in an organic layer, between organic layers, or between an organic layer and a metal electrode when light emission occurs, and is durable in high-temperature environments. An organic light-emitting device manufactured using the condensed cyclic compound of Formula 1 may have improved durability when stored or operated. In addition, due to the inclusion of a substituent such as a fluorene group in the molecular structure, organic layers formed as thin films may be maintained in good condition, so that the organic light-emitting device may have improved characteristics. When used as a material capable of transporting holes and electrons, the condensed cyclic compound of Formula 1 may have good energy transfer ability, may lower the driving voltage of the device, and may have good light-emitting characteristics with high efficiency.

As used herein, the unsubstituted C₁-C₆₀ alkyl group (or a C₁-C₆₀ alkyl group) may be a linear or branched C₁-C₆₀ alkyl group, including a methyl group, an ethyl group, a propyl group, an isobutyl group, a sec-butyl group, a pentyl group, an iso-amyl group, or a hexyl group. The substituted C₁-C₆₀ alkyl group refers to the unsubstituted C₁-C₆₀ alkyl group in which at least one hydrogen atom is substituted with a deuterium atom, a halogen atom, a cyano group, a hydroxyl group, a nitro group, an amino group, an amidino group, a silyl group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ an alkenyl group C₂-C₆₀ alkynyl group, C₁-C₆₀ alkoxy group, a C₃-C₆₀ cycloalkyl group, a C₆-C₆₀ aryl group, a C₂-C₆₀ heteroaryl group, a C₆-C₆₀ aralkyl group, a C₆-C₆₀ aryloxy group; a C₁-C₆₀ alkyl group, a C₂-C₆₀ an alkenyl group, a C₂-C₆₀ alkynyl group, or a C₁-C₆₀ alkoxy group substituted with at least one of a deuterium atom, a halogen atom, a cyano group, a hydroxyl group, a nitro group, an amino group, an amidino group, a silyl group, a hydrazine, a hydrazone, a carboxyl group or a salt thereof, a sulfonic acid group or a salt thereof, or a phosphoric acid group or a salt thereof; or a C₃-C₆₀ cycloalkyl group, a C₆-C₆₀ aryl group, a C₂-C₆₀ heteroaryl group, a C₆-C₆₀ aralkyl group, or a C₆-C₆₀ aryloxy group substituted with at least one of a deuterium atom, a halogen atom, a cyano group, a hydroxyl group, a nitro group, an amino group, an amidino group, a silyl group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ an alkenyl group, a C₂-C₆₀ alkynyl group, a C₁-C₆₀ alkoxy group, a C₆-C₆₀ aryl group, or a C₂-C₆₀ heteroaryl group.

As used herein, the unsubstituted alkoxy group (or a C₁-C₆₀ alkoxy group) is represented by the formula —OA (where A is an unsubstituted C₁-C₆₀ alkyl group as described above). Non-limiting examples of the unsubstituted C₁-C₆₀ alkoxy group include a methoxy group, an ethoxy group, or an isopropyloxy group. The substituted C₁-C₆₀ alkoxy group refers to a C₁-C₆₀ alkoxy group in which at least one hydrogen atom is substituted with the substituents described above in connection with the C₁-C₆₀ alkyl group.

As used herein, the unsubstituted C₂-C₆₀ alkenyl group (or a C₂-C₆₀ alkenyl group) refers to an alkyl group having at least one carbon-carbon double bond in the center or at a terminal end of the alkyl group. Examples of the alkenyl group include an ethenyl group, a propenyl group, or a butenyl group. The substituted C₂-C₆₀ alkenyl group refers to a C₂-C₆₀ an alkenyl group in which at least one hydrogen atom is substituted with the substituents described above in connection with the C₁-C₆₀ alkyl group.

As used herein, the unsubstituted C₂-C₆₀ alkynyl group for a C₂-C₆₀ alkynyl group) indicates a C₂-C₆₀ alkyl group having at least one carbon-carbon triple bond in the center or at a terminal end of the alkyl group. Non-limiting examples of the unsubstituted C₂-C₆₀ alkynyl group include an ethynyl group or a propynyl group. The substituted C₂-C₆₀ alkynyl group refers to a C₂-C₆₀ alkynyl group in which at least one hydrogen atom is substituted with the substituents described above in connection with the C₂-C₆₀ alkyl group.

As used herein, the unsubstituted C₆-C₆₀ aryl group indicates a monovalent C5-C60 carbocyclic aromatic system containing at least one aromatic ring. The unsubstituted C₆-C₆₀ arylene group indicates a divalent C5-C60 carbocyclic aromatic system containing at least one aromatic ring When the unsubstituted C₆-C₆₀ aryl or arylene group includes at least two rings, the at least two rings may be fused to each other. The substituted C₆-C₆ aryl group refers to a C₆-C₆₀ aryl group in which at least one hydrogen atom is substituted with the substituents described above in connection with the C₁-C₆₀ alkyl group. The substituted C₆-C₆₀ arylene group refers to a C₆-C₆₀ arylene group in which at least one hydrogen atom is substituted with the substituents described above in connection with the C₁-C₆₀ alkyl group.

Non-limiting examples of the substituted or unsubstituted C₆-C₆₀ aryl group include a phenyl group, a C₁-C₁₀ alkylphenyl group (for example, an ethylphenyl group), a C₁-C₁₀ alkylbiphenyl group (for example, an ethylbiphenyl group), a halophenyl group (for example, o-, m- and p-fluorophenyl groups, a dichlorophenyl group), a dicyanophenyl group, a trifluoromethoxyphenyl group, o-, m-, and p-tolyl groups, o-, m- and p-cumenyl groups, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (for example, a fluoronaphthyl group), a C₁-C₁₀ alkylnaphthyl group (for example, a methylnaphthyl group), a C₁-C₁₀ alkoxynaphthyl group (for example, a methoxynaphthyl group), an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylene group, a pyrenyl group, a chrysenyl group, an ethyl-chrysenyl group, a picenyl group, a perylenyl group, a chloroperylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group, and an ovalenyl group.

Examples of the substituted C₆-C₆₀ aryl group may be inferred based on the above-described examples of the unsubstituted C₆-C₆₀ aryl group and substituted C₁-C₆₀ alkyl group. Examples of the substituted or unsubstituted C₆-C₆₀ arylene group may be inferred based on the above-described examples of the substituted or unsubstituted C₆-C₆₀ aryl group.

The unsubstituted C₂-C₆₀ heteroaryl group is a monovalent carbocyclic aromatic system having at least one aromatic ring and at least one heteroatom selected from N, O, P, and S. The unsubstituted C₂-C₆₀ heteroarylene group is a divalent carbocyclic aromatic system having at least one aromatic ring and at least one heteroatom selected from N, O, P, and S. In this regard, when the heteroaryl group and the heteroarylene group have at least two rings, they may be fused to each other. The substituted C₂-C₆₀ heteroaryl group refers to a C₂-C₆₀ heteroaryl group in which at least one hydrogen atom is substituted with the substituents described above in connection with the C₁-C₆₀ alkyl group. The substituted C₂-C₆₀ heteroarylene group refers to a C₂-C₆₀ heteroarylene group in which at least one hydrogen atom is substituted with the substituents described above in connection with the C₁-C₆₀ alkyl group.

Examples of the unsubstituted C₂-C₆₀ heteroaryl group include a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzoimidazolyl group, an imidazopyridinyl group and an imidazopyrimidinyl group. Examples of the substituted C₂-C₆₀ heteroaryl group may be inferred based on the above-described exemplary substituents of the unsubstituted C₂-C₆₀ heteroaryl group and substituted C₁-C₆₀ alkyl group. Examples of the substituted or unsubstituted C₂-C₆₀ heteroarylene group may be inferred based on the above-described exemplary substituents of the substituted or unsubstituted C₂-C₆₀ heteroaryl group described above.

The substituted or unsubstituted C₆-C₆₀ aryloxy group is represented by —OA₂ (where A₂ is a substituted or unsubstituted C₆-C₆₀ aryl group described above). The substituted or unsubstituted C₆-C₆₀ arylthiol group is represented by —SA₃ (where A₃ is a substituted or unsubstituted C₆-C₆₀ aryl group described above).

The condensed cyclic compound of Formula 1 may be synthesized through organic synthesis. A synthesis method of the fused ring compound of Formula 1 may be understood by those of ordinary skill in the art from the examples that will be described below.

The condensed cyclic compound of Formula 1 may be used between a pair of electrodes of an organic light-emitting device. For example, the fused ring compound may be used in an emission layer, in a layer between the anode and the emission layer (for example, a hole injection layer, a hole transport layer, or a functional layer with both hole injection and transport capabilities), and/or in a layer between the cathode and the emission layer (for example, an electron injection layer, an electron transport layer, or a functional layer with both electron injection and transport capabilities).

According to another embodiment of the present invention, an organic light-emitting device includes a first electrode, a second electrode facing the first electrode, and an organic layer between the first electrode and the second electrode, the organic layer including at least one of the condensed cyclic compounds of Formula 1 described above.

As used herein, the term “organic layer” refers to a layer containing an organic compound and having at least one layer. For example, the organic layer may include at least one layer selected from a hole injection layer, a hole transport layer, a functional layer (hereinafter, “hole injection and transport layer”) having both hole injection and hole transport capabilities, an electron blocking layer, an emission layer, a hole blocking layer, an electron injection layer, an electron transport layer, and a functional layer (hereinafter, “electron injection and transport layer”) having both electron injection and electron transport capabilities.

In some embodiments, the organic layer may not include solely organic compounds. The organic layer may include an inorganic compound or an inorganic material. In one embodiment, the organic layer may include both an organic compound and an inorganic compound or an inorganic material in one layer. For example, the organic layer may include an organometallic complex in one layer. In another embodiment, the organic layer may include a layer containing an organic compound and a layer containing an inorganic compound or an inorganic material.

The organic layer may include at least one of the condensed cyclic compounds listed above in one layer, and in some other embodiments, may include at least one of the condensed cyclic compounds listed above in multiple layers. For example, the organic layer may include one of the condensed cyclic compounds of Formula 1 above as a dopant in an emission layer, and another condensed cyclic compound of Formula 1 as an electron transport material in an electron transport layer. In another embodiment, the organic layer may include one of the condensed cyclic compounds of Formula 1 as an emitting dopant and another condensed cyclic compound as a host in an emission layer. In another embodiment, the organic layer may include one of the condensed cyclic compounds as an emitting dopant and another condensed cyclic compound as a host in an emission layer, and still another condensed cyclic compound as an electron transport material in an electron transport layer.

The organic layer may include at least one of an emission layer, an electron injection layer, an electron transport layer, and an electron injection and transport layer, and at least one of the emission layer, the electron injection layer, the electron transport layer, and the electron injection and transport layer may include a condensed cyclic compound of Formula 1.

For example, the organic layer may include an emission layer including a host and a dopant, and the condensed cyclic compound of Formula 1 may serve as a fluorescent host or a phosphorescent host of the emission layer.

The emission layer may include a host and a dopant, and the emission layer may further include a fluorescent dopant or a phosphorescent dopant. For example, the phosphorescent dopant may be, but is not limited to, an organometallic complex including at least one of iridium (Ir), platinum (Pt), osmium (Os), rhenium (Re), titanium (Ti), zirconium (Zr), hafnium (Hf), or a combination of at least two thereof. The emission layer may or may not include the condensed cyclic compound of Formula 1 above.

In some embodiments, the emission layer may further include an anthracene compound, an arylamine compound, or a styryl compound. The emission layer may or may not include the condensed cyclic compound of Formula 1 above.

The organic layer may include an electron transport layer, which may include an electron transporting organic compound and a metal-containing material. The metal-containing material may include a lithium (Li) complex. The electron transport layer may or may not include the condensed cyclic compound of Formula 1 above.

The organic layer may include at least one of a hole injection layer, a hole transport layer, or a hole injection and transport layer, and at least one of these layers may further include a charge generating material. The charge generating material may be, for example, a p-dopant.

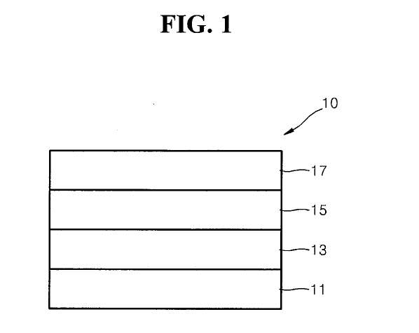

FIG. 1 is a schematic sectional view of an organic light-emitting device 10 according to an embodiment of the present invention. Hereinafter, a structure of an organic light-emitting device according to an embodiment of the present invention and a method of manufacturing the same will be described with reference to FIG. 1.

Referring to FIG. 1, the organic light-emitting device 10 includes a first electrode 13, an organic layer 15, and a second electrode 17, which are sequentially stacked (in this order) on a substrate 11.

The substrate 11 may be any substrate conventionally used in existing organic light-emitting devices. In some embodiments, the substrate 11 may be a glass substrate or a transparent plastic substrate having good mechanical strength, thermal stability, transparency, surface smoothness, ease of handling, and water resistance.

The first electrode 13 may be formed by depositing or sputtering a first electrode-forming material on the substrate 11. When the first electrode 13 is an anode, a material having a high work function may be used as the first electrode-forming material to facilitate hole injection. The first electrode 13 may be a reflective electrode or a transmissive electrode. Transparent and conductive materials such as ITO, IZO, SnO2, and ZnO may be used as materials for the first electrode 13. In some embodiments, the first electrode 13 may be formed as a reflective electrode using magnesium (Mg), silver (Ag), aluminum (Al), aluminum-lithium (Al—Li), calcium (Ca), magnesium-indium (Mg—In), magnesium-silver (Mg—Ag), or the like. The first electrode 13 may have a single-layer structure or a multi-layer structure including at least two layers. For example, the first electrode 13 may have a three-layered structure of ITO/Ag/ITO, but is not limited thereto.

The organic layer 15 may be disposed on the first electrode 13.

The organic layer 15 may include a hole injection layer (HIL), a hole transport layer (HTL), an emission layer (EML), an electron transport layer (ETL), and an electron injection layer (EIL).

The HIL may be formed on the first electrode 13 by vacuum deposition, spin coating, casting, Langmuir-Blodgett (LB) deposition, or the like. When the HIL is formed using vacuum deposition, the vacuum deposition conditions may vary according to the compound that is used to form the HIL, and the desired structure and thermal properties of the HIL to be formed. For example, the vacuum deposition may be performed at a temperature of about 100° C. to about 500° C., a pressure of about 10⁻⁸ torr to about 10⁻³ torr, and a deposition rate of about 0.01 to about 100 Å/sec. However, the deposition conditions are not limited thereto.

When the HIL is formed using spin coating, the coating conditions may vary according to the compound that is used to form the HIL, and the desired structure and thermal properties of the HIL to be formed. For example, the coating rate may be in the range of about 2000 rpm to about 5000 rpm, and a temperature at which heat treatment is performed to remove solvent after coating may be in the range of about 80° C. to about 200° C. However, the coating conditions are not limited thereto.

For example, as a HIL material, the condensed cyclic compound of Formula 1 or any known hole injection material may be used. Non-limiting examples of known hole injection materials include N,N′-diphenyl-N,N′-bis-[4-(phenyl-m-tolyl-amino)-phenyl]-biphenyl-4,4′-diamine, (DNTPD), phthalocyanine compounds such as copperphthalocyanine, 4,4′,4″-tris(3-methylphenylphenylamino)triphenylamine (m-MTDATA), 4,4′,4″-tris(N,N-diphenylamino)triphenylamine (TDATA), 4,4′,4″-tris{N,-(2-naphthyl)-N-phenylamino}-triphenylamine (2T-NATA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonicacid (PANI/CSA), and polyaniline/poly(4-styrenesulfonate) (PANI/PSS).

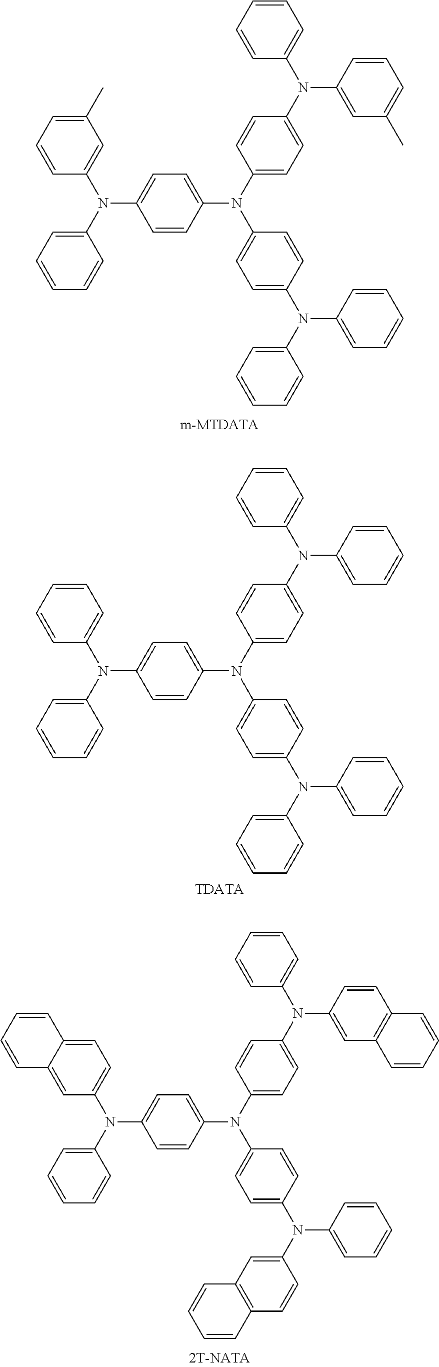 [SMILES: Cc1cccc(N(c2ccccc2)c2ccc(N(c3ccc(N(c4ccccc4)c4ccccc4)cc3)c3ccc(N(c4ccccc4)c4cccc(C)c4)cc3)cc2)c1 ; c1ccc(N(c2ccccc2)c2ccc(N(c3ccc(N(c4ccccc4)c4ccccc4)cc3)c3ccc(N(c4ccccc4)c4ccccc4)cc3)cc2)cc1 ; "TDATA" ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

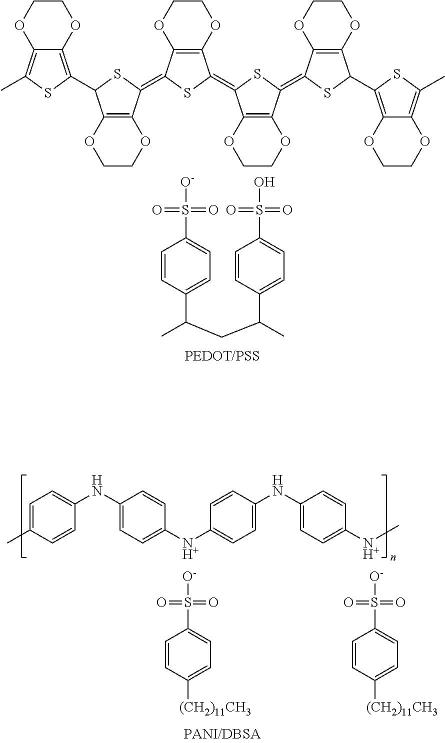

The thickness of the HIL may be about 100 Å to about 10,000 Å, and in some embodiments, may be from about 100 Å to about 1,000 Å. When the thickness of the HIL is within these ranges, the HIL may have good hole injecting ability without a substantial increase in driving voltage.

Then, a HTL may be formed on the HIL by vacuum deposition, spin coating, casting, Langmuir-Blodgett (LB) deposition, or the like. When the HTL is formed using vacuum deposition or spin coating, the conditions for deposition or coating may be similar to those for the formation of the HIL, though the conditions for the deposition or coating may vary according to the material that is used to form the HTL.

The HTL may be formed of any known hole-transporting materials. Non-limiting examples of known hole transporting materials include carbazole derivatives, such as N-phenylcarbazole, polyvinylcarbazole, or the like; triphenylamine materials, such as TPD (N,N′-bis(3-methylphenyl)-N,N′-diphenyl-[biphenyl]-4,4′-diamine); NPB (N,N′-di(1-naphthyl)-N,N-diphenylbenzidine), α-NPD (N,N′-bis(naphthalen-1-yl)-N,N′-bis(phenyl)-2,2′-dimethylbenzidine, and TCTA (4,4′,4″-tris(N-carbazolyl)triphenylamine).

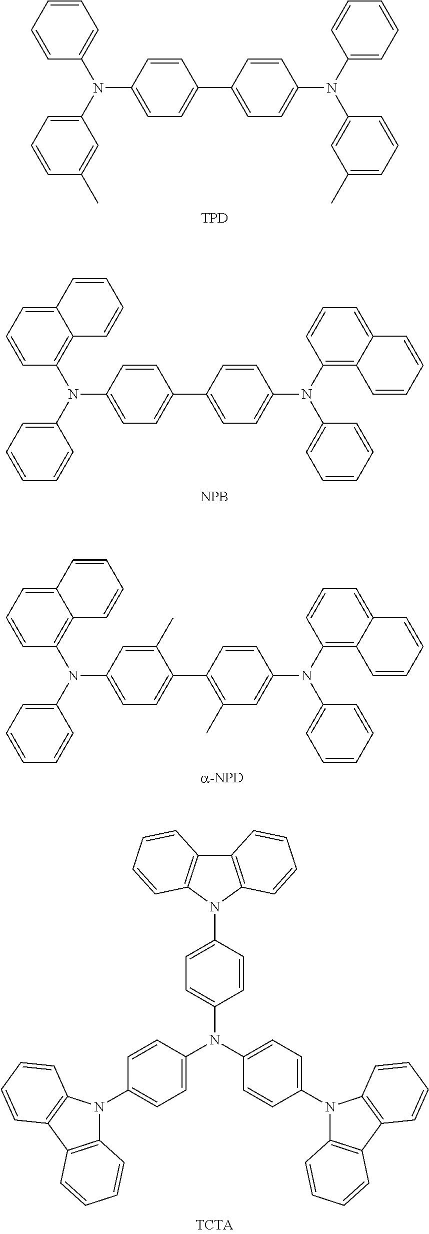

The thickness of the HTL may be from about 50 Å to about 1,000 Å, and in some embodiments, from about 100 Å to about 800 Å. When the thickness of the HTL is within these ranges, the HTL may have satisfactory hole transporting ability without a substantial increase in driving voltage.

In some embodiments, instead of the HIL and the HTL, a hole injection and transport layer may be formed. The hole injection and transport layer may include at least one of the hole injection layer materials and hole transport layer materials described above. A thickness of the hole injection and transport layer may be from about 500 Å to about 10,000 Å, and in some embodiments, may be from about 100 Å to about 1,000 Å. When the thickness of the hole injection and transport layer is within these ranges, the hole injection and transport layer may have good hole injection and transport capabilities without a substantial increase in driving voltage.

In some embodiments, at least one of the HIL, HTL, or hole injection and transport layer may include at least one of a compound of Formula 100 below or a compound of Formula 101 below:

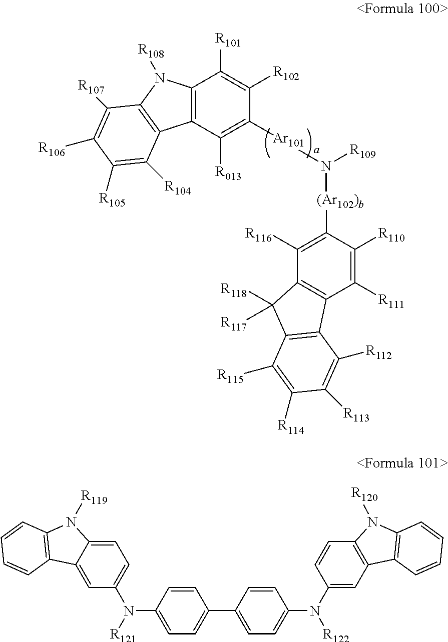

In Formula 100, Ar₁₀₁ and Ar₁₀₂ may be each independently a substituted or unsubstituted C₆-C₄₀ arylene group. In some embodiments, Ar₁₀₁ and Ar₁₀₂ may be each independently one of a phenylene group, a pentalenylene group, an indenylene group, a naphthylene group, an azulenylene group, a heptalenylene group, a substituted or unsubstituted acenaphthylene group, a fluorenylene group, a pentalenylene group, a phenanthrenylene group, an anthrylene group, a fluoranthenylene group, a triphenylenylene group, a pyrenylene, group, a chrysenylene group, a naphthacenylene group, a picenylene group, a perylenylene group, or a pentacenylene group; or a phenylene group, a pentalenylene group, an indenylene group, a naphthylene group, an azulenylene group, a heptalenylene group, a substituted or unsubstituted acenaphthylene group, a fluorenylene group, a pentalenylene group, a phenanthrenylene group, an anthrylene group, a fluoranthenylene group, a triphenylenylene group, a pyrenylene group, a chrysenylene group, a naphthacenylene group, a picenylene group, a perylenylene group, or a pentacenylene group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₄₀ alkyl group, a C₂-C₄₀ alkenyl group C₂-C₄₀ alkynyl group, a C₁-C₄₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₄₀ aryl group, a C₆-C₄₀ aryloxy group, a C₆-C₄₀ arylthio group, or a C₂-C₄₀ heteroaryl group.

In Formula 100, a and b may be each independently an integer from 0 to 5, for example, 0, 1, or 2. For example, a may be 1, and b may be 0, but a and b are not limited thereto.

In Formulae 100 and 101, R₁₀₁ to R₁₂₂ may be each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₄₀ alkyl group, a substituted or unsubstituted C₂-C₄₀ alkenyl group, a substituted or unsubstituted C₂-C₄₀ an alkynyl group, a substituted or unsubstituted C₁-C₄₀ alkoxy group, a substituted or unsubstituted C₃-C₄₀ cycloalkyl group, a substituted or unsubstituted C₆-C₄₀ aryl group, a substituted or unsubstituted C₆-C₄₀ aryloxy group, or a substituted or unsubstituted C₆-C₄₀ arylthio group.

In some other embodiments, R₁₀₁ to R₁₀₈, and R₁₁₀ to R₁₂₂ may be each independently one of a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, a hexyl group, or the like), a C₁-C₁₀ alkoxy group (for example, a methoxy group, an ethoxy group, a propoxy group, a butoxy group, a pentoxy group, or the like), a phenyl group, a naphthyl group, an anthryl group, a fluorenyl group, or a pyrenyl group; or a C₁-C₁₀ alkyl group, a C₁-C₁₀ alkoxy group, a phenyl group, a naphthyl group, an anthryl group, a fluorenyl group, or a pyrenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof, but are not limited thereto.

In Formula 100, R₁₀₉ may be one of a phenyl group, a naphthyl group, an anthryl group, a biphenyl group, a pyridyl group; or a phenyl group, a naphthyl group, an anthryl group, a biphenyl group, or a pyridyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₂₀ alkyl group, or a substituted or unsubstituted C₁-C₂₀ alkoxy group.

In some embodiments, the compound of Formula 100 may be a compound represented by Formula 100A below, but the compound of Formula 100 is not limited thereto:

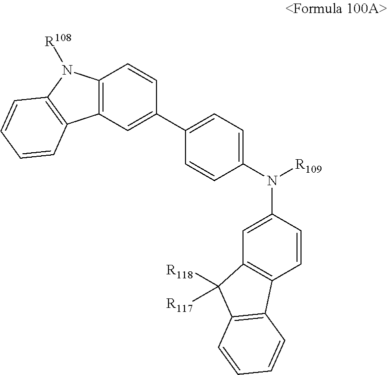

In Formula 100A, R₁₀₈, R₁₀₉, R₁₁₇, and R₁₁₈ are as defined above.

In some embodiments, at least one of the HIL, HTL, or hole injection and transport layer may include at least one of the compounds represented by Formulae 102 to 121 below, but the HIL, HTL, or hole injection and transport layer are not limited thereto:

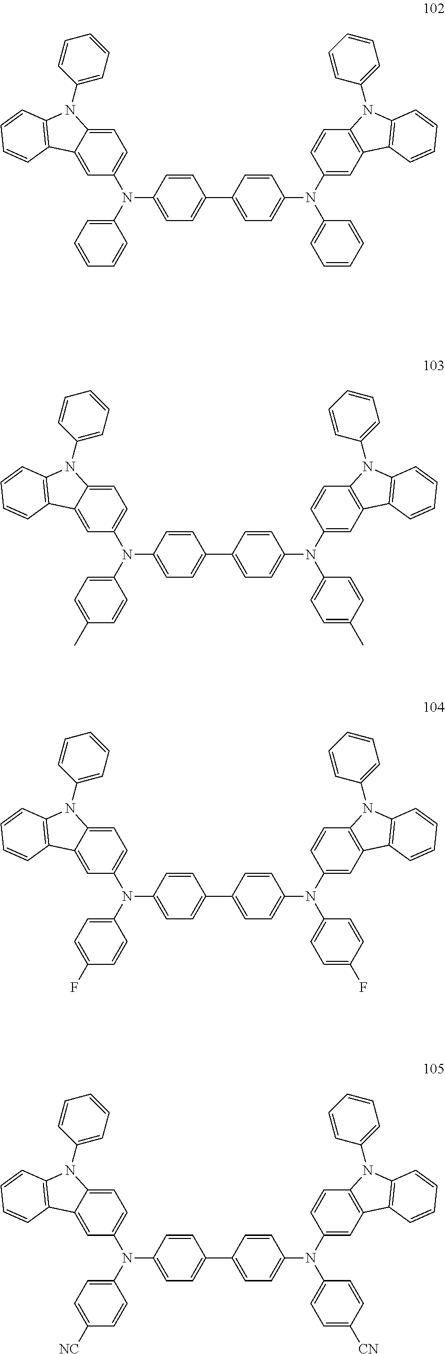 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

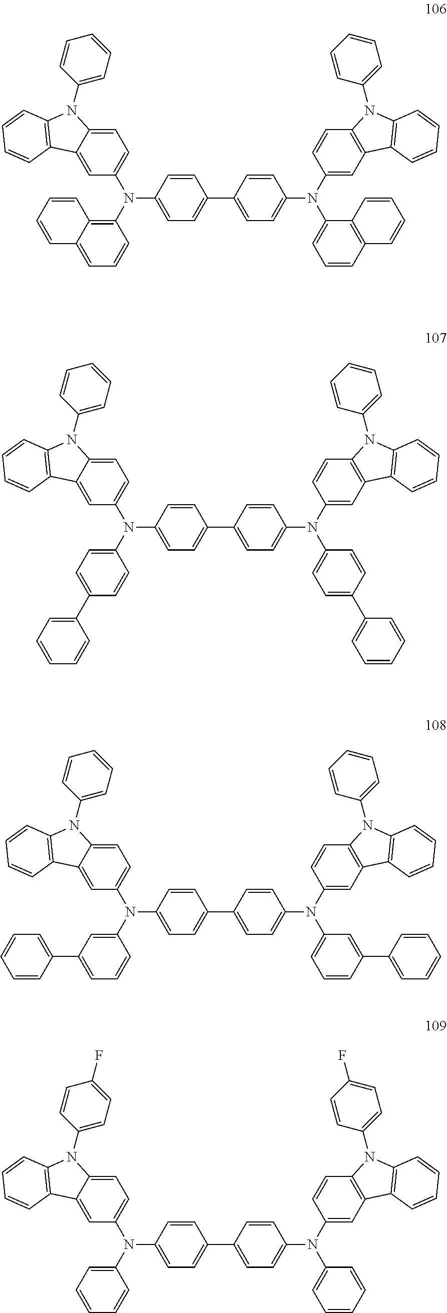 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

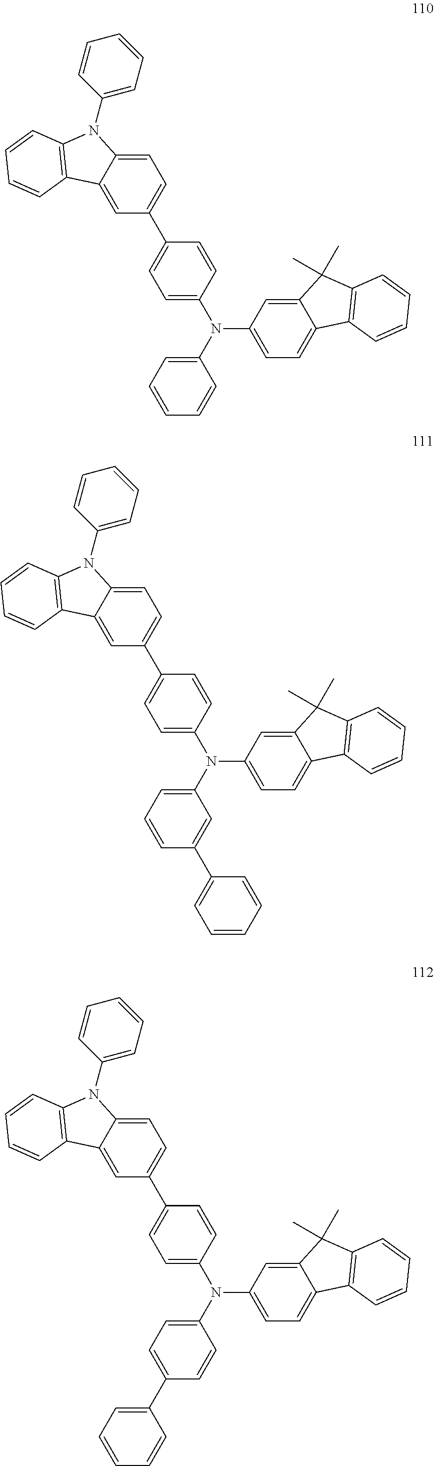 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

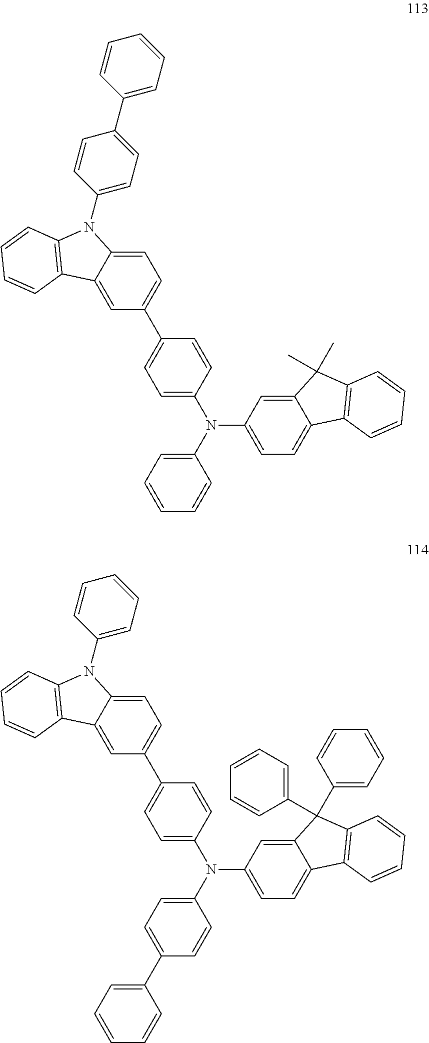 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

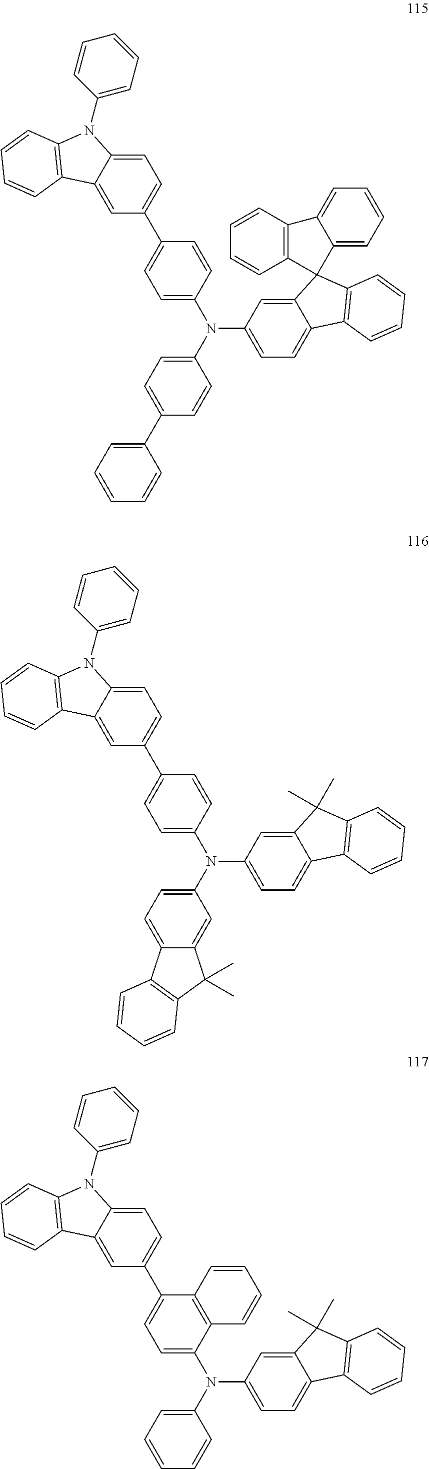 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

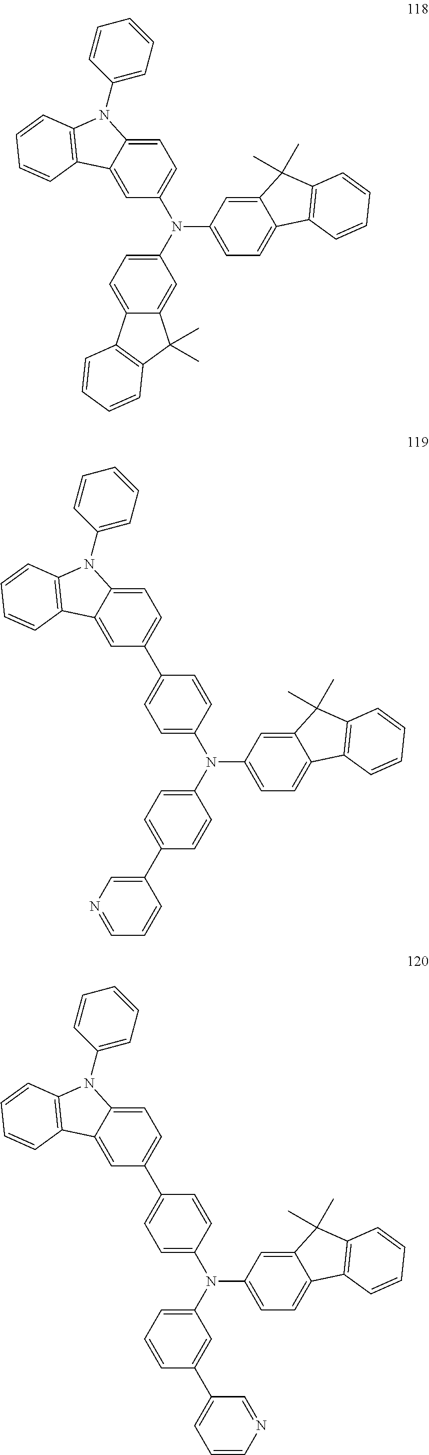 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

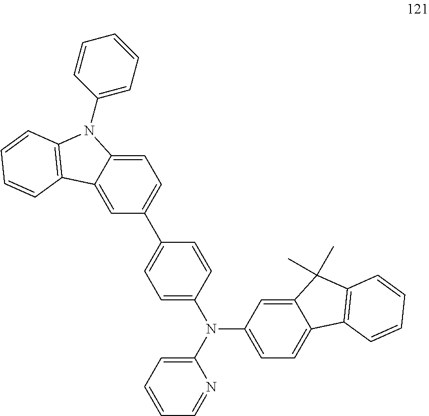 [SMILES: CC1(C)c2ccccc2-c2ccc(N(c3ccc(-c4ccc5c(c4)c4ccccc4n5-c4ccccc4)cc3)c3ccccn3)cc21]

In addition to a known hole injecting material, hole transport material, and/or material having both hole injection and hole transport capabilities as described above, at least one of the HIL, HTL, or hole injection and transport layer may further include a charge-generating material for improved layer conductivity. The charge-generating material may be, for example, a p-dopant. Non-limiting examples of the p-dopant include quinone derivatives such as tetracyanoquinonedimethane (TCNQ), 2,3,5,6-tetrafluoro-tetracyano-1,4-benzoquinonedimethane (F4TCNQ), and the like; metal oxides such as tungsten oxide, molybdenum oxide, and the like; and cyano-containing compounds such as Compound 200 below.

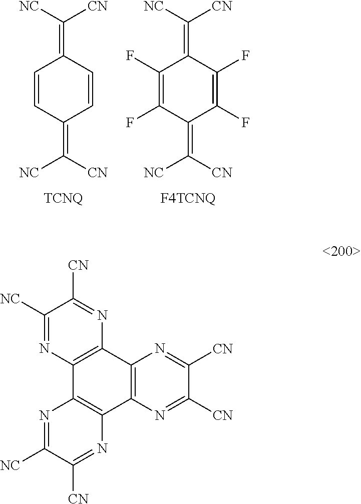

When the hole injection layer, the hole transport layer, or the hole injection and transport layer further includes a charge generating material, the charge generating material may be, but is not limited to being, homogeneously dispersed or inhomogeneously distributed in the layer.

A buffer layer may be disposed between at least one of the HIL, HTL or hole injection and transport layer, and the EML. The buffer layer may compensate for an optical resonance distance of light according to a wavelength of the light emitted from the EML, and thus may increase efficiency. The buffer layer may include any known hole injecting material or hole transporting material. In some other embodiments, the buffer layer may include the same material as one of the materials included in the HIL, HTL, or hole injection and transport layer.

Then, an EML may be formed on the HTL, hole injection and transport layer, or buffer layer by vacuum deposition, spin coating, casting, Langmuir-Blodget (LB) deposition, or the like. When the EML is formed using vacuum deposition or spin coating, the deposition or coating conditions may be similar to those for the formation of the HIL, though the conditions for deposition or coating may vary according to the material that is used to form the EML.

The EML, may be formed using at least one of the condensed cyclic compounds of Formula 1 above or known light-emitting materials (including hosts and dopants). When it includes the condensed cyclic compound of Formula 1 above, the EML may further include a known phosphorescent host, fluorescent host, phosphorescent dopant, or fluorescent dopant (in addition to the condensed cyclic compound of Formula 1 above). The condensed cyclic compound Formula 1 above may serve as a fluorescent host or a phosphorescent host.

The condensed cyclic compound of Formula 1 above may be used as a host. In another embodiment, a known host may be used. Non-limiting examples of known hosts include Alq₃ (tris(8-quinolinorate)aluminum), CBP (4,4′-N,N′-dicarbazole-biphenyl), PVK (poly(n-vinylcarbazole), ADN (9,10-di(naphthalene-2-yl)anthracene), TCTA, TPBI ((1,3,5-tris(N-phenylbenzimidazole-2-yl)benzene), TBADN ((3-tert-butyl-9,10-di(naphth-2-yl) anthracene), DSA (distyrylarylene), E3, dmCBP (see the following formula), and Compounds 301 to 309 below.

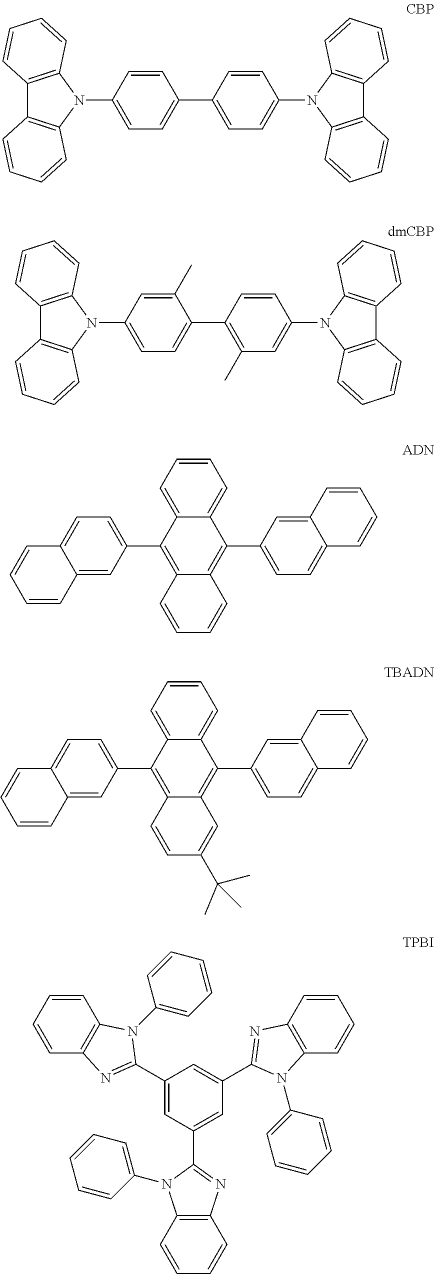

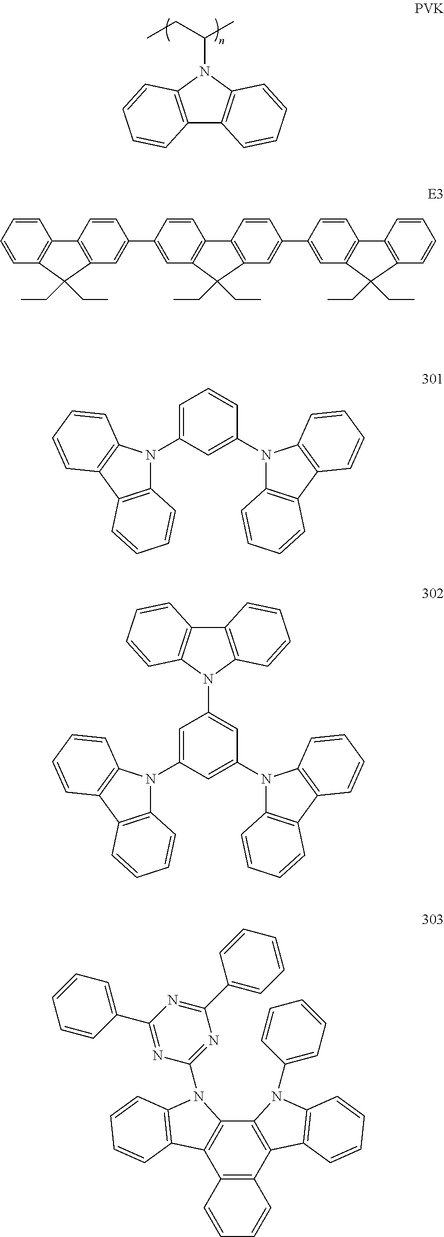

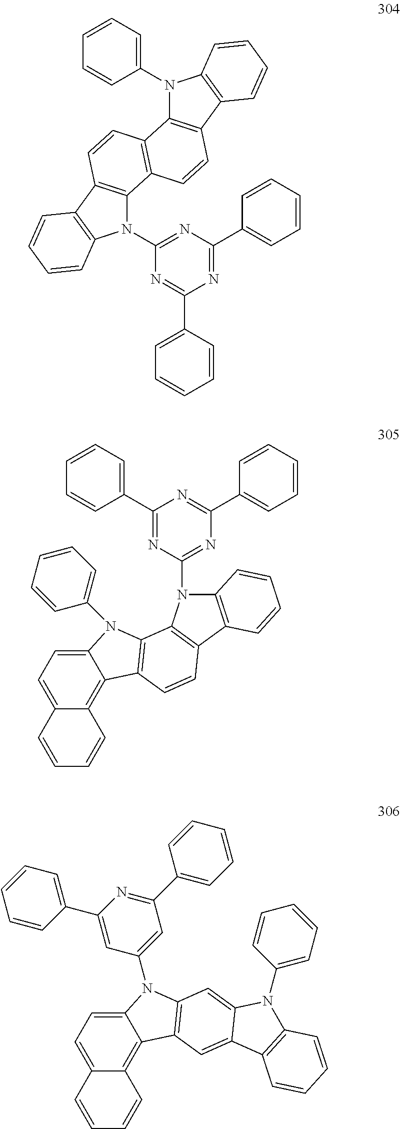 [SMILES: c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1 ; c1ccc(-c2cc(-n3c4cc5c(cc4c4c6ccccc6ccc43)c3ccccc3n5-c3ccccc3)cc(-c3ccccc3)n2)cc1]

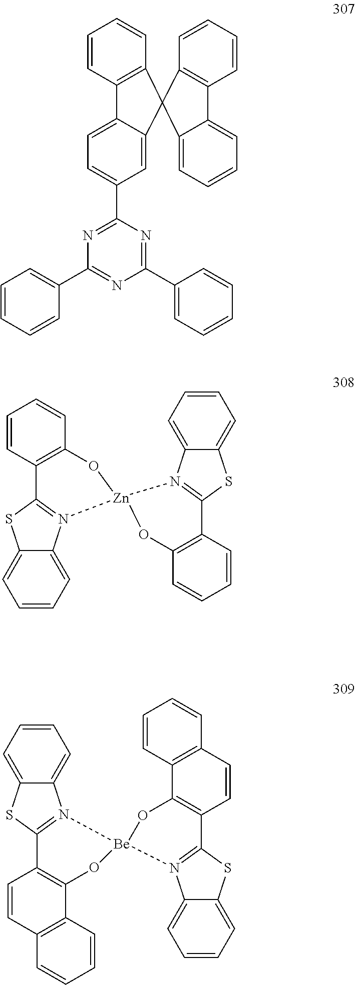

In some embodiments, an anthracene-based compound represented by Formula 400 below may be used as the host.

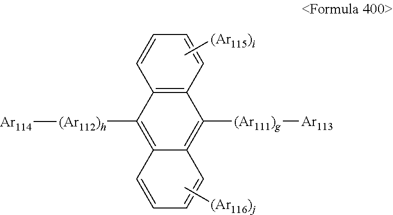

In Formula 400, Ar₁₁ and Ar₁₁₂ may be each independently a substituted or unsubstituted C₆-C₆₀ arylene group. Ar₁₁₃ to Ar₁₁₆ may be each independently a substituted or unsubstituted C₁-C₁₀ alkyl group, or a substituted or unsubstituted aryl group, g, h, I, and j may be each independently an integer from 0 to 4.

In some embodiments, Ar₁₁₁ and Ar₁₁₂ in Formula 400 may be each independently a phenylene group, a naphthylene group, a phenanthrenylene group, or a pyrenylene group; or a phenylene group, a naphthylene group, a phenanthrenylene group, a fluorenyl group, or a pyrenylene group substituted with at least one of a phenyl group, a naphthyl group, or an anthryl group.

In Formula 400 above, g, h, i, and j may be each independently 0, 1, or 2.

In some embodiments, Ar₁₁₃ to Ar₁₁₆ in Formula 400 may be each independently one of a C₁-C₁₀ alkyl group substituted with at least one of a phenyl group, a naphthyl group, or an anthryl group; a phenyl group; a naphthyl group; an anthryl group; a pyrenyl group; a phenanthrenyl group; a fluorenyl group; a phenyl group, a naphthyl group, an anthryl group, a pyrenyl group, a phenanthrenyl group, or a fluorenyl group substituted with at least one of a deuterium atom, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a pyrenyl group, a phenanthrenyl group, a fluorenyl group, or

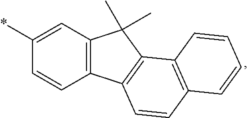 [SMILES: *c1ccc2c(c1)C(C)(C)c1c-2ccc2ccccc12]

but Ar₁₁₃ to Ar₁₁₆ are not limited thereto.

For example, the anthracene-based compound of Formula 400 above may be one of the compounds represented by the following formulae, but the anthracene-based compound of Formula 400 above is not limited thereto:

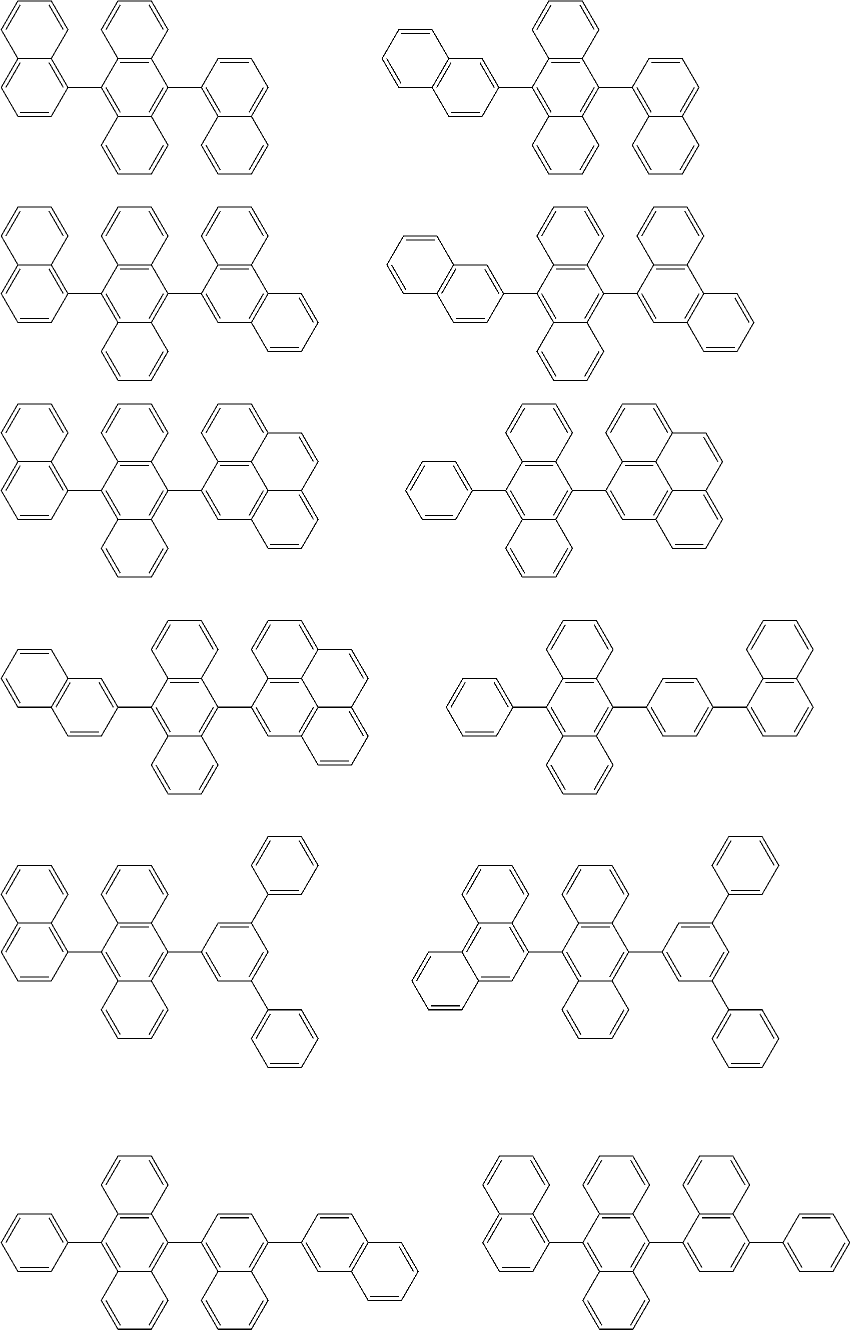

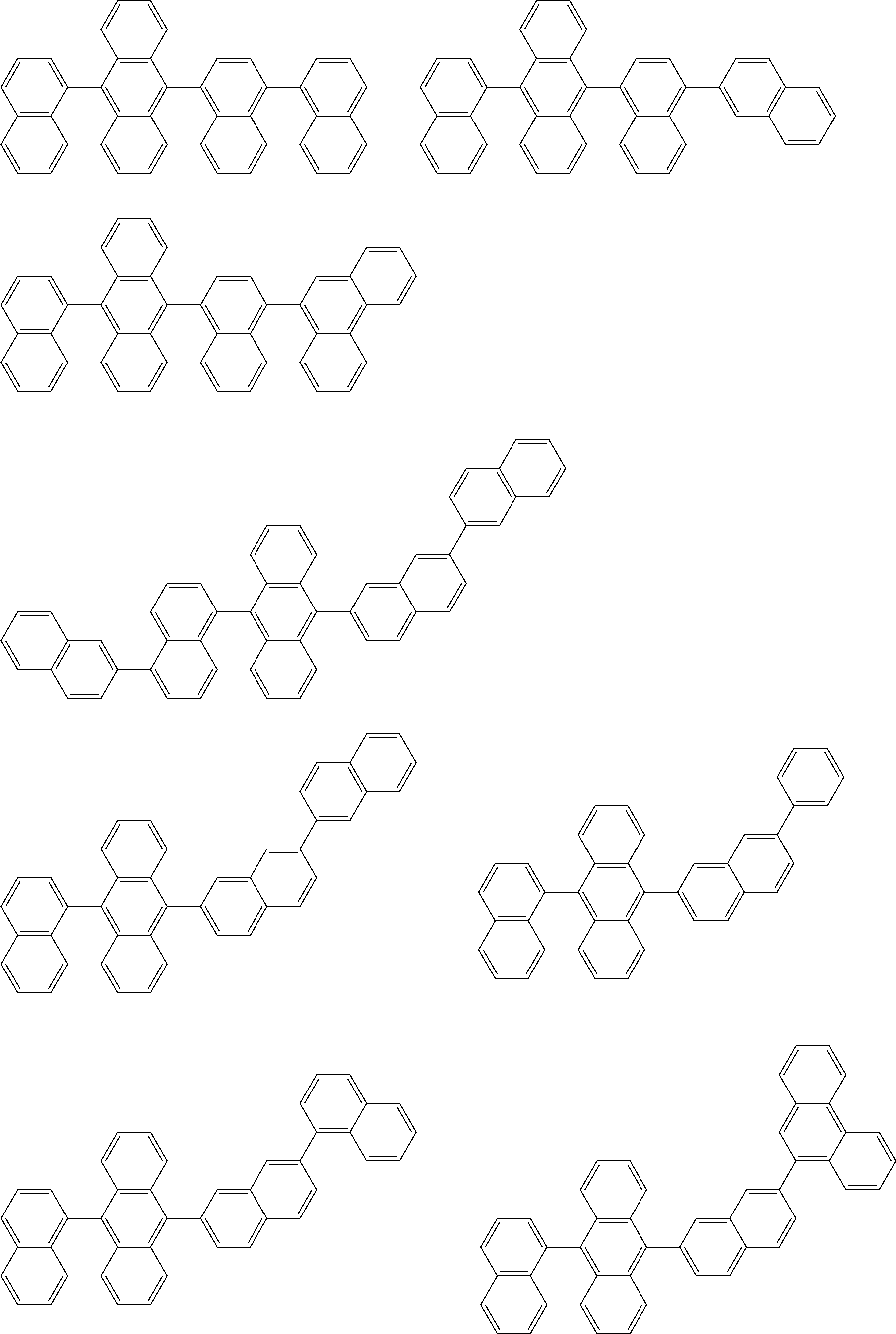

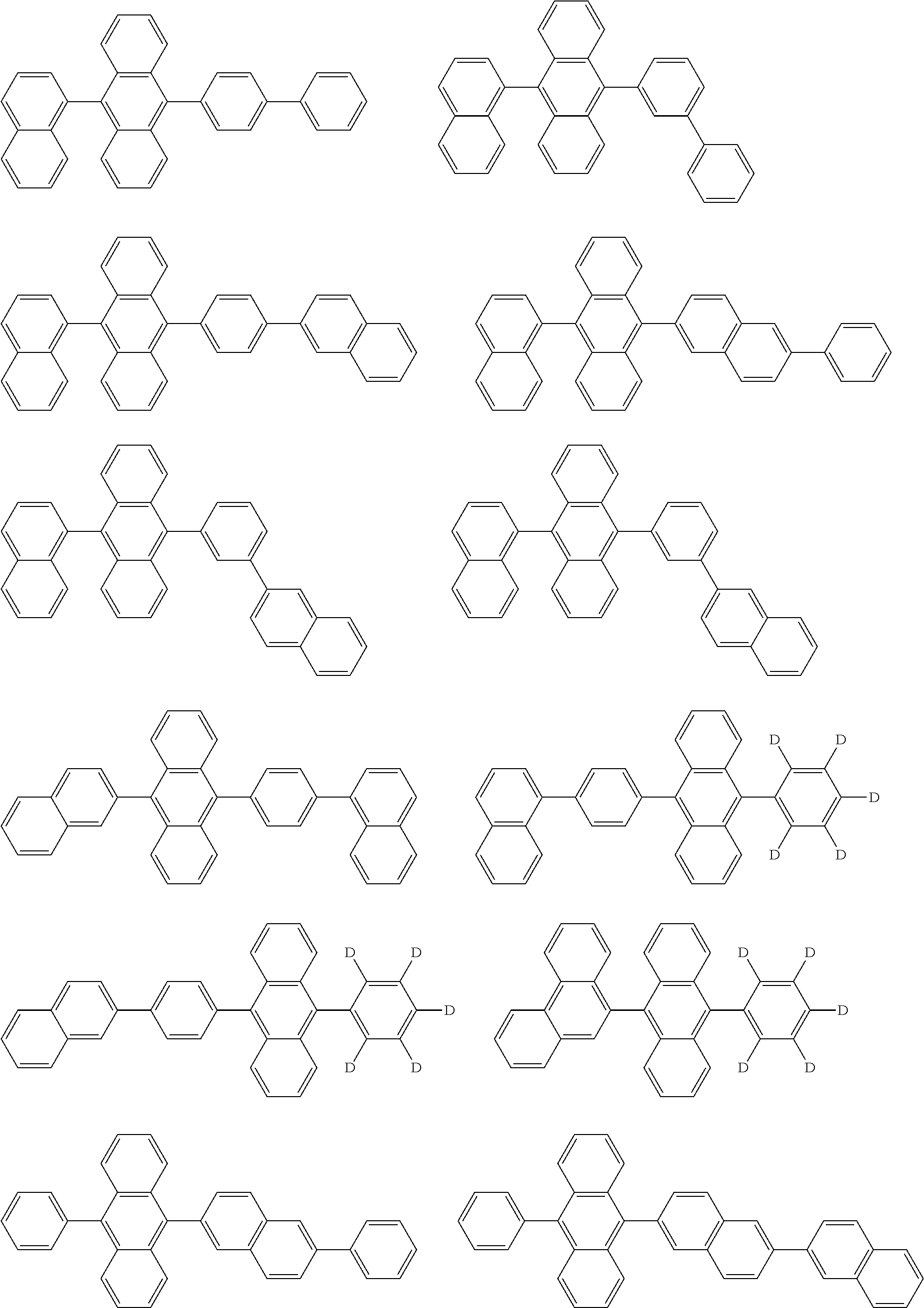

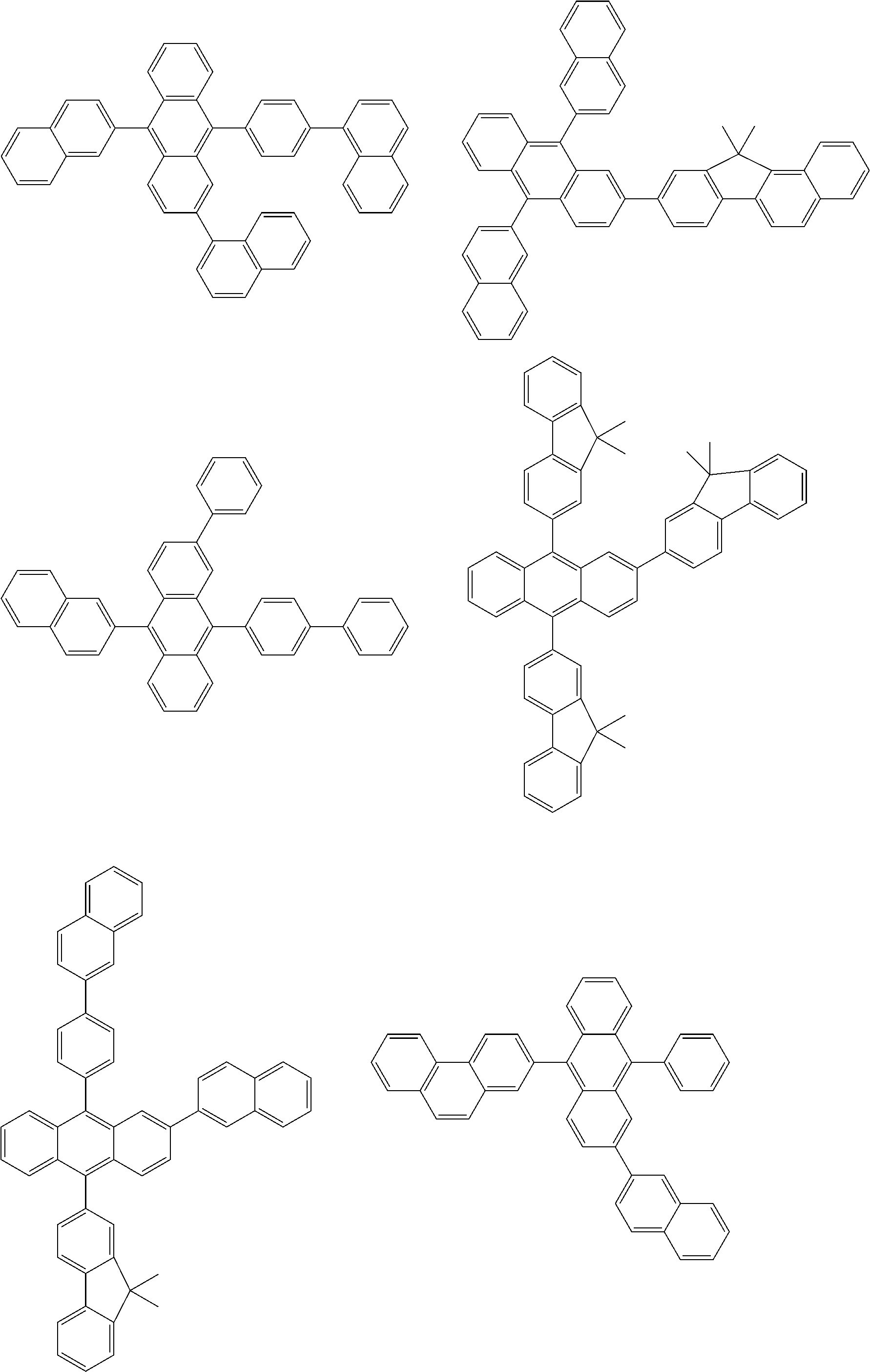

In some embodiments, an anthracene-based compound represented by Formula 401 below may be used as the host.

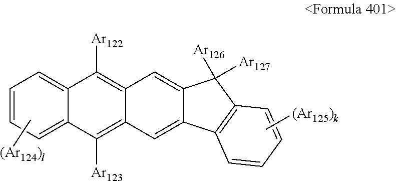

Ar₁₂₂ to Ar₁₂₅ in Formula 401 above are as described above in connection with Ar₁₁₃ of Formula 400.

Ar₁₂₆ and Ar₁₂₇ in Formula 401 above may be each independently a C₁-C₁₀ alkyl group, for example, a methyl group, an ethyl group, or a propyl group.

In Formula 401, k and I may be each independently an integer from 0 to 4, for example, 0, 1, or 2.

For example, the anthracene compound of Formula 401 above may be one of the compounds represented by the following formulae, but is not limited thereto:

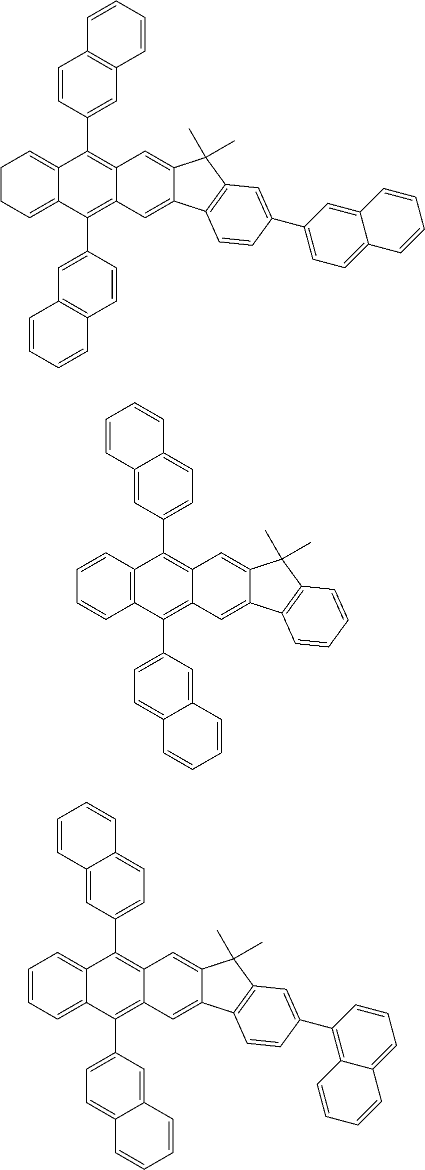

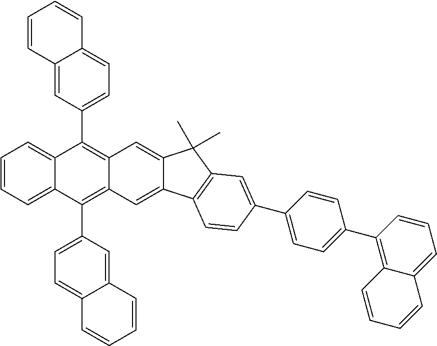 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

The dopant may be any known dopant, for example, at least one of a fluorescent dopant and a phosphorescent dopant may be used. For example, the phosphorescent dopant may include, but is not limited to, an organometallic complex including at least one selected from iridium (Ir), platinum (Pt), osmium (Os), rhenium (Re), titanium (Ti), (zirconium (Zr), hafnium (Hf), and a combination of at least two thereof.

Non-limiting examples of known blue dopants include the following compounds, including F₂Irpic (bis[3,5-difluoro-2-(2-pyridyl)phenyl](picolinato)iridium(III)), (F₂ppy)₂Ir(tmd), Ir(dfppz)₃, DPVBi (4,4′-bis(2,2′-diphenylethen-1-yl)biphenyl), DPAVBi (4,4′-bis[4-(diphenylamino)styryl]biphenyl), and TBPe (2,5,8,11-tetra-tert-butyl perylene).

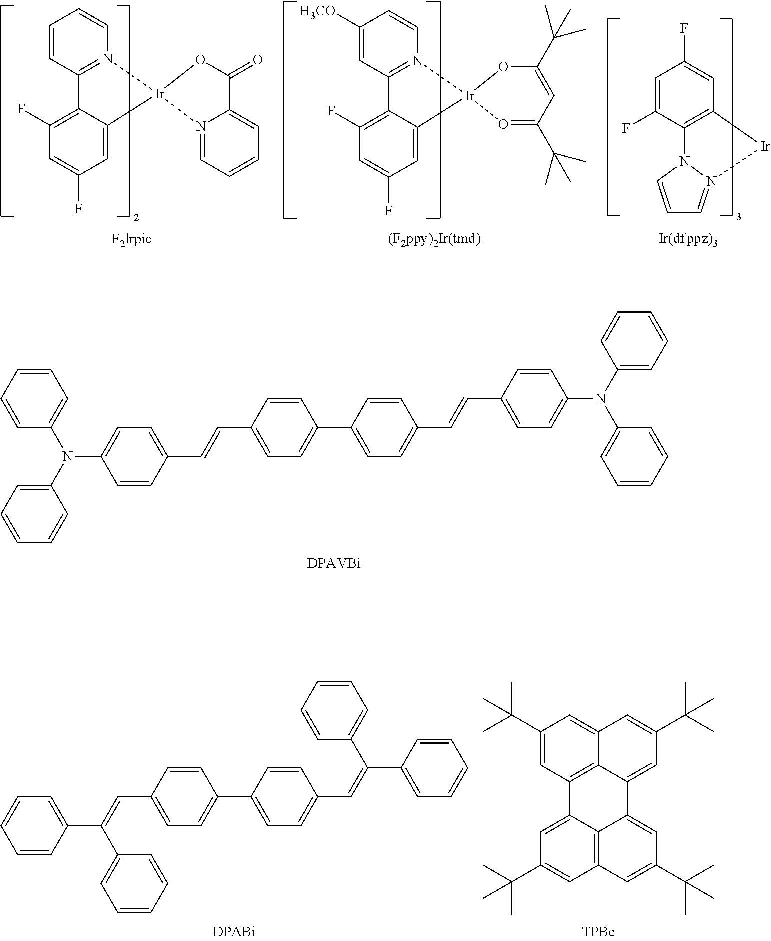

Non-limiting examples of known blue dopants include compounds represented by the following formulae.

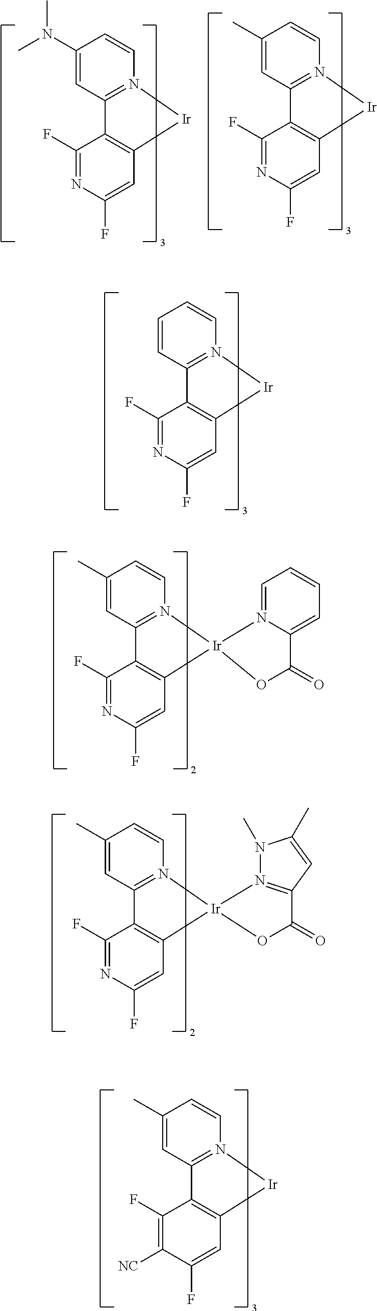

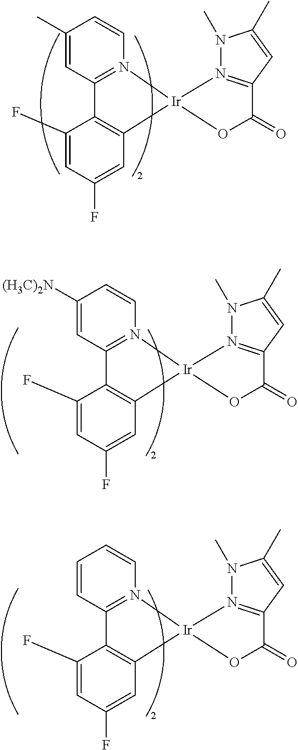

Non-limiting examples of known red dopants include PtOEP (Pt(II) octaethylporphine), Ir(piq)₃ (tris(2-phenylisoquinoline)iridium), Btp₂Ir(acac) (bis(2-(2′-benzothienyl)-pyridinato-N,C3′)iridium(acetylacetonate)), DCM (4-(dicyanomethylene)-2-methyl-6-[p-(dimethylamino)styryl]4H-pyran). DCJTB (4-(dicyanomethylene)-2-tert-butyl-6-(1,1,7,7,-tetramethyljulolidyl-9-enyl)-4H-pyran).

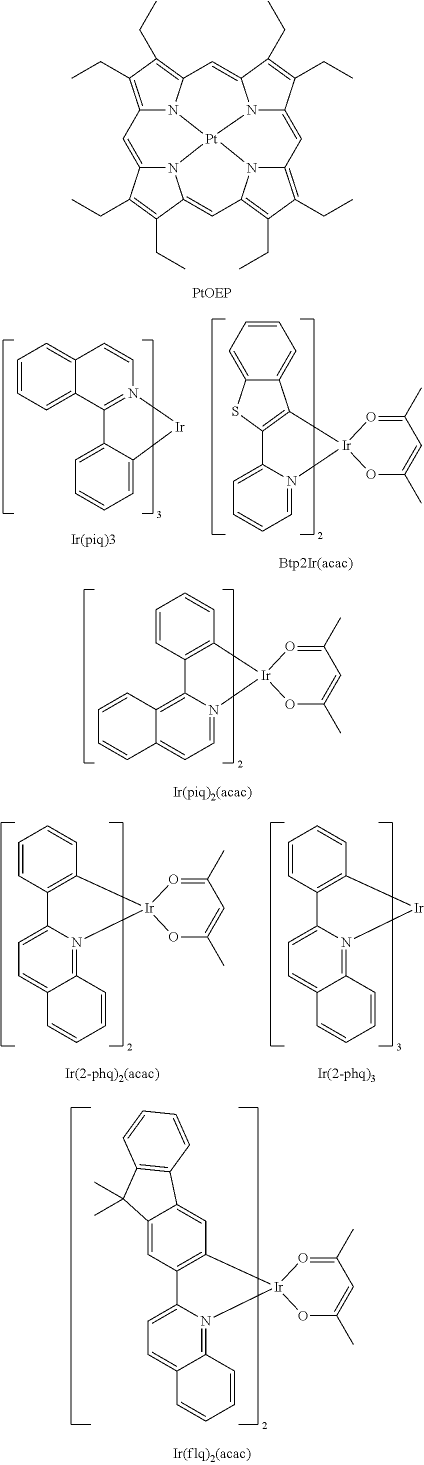

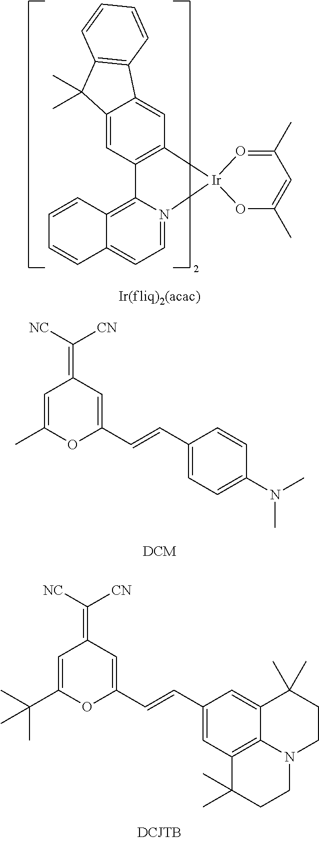

Non-limiting examples of known green dopants include Ir(ppy)₃ (tris(2-phenylpyridine)iridium), Ir(ppy)₂(acac) (bis(2-phenylpyridine)(acetylacetonato)iridium(III), Ir(mppy)₃ (tris(2-(4-tolyl)phenylpiridine)iridium), and C545T (10-(2-benzothiazolyl)-1,1,7,7-tetramethyl-2,3,6,7-tetrahydro-1H,5H,11H-[1]benzopyrano[6,7,8-ij]-quinolizin-11-one).

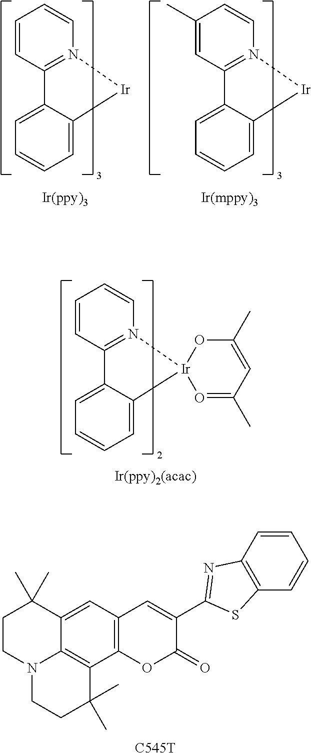

Non-limiting examples of the depart that may be used in the EML include Pt complexes represented by the following formulae.

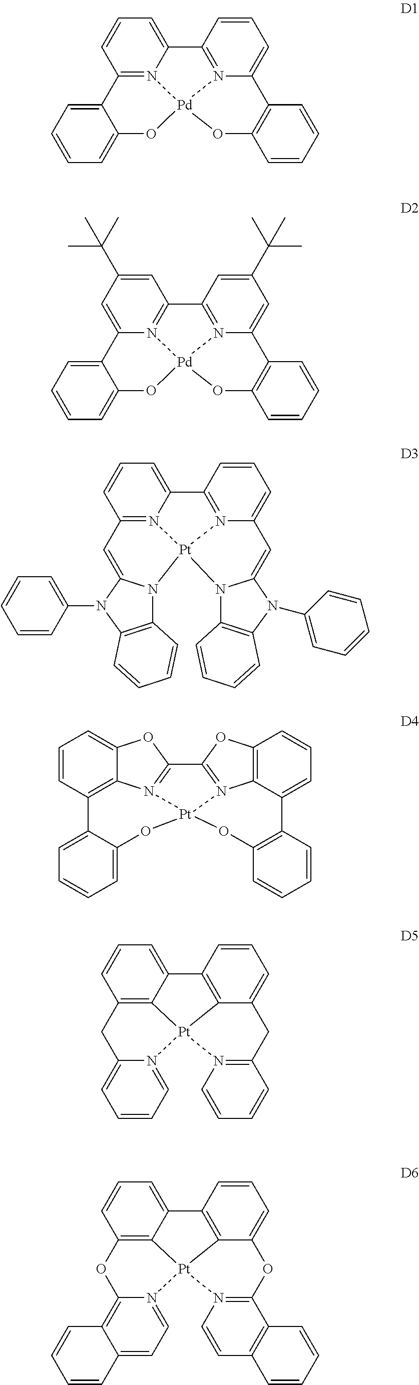

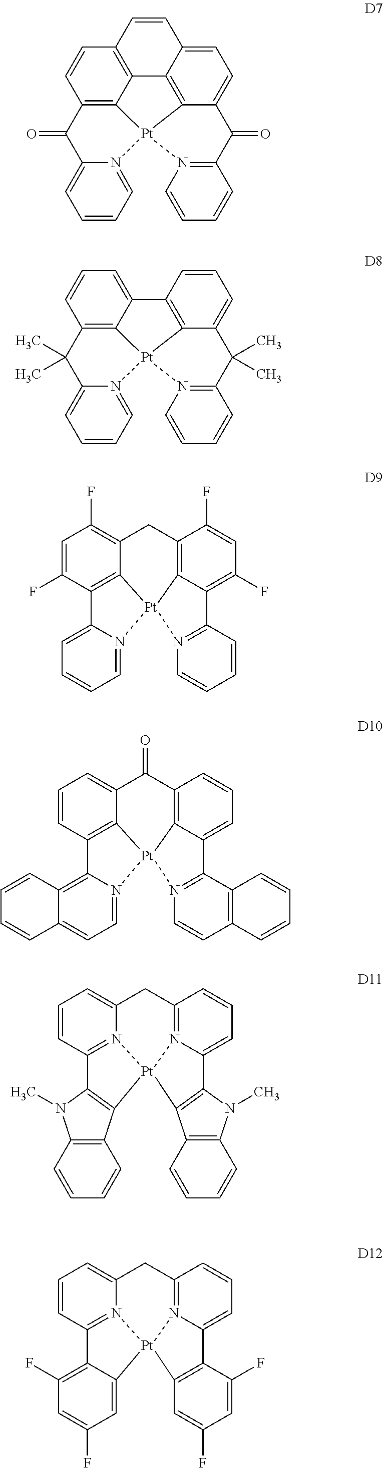

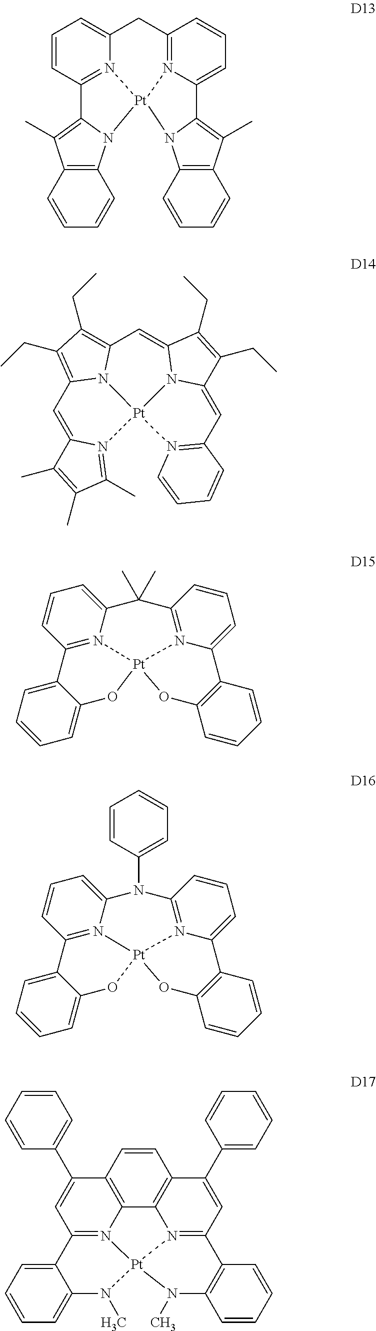

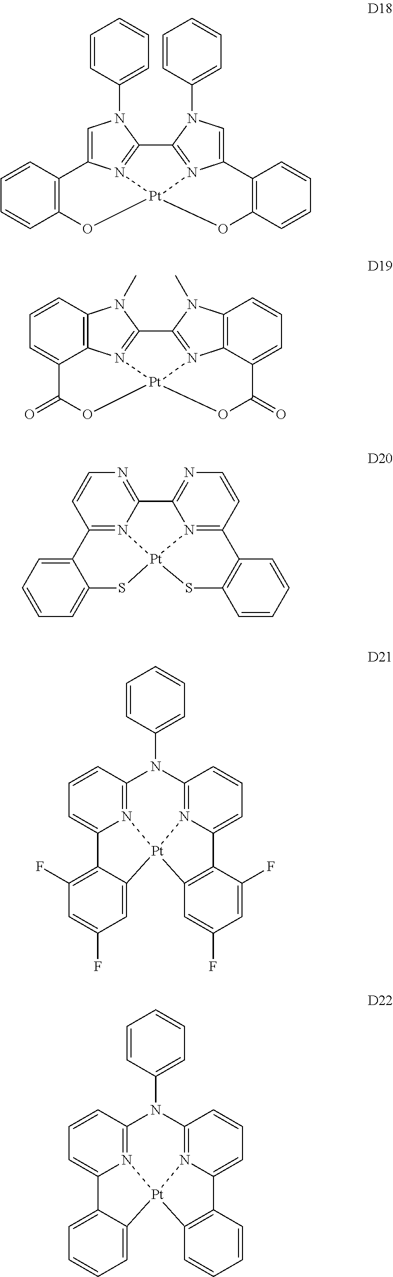

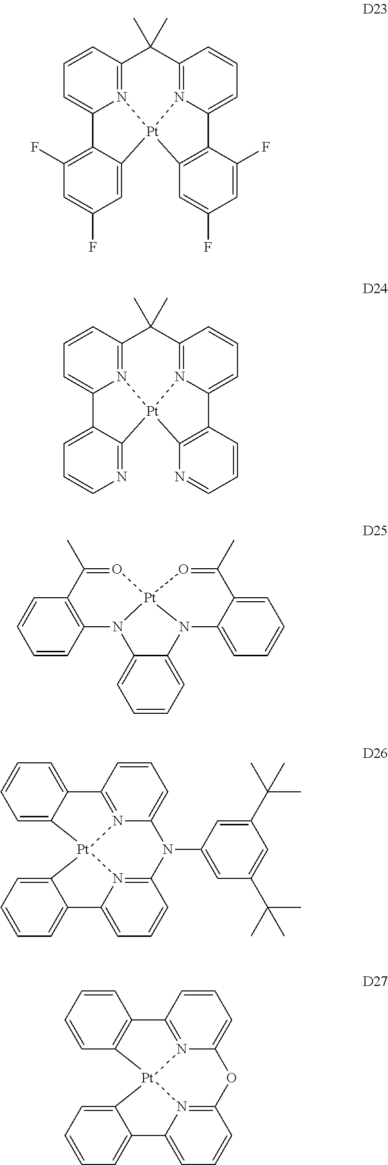

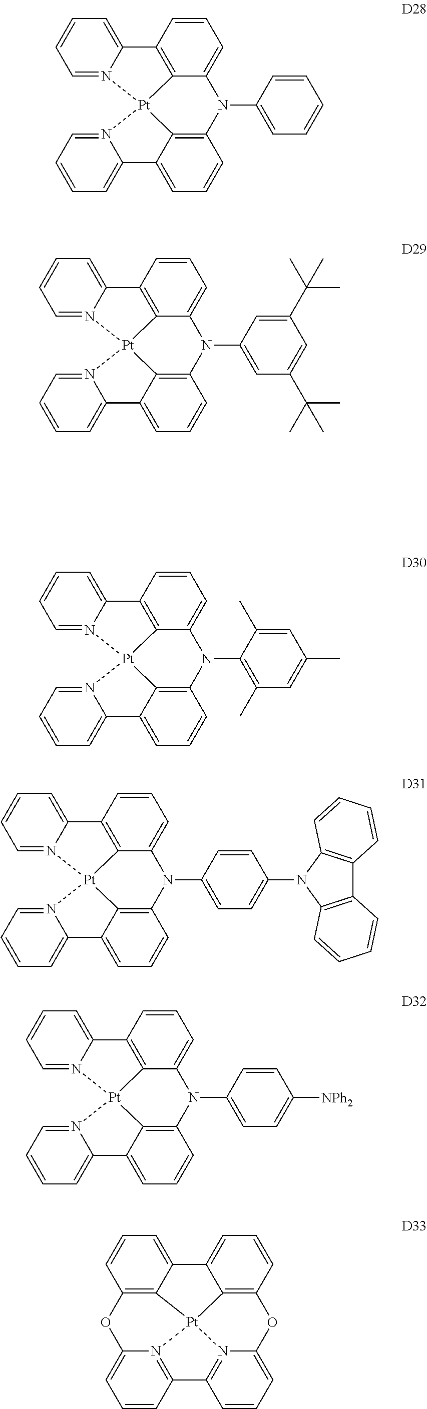

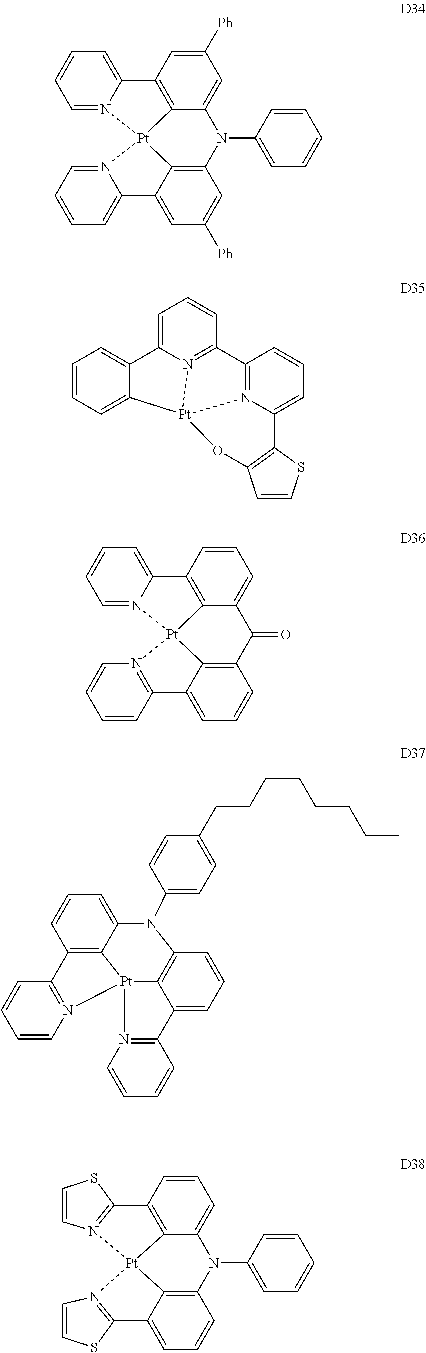

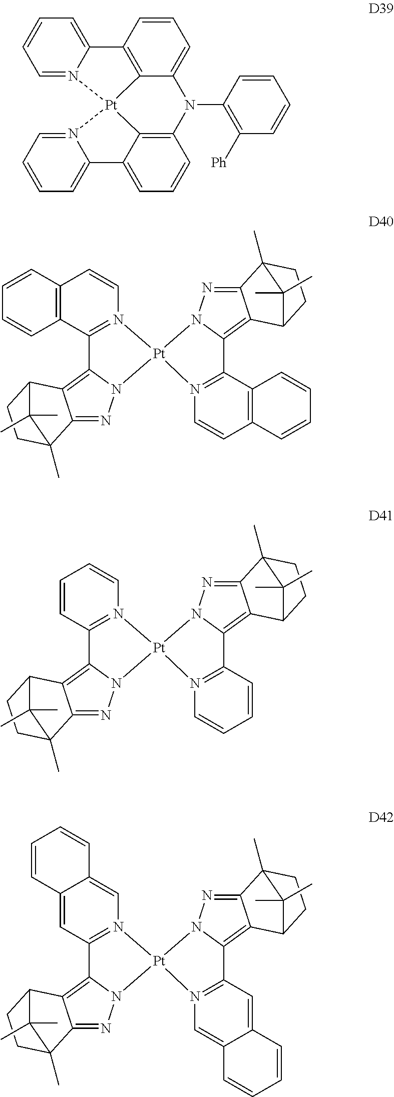

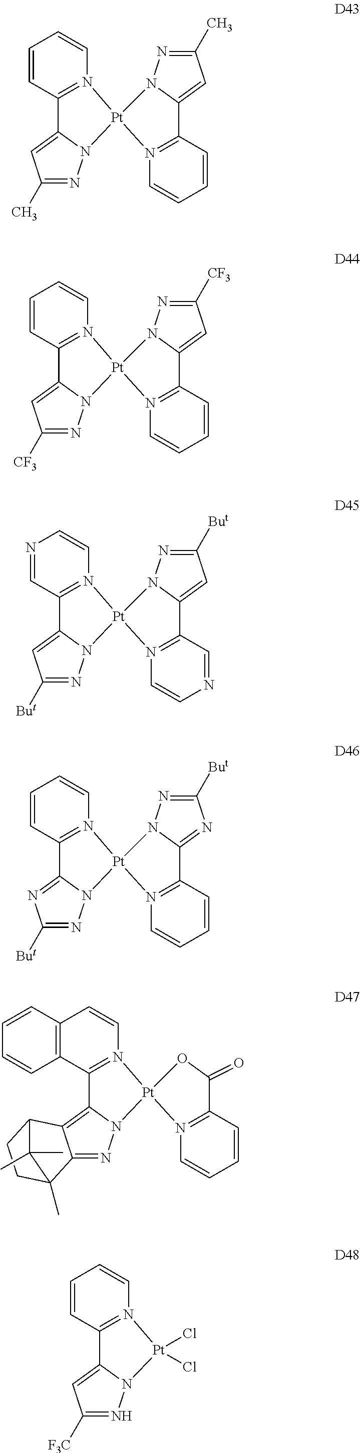

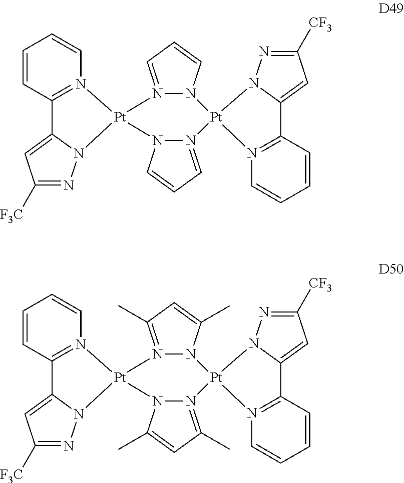

Non-limiting examples of the dopant that may be used in the EML include Os complexes represented by the following formulae.

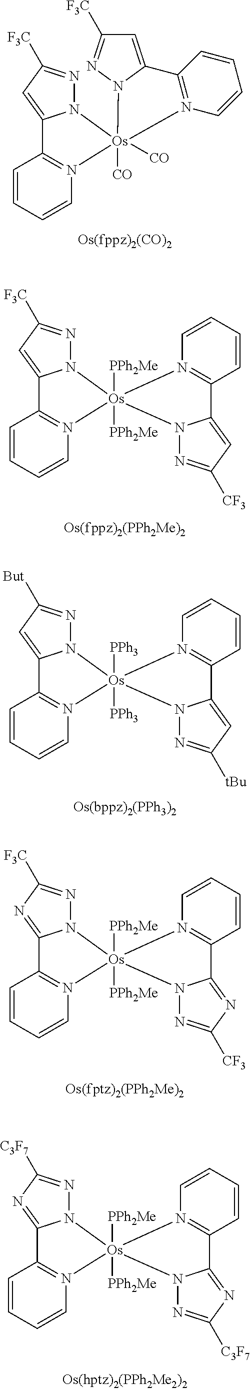

When the EML includes both a host and a dopant, the amount of the dopant may be from about 0.01 to about 15 parts by weight based on 100 parts by weight of the host. However, the amount of the dopant is not limited to this range.

The thickness of the EML may be from about 100 Å to about 1000 Å, and in some embodiments, may be from about 200 Å to about 600 Å. When the thickness of the EML is within these ranges, the EML may have good light emitting ability without a substantial increase in driving voltage.

To prevent diffusion of triplet excitons or holes into the ETL, a HBL may be formed between the HTL and the EML by vacuum deposition, spin coating, casting, Langmuir-Blodgett (LB) deposition, or the like. When the HBL is formed using vacuum deposition or spin coating, the conditions for deposition or coating may be similar to those for the formation of the HIL, although the conditions for deposition or coating may vary according to the material that is used to form the HBL. Any known hole-blocking material may be used. Non-limiting examples of hole-blocking materials include oxadiazole derivatives, triazole derivatives, and phenanthroline derivatives. For example, BCP may be used as a material for forming the HBL.

The thickness of the HBL may be from about 50 Å to about 1000 Å, and in some embodiments, from about 100 Å to about 300 Å. When the thickness of the HBL is within these ranges, the HBL may have improved hole blocking ability without a substantial increase in driving voltage.

Then, an ETL may be formed on the HBL or EML by vacuum deposition, spin coating, casting, or the like. When the ETL is formed using vacuum deposition or spin coating, the deposition or coating conditions may be similar to those for the formation of the HIL, though the deposition or coating conditions may vary according to the material that is used to form the ETL. As a material for forming the ETL, the condensed cyclic compound of Formula 1 or any known material that may stably transport electrons injected from an electron injecting electrode (cathode) may be used.

Non-limiting examples of known ETL materials include quinoline derivatives, such as Alq₃(tris(8-quinolinolate)aluminum), BCP (2,9-dimethyl-4,7-diphenyl-1,10-phenanthroline), Bphen (4,7-diphenyl-1,10-phenanthroline; 4,7-diphenyl-1,10-phenanthroline), TAZ (3-(4-biphenylyl)-4-phenyl-5-tert-butylphenyl-1,2,4-triazole), NTAZ (4-(Naphthalen-1-yl)-3,5-diphenyl-4H-1,2,4-triazole), tBu-PBD (2-(4-biphenylyl)-5-(4-tert-butylphenyl)-1,3,4-oxadiazole, BAlq (see the following formula), Bebq₂ (beryllium bis(benzoquinolin-10-olate), ADN (9,10-di(naphthalene-2-yl)anthracene), Compound 501, and Compound 502.

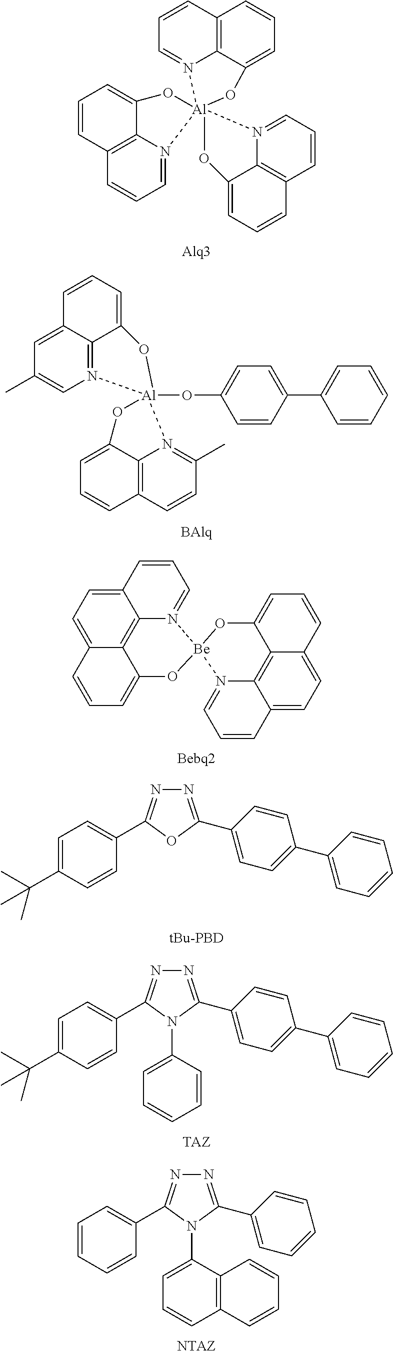

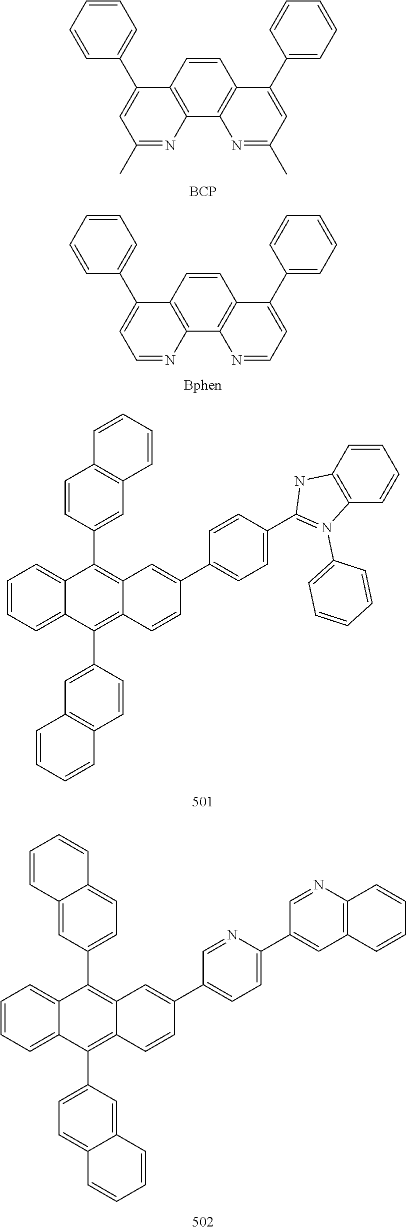

The thickness of the ETL may be from about 100 Å to about 1,000 Å, and in some embodiments, may be from about 150 Å to about 500 Å. When the thickness of the ETL is within these ranges, the ETL may have satisfactory electron transporting ability without a substantial increase in driving voltage.

In some embodiments, the ETL may include an electron-transporting organic compound and a metal-containing material. The metal-containing material may include a lithium (Li) complex. Non-limiting examples of the Li complex include lithium quinolate (LiQ) and Compound 503 below.

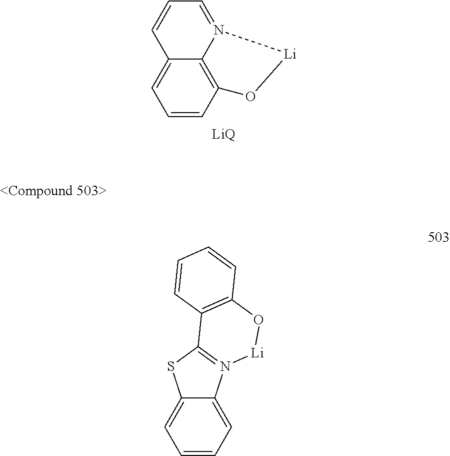

Then, an EIL, which facilitates injection of electrons from the cathode, may be formed on the ETL. Any suitable electron-injecting material may be used to form the EIL.

Non-limiting examples of materials for forming the EIL include LiF, NaCl, CsF, Li₂O, and BaO. The deposition or coating conditions for forming the EIL 18 may be similar to those for the formation of the HIL, though the deposition or coating conditions may vary according to the material that is used to form the EIL 18.

The thickness of the DL may be from about 1 Å to about 100 Å, and in some embodiments, may be from about 3 Å to about 90 Å. When the thickness of the EIL is within these ranges, the EIL may have satisfactory electron injection ability without a substantial increase in driving voltage.

The second electrode 17 is disposed on the organic layer 15. The second electrode 17 may be a cathode that is an electron injection electrode. A material for forming the second electrode 17 may be a metal, an alloy, an electro-conductive compound (which have a low work function), or a mixture thereof. In this regard, the second electrode 9 may be formed of lithium (Li), magnesium (Mg), aluminum (Al), aluminum (Al)-lithium (Li), calcium (Ca), magnesium (Mg)-indium (In), magnesium (Mg)-silver (Ag), or the like. The second electrode may be formed as a thin film type transmission electrode. In some embodiments, to manufacture a top-emission light-emitting device, the transmission electrode may be formed of indium tin oxide (ITO) or indium zinc oxide (IZO).

Hereinafter, the present invention will be described with reference to the following synthesis examples and other examples. However, these examples are presented for illustrative purposes only and are not intended to limit the scope of the present invention.

### SYNTHESIS EXAMPLES

### Synthesis Example 1

### Synthesis of Compound 1

Compound 1 was synthesized according to Reaction Scheme 1 below. Intermediate 1-1 was synthesized according to the method described in Chem. Commun., 2005, 2172-2174, the entire content of which is incorporated herein by reference.

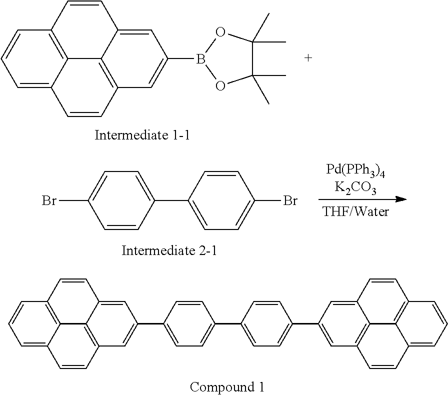

### Synthesis of Compound 1

3.28 g (10.0 mmol) of Intermediate 1-1, 1.55 g (5.0 mmol) of 4,4′-dibromobiphenyl (Intermediate 2-1), 0.29 g (0.25 mmol) of Pd(PPh₃)₄ (tetrakis(triphenylphosphine)palladium(0)), and 2.07 g (15.0 mmol) of K₂CO₃ were mixed with 50 mL of a mixed solution of tetrahydrofuran (THF)/H₂O (2:1 by volume), and then stirred at about 75° C. for about 10 hours. The resultant mixture was cooled to room temperature, followed by three extractions with 30 mL of water and 30 mL of diethylether. The organic layer was collected and dried using magnesium sulfate to evaporate the solvent. The residue was separated and purified by silica gel column chromatography to obtain 2.22 g (Yield 80%) of Compound 1. This compound was identified using fast atom bombardment mass spectroscopy (MS-FAB) and ¹H nuclear magnetic resonance (NMR) spectroscopy.

C₄₄H₂₆: (calc.) 554.20. (found) 554.21.

¹H NMR (CDCl₃, 400 MHz) δ (ppm) 8.30-8.28 (m, 4H), 8.24-8.23 (m, 2H), 8.21-8.19 (m, 2H), 8.10-8.09 (m, 2H), 8.07-8.06 (m, 2H), 8.05 (s, 1H), 8.02 (d, 1H), 7.85-7.83 (m, 2H), 7.82-7.79 (m, 6H), 7.67-7.65 (m, 2H), 7.63-7.61 (m, 2H)

### Synthesis Example 2

### Synthesis of Compound 2

2.21 g of Compound 2 (Yield 84%) was synthesized as in the method of synthesizing Compound 1 of Synthesis Example 1, except that Intermediate 2-2 was used instead of Intermediate 2-1. This compound was identified using MS-FAB and ¹H NMR.

C₄₂H₂₄: (calc.) 528.19. (found) 528.18.

¹H NMR (CDCl₃, 400 MHz) δ (ppm) 8.35-8.32 (m, 4H), 8.26-8.24 (m, 2H), 8.23-8.21 (m, 2H), 8.20-8.18 (m, 2H), 8.09-8.08 (m, 2H), 8.07-8.06 (m, 2H), 8.05-8.04 (m, 1H), 8.03-8.01 (m, 3H), 7.99-7.96 (m, 2H), 7.88-7.86 (m, 2H), 7.85-7.83 (m, 2H)

### Synthesis Example 3

### Synthesis of Compound 7

2.10 g of Compound 7 (Yield 87%) was synthesized as in the method of synthesizing Compound 1 of Synthesis Example 1, except that Intermediate 2-7 was used instead of Intermediate 2-1. This compound was identified using MS-FAB and ¹H NMR.

C₃₈H₁₈D₄: (calc.) 482.20. (found) 482.21.

¹H NMR (CDCl₃, 400 MHz) δ (ppm) 8.31-8.29 (m, 4H), 8.24-8.23 (m, 2H), 8.21-8.19 (m, 2H), 8.12-8.10 (m, 2H), 8.08-8.07 (m 2H), 8.06-8.03 (m, 2H), 7.85-7.83 (m, 2H), 7.81-7.79 (m, 2H)

### Synthesis Example 4

### Synthesis of Compound 11

2.31 g of Compound 11 (Yield 78%) was synthesized as in the method of synthesizing Compound 1 of Synthesis Example 1, except that Intermediate 2-11 was instead of Intermediate 2-1 This compound was identified using MS-FAB and ¹H NMR.

C₄₇H₃₀: (calc.) 594.23. (found) 694.23.

¹H NMR (CDCl₃, 400 MHz) δ (ppm) 8.25-8.24 (m, 2H), 8.22-8.21 (m, 2H), 8.20-8.18 (m, 4H), 8.10-8.09 (m, 2H), 8.07-8.06 (m, 2H), 8.05-8.02 (m, 2H), 7.89-7.87 (m, 2H), 7.85-7.84 (m, 2H), 7.78-7.76 (dd, 2H), 7.70-7.67 (m, 2H), 7.62 (d, 1H), 7.59 (d, 1H), 1.56 (s, 6H)

### Synthesis Example 5

### Synthesis of Compound 15

2.76 g of Compound 15 (Yield 77%) was synthesized as in the method of synthesizing Compound 1 of Synthesis Example 1, except that Intermediate 2-15 was used instead of Intermediate 2-1. This compound was identified using MS-FAB and ¹H NMR.

C₅₇H₃₄: (calc.) 718.27. (found) 718.26.

¹H NMR (CDCl₃, 400 MHz) δ (ppm) 8.24-8.20 (m, 8H), 8.11-8.10 (m, 2H), 8.08-8.07 (m, 2H), 8.06-8.03 (m, 2H), 7.93 (d, 1H), 7.91 (d, 1H), 7.88-7.87 (m, 2H), 7.85-7.84 (m, 2H), 7.59 (d, 1H) 7.57 (d, 1H), 7.33-7.25 (m, 4H), 7.22-7.21 (m, 2H), 7.18-7.11 (m, 6H)

### Synthesis Example 6

### Synthesis of Compound 18

2.20 g of Compound 18 (Yield 73%) was synthesized as in the method of synthesizing Compound 1 of Synthesis Example 1, except that Intermediate 2-18 was used instead of Intermediate 2-1. This compound was identified using MS-FAB and ¹H NMR.

C₄₈H₂₆: (calc.) 602.20. (found) 602.19.

¹H NMR (CDCl₃, 400 MHz) δ (ppm) 8.33-8.31 (m, 4H), 8.25-8.24 (m, 2H), 8.22-8.21 (m, 2H), 8.10-8.09 (m, 2H) 8.07-8.06 (m, 2H), 8.04-8.00 (m, 6H), 7.94-7.93 (m, 2H), 7.92-7.90 (m, 2H), 7.89-7.88 (m, 2H), 7.86-7.84 (m, 2H)

### Synthesis Example 7

### Synthesis of Compound 21

2.54 g of Compound 21 (Yield 79%) was synthesized as in the method of synthesizing Compound 1 of Synthesis Example 1, except that Intermediate 2-21 was used instead of Intermediate 2-1. This compound was identified using MS-FAB and ¹H NMR.

C₅₀H₂₉N: (calc.) 643.23. (found) 643.23.

¹H NMR (CDCl₃, 400 MHz) δ (ppm) 8.40-8.39 (m, 4H), 8.25-8.24 (m, 2H), 8.22-8.21 (m, 2H), 8.11-8.10 (m, 2H), 8.07-8.04 (m, 4H), 7.98 (t, 1H), 7.95-7.94 (m, 1H), 7.87-7.86 (m, 2H), 7.85-7.84 (m, 2H), 7.82-7.80 (m, 2H), 7.76 (d, 1H), 7.74 (d, 1H), 7.57-7.50 (m, 4H), 7.33-7.30 (m, 1H)

### Synthesis Example 8

### Synthesis of Compound 22

2.68 g of Compound 22 (Yield 82%) was synthesized as in the method of synthesizing Compound 1 of Synthesis Example 1, except that Intermediate 2-22 was used instead of Intermediate 2-1. This compound was identified using MS-FAB and ¹H NMR.

C₅₂H₃₀: (calc) 654.23. (found) 654.24.

¹H NMR (CDCl₃, 400 MHz) δ (ppm) 8.40-8.37 (m, 3H), 8.31-8.28 (m, 3H), 8.25-8.22 (m, 3H), 8.21-8.20 (m, 2H), 8.17-8.15 (m, 1H), 8.10-8.09 (m, 2H), 8.07-8.06 (m, 2H), 8.04-8.01 (m, 2H), 7.92-7.89 (m, 1H), 7.88-7.83 (m, 5H), 7.82-7.78 (m, 5H), 7.75-7.72 (m, 1H)

### Synthesis Example 9

### Synthesis of Compound 24

2.78 g of Compound 24 (Yield 85%) was synthesized as in the method of synthesizing Compound 1 of Synthesis Example 1, except that Intermediate 2-24 was used instead of Intermediate 2-1. This compound was identified using MS-FAB and ¹H NMR.

C₅₂H₃₀: (calc.) 654.23. (found) 654.22.

¹H NMR (CDCl₃400 MHz) δ (ppm) 8.32-8.30 (m, 4H), 8.24-8.23 (m, 2H), 8.22-8.21 (m, 2H), 8.10-8.09 (m, 2H), 8.08-8.07 (m, 2H), 8.05-8.02 (m, 2H), 7.95-7.94 (m, 2H), 7.92-7.91 (m, 2H), 7.79 (s, 1H) 7.77 (s, 1H) 7.73-7.69 (m, 2H), 7.68-7.65 (m, 4H), 7.06-6.99 (m, 4H)

### Synthesis Example 10

### Synthesis of Compound 25

2.42 g of Compound 25 (Yield 80%) was synthesized as in the method of synthesizing Compound 1 of Synthesis Example 1, except that Intermediate 2-25 was used instead of Intermediate 2-1. This compound was identified using MS-FAB and ¹H NMR.

C₄₈H₂₈: (calc.) 604.22. (found) 604.21.

¹H NMR (CDCl₃, 400 MHz) δ (ppm) 8.36-8.34 (m, 2H), 8.30-8.28 (m, 2H), 826-8.24 (m, 1H), 8.21-8.20 (m, 2H), 8.18-8.17 (m, 2H), 8.13-8.11 (m, 1H), 8.09-8.08 (m, 2H), 8.07-8.06 (m, 2H), 8.05-8.04 (m, 1H), 8.03-8.00 (m, 3H), 7.90-7.88 (m, 2H), 7.85-7.83 (m, 3H), 7.82-7.80 (m, 2H), 7.78-7.76 (m, 2H), 7.73-7.70 (m, 1H)

### Synthesis Example 11

### Synthesis of Compound 28

2.68 g of Compound 28 (Yield 76%) was synthesized as in the method of synthesizing Compound 1 of Synthesis Example 1, except that Intermediate 2-28 was used instead of Intermediate 2-1. This compound was identified using MS-FAB and ¹H NMR.

C₅₆H₃₂: (calc.) 704.25. (found) 704.26.

¹H NMR (CDCl₃, 400 MHz) δ (ppm) 8.41-8.40 (m, 2H), 8.33-8.32 (m, 2H), 8.25-8.24 (m, 2H), 8.22-8.21 (m, 2H), 8.16-8.13 (m, 1H), 8.10-8.06 (m, 4H), 8.04-8.00 (m, 4H), 7.94-7.92 (m, 3H), 7.83-7.80 (m, 2H), 7.58-7.57 (m, 1H), 7.55-7.54 (m, 1H), 7.49-7.45 (m, 3H), 7.41-7.36 (m, 3H), 7.31-7.27 (m, 1H), 7.20-7.16 (m, 1H)

### Synthesis Example 12

### Synthesis of Compound 30

2.66 g of Compound 30 (Yield 75%) was synthesized as in the method of synthesizing Compound 1 of Synthesis Example 1, except that Intermediate 2-30 was used instead of Intermediate 2-1. This compound was identified using MS-FAB and ¹H NMR.

C₅₆H₃₆: (calc.) 710.30. (found) 710.31.

¹H NMR (CDCl₃, 400 MHz) δ (ppm) 8.26-8.25 (m, 2H), 8.24-8.23 (m, 2H), 8.21-8.20 (m, 4H), 8.11-8.10 (m, 2H), 8.08-8.04 (m, 4H), 7.89-7.86 (m, 6H), 7.63-7.60 m, 4H), 7.23-7.21 (m, 2H), 1.65 (s, 12H)

### Synthesis Example 13

### Synthesis of Compound 33

2.45 g of Compound 33 (Yield 73%) was synthesized as in the method of synthesizing Compound 1 of Synthesis Example 1, except that Intermediate 2-33 was used instead of Intermediate 2-1. This compound was identified using MS-FAB and ¹H NMR.

C₅₂H₃₃N: (calc.) 671.26. (found) 671.26.

¹H NMR (CDCl₃, 400 MHz) δ (ppm) 8.99 (d, 1H), 8.31-8.30 (m, 2H), 8.27-8.26 (m, 2H), 8.24-8.23 (m, 2H), 8.21-8.20 (m, 2H), 8.13-8.12 (m, 2H), 8.10-8.08 (m, 2H), 8.06-8.02 (m, 3H), 7.98-7.94 (m, 2H), 7.93-7.91 (m, 2H), 7.87-7.85 (m, 2H), 7.78-7.72 (m, 3H), 7.68-7.66 (m, 1H), 7.58-7.55 (m, 1H), 1.64 (s, 6H)

### Synthesis Example 14

### Synthesis of Compound 34

2.68 g of Compound 34 (Yield 76%) was synthesized as in the method of synthesizing Compound 1 of Synthesis Example 1, except that Intermediate 2-34 was used instead of Intermediate 2-1. This compound was identified using MS-FAB and ¹H NMR.

C₅₀H₂₈O: (calc.) 644.21. (found) 644.20.

¹H NMR (CDCl₃. 400 MHz) δ (ppm) 8.43-8.41 (m, 2H), 8.30-8.28 (m, 2H), 8.25-8.24 (m, 2H), 8.22-8.21 (m, 2H), 8.15-8.12 (m, 1H), 8.10-8.09 (m, 2H), 8.07-8.06 (m, 2H), 8.05-8.02 (m, 2H), 7.96-7.90 (m, 2H), 7.87-7.80 (m, 7H), 7.76-7.73 (m, 2H), 7.71-7.70 (m, 1H), 7.69-7.68 (m, 1H)

### Synthesis Example 15

### Synthesis of Compound 38

2.36 g of Compound 2 (Yield 84%) was synthesized as in the method of synthesizing Compound 1 of Synthesis Example 1, except that Intermediate 2-38 was used instead of Intermediate 2-1. This compound was identified using MS-FAB and ¹H NMR.

C₄₄H₂₄S: (calc.) 584.16. (found) 584.17.

¹H NMR (CDCl₃, 400 MHz) δ (ppm) 8.62-8.59 (m, 1H), 8.39-8.37 (m, 2H), 8.25-8.23 (m, 4H), 8.22-8.21 (m, 2H), 8.14-8.12 (m, 1H), 8.10-8.06 (m, 5H), 8.05-8.01 (m, 2H), 7.99-7.95 (m, 2H), 7.90-7.88 (m, 1H), 7.86-7.85 (m, 2H), 7.83-7.81 (m, 2H)

### Synthesis Example 16

### Synthesis of Compound 40

2.30 g of Compound 40 (Yield 83%) was synthesized as in the method of synthesizing Compound 1 of Synthesis Example 1, except that Intermediate 2-40 was used instead of Intermediate 2-1. This compound was identified using MS-FAB and ¹H NMR.

C₄₄H₂₆: (calc.) 554.20. (found) 554.21.

¹H NMR (CDCl₃, 400 MHz) δ (ppm) 8.34-8.32 (m, 2H), 8.29-8.28 (m, 2H), 8.24-8.23 (m, 2H), 8.21-8.20 (m, 2H), 8.11-8.10 (m, 2H), 8.08-8.07 (m, 2H), 8.06-8.02 (m, 2H), 7.93-7.91 (m, 1H), 7.87-7.83 (m, 6H), 7.81-7.79 (m, 2H), 7.70-7.67 (m, 1H), 7.57-7.54 (m, 1H), 7.27-7.23 (m, 1H)

### Synthesis Example 17

### Synthesis of Compound 43

2.77 g of Compound 43 (Yield 86%) was synthesized as in the method of synthesizing Compound 1 of Synthesis Example 1, except that Intermediate 2-43 was used instead of Intermediate 2-1. This compound was identified using MS-FAB and ¹H NMR.

C₅₀H₂₉N: (calc.) 643.23. (found) 643.22.

¹H NMR (CDCl₃, 400 MHz) δ (ppm) 8.49-8.48 (m, 4H), 8.25-8.24 (m, 2H), 8.22-8.21 (m, 2H), 8.14-8.11 (m, 2H), 8.10-8.09 (m, 2H), 8.07-8.06 (m, 2H), 8.05-8.01 (m, 3H), 7.93-7.92 (m, 2H), 7.90-7.89 (m, 2H), 7.71 (d, 2H), 7.41-7.28 (m, 6H)

### Synthesis Example 18

### Synthesis of Compound 45

2.94 g of Compound 45 (Yield 80%) was synthesized as in the method of synthesizing Compound 1 of Synthesis Example 1, except that Intermediate 2-45 was used instead of Intermediate 2-1. This compound was identified using MS-FAB and ¹H NMR.

C₅₆H₃₆Si: (calc.) 736.26. (found) 736.25.

¹H NMR (CDCl₃, 400 MHz) δ (ppm) 8.24-8.23 (m, 2H), 8.21-8.20 (m, 2H), 8.15-8.14 (m, 4H), 8.09-8.08 (m, 2H), 8.06-8.05 (m, 2H), 8.04-8.01 (m, 2H), 7.85-7.84 (m, 2H), 7.82-7.81 (m, 2H), 7.62-7.58 (m, 4H), 7.54-7.50 (m, 4H), 7.43-7.39 (m, 4H), 7.34-7.29 (m, 4H), 7.27-7.23 (m, 2H)

### Synthesis Example 19

### Synthesis of Compound 48

2.79 g of Compound 48 (Yield 82%) was synthesized as in the method of synthesizing Compound 1 of Synthesis Example 1, except that Intermediate 2-48 was used instead of Intermediate 2-1. This compound was identified using MS-FAB and ¹H NMR.

C₅₄H₃₂: (calc.) 680.25. (found) 680.24.

¹H NMR (CDCl₃. 400 MHz) δ (ppm) 8.30-8.28 (m, 4H), 8.24-8.23 (m, 2H), 8.21-8.20 (m, 2H), 8.09-8.08 (m, 2H), 8.07-8.06 (m, 2H), 8.05-8.01 (m, 2H), 7.87-7.83 (m, 6H), 7.81-7.80 (m, 2H), 7.74-7.69 (m, 8H), 7.10-7.07 (m, 2H)

### Synthesis Example 20

### Synthesis of Compound 51

2.77 g of Compound 51 (Yield 76%) was synthesized as in the method of synthesizing Compound 1 of Synthesis Example 1, except that Intermediate 2-51 was used instead of Intermediate 2-1. This compound was identified using MS-FAB and ¹H NMR.

C₅₈H₃₄: (calc.) 730.27. (found) 730.26.

¹H NMR (CDCl₃, 400 MHz) δ (ppm) 8.31-8.29 (m, 4H), 8.25-8.24 (m, 2H), 8.22-8.21 (m, 2H), 8.09-8.08 (m, 2H), 8.07-8.06 (m, 2H), 8.05-8.02 (m, 2H), 8.01-7.97 (m, 4H), 7.86-7.85 (m, 2H), 7.82-7.81 (m 2H), 7.76-7.61 (m, 8H), 7.32-7.28 (m, 4H)

### Synthesis Example 21

### Synthesis of Compound 53

2.37 g of Compound 53 (Yield 69%) was synthesized as in the method of synthesizing Compound 1 of Synthesis Example 1, except that Intermediate 2-53 was used instead of Intermediate 2-1. This compound was identified using MS-FAB and ¹H NMR.

C₅₄H₂₄D₈: (calc.) 688.30. (found) 688.29.

¹H NMR (CDCl₃, 400 MHz) δ (ppm) 8.30-8.28 (m, 4H), 8.24-8.23 (m, 2H), 8.22-8.21 (m, 2H), 8.12-8.10 (m, 2H), 8.09-8.08 (m, 2H), 8.07-8.06 (m, 2H), 8.05-8.01 (m, 2H), 7.96-7.94 (m, 1H), 7.92-7.91 (m, 1H), 7.85-7.83 (m, 2H), 7.82-7.81 (m, 2H), 7.70-7.68 (m, 1H), 7.65-7.63 (m, 1H)

### Synthesis Example 22

### Synthesis of Compound 57

2.33 g of Compound 57 (Yield 74%) was synthesized as in the method of synthesizing Compound 1 of Synthesis Example 1, except that Intermediate 2-57 was used instead of Intermediate 2-1. This compound was identified using MS-FAB and ¹H NMR.

C₄₉H₂₉N: (calc.) 631.23. (found) 631.22.

¹H NMR (CDCl₃, 400 MHz) δ (ppm) 8.78 (d, 1H), 8.31-8.36 (m, 4H), 8.24-8.23 (m, 2H), 8.22-8.21 (m, 2H), 8.13-8.09 (m, 4H), 8.07-8.06 (m 2H), 8.05-8.02 (m, 2H), 7.97-7.95 (m, 1H), 7.86-7.81 (m, 9H), 7.75-7.71 (m, 2H)

### Synthesis Example 23

### Synthesis of Compound 62

2.75 g of Compound 62 (Yield 81%) was synthesized as in the method of synthesizing Compound 1 of Synthesis Example 1, except that Intermediate 2-62 was used instead of Intermediate 2-1. This compound was identified using MS-FAB and ¹H NMR.

C₅₄H₃₀: (calc.) 678.23. (found) 678.24.

¹H NMR (CDCl₃, 400 MHz) δ (ppm) 8.45-8.42 (m, 8H), 8.24-8.23 (m, 3H), 8.22-8.21 (m, 3H), 8.11-8.09 (m, 3H), 8.07-8.06 (m, 3H), 8.04-8.01 (m, 3H), 7.93-7.91 (m, 6H), 7.88-7.86 (m, 3H)

### Synthesis Example 24

### Synthesis of Compound 64

Compound 64 was synthesized according to Reaction Scheme 1 below:

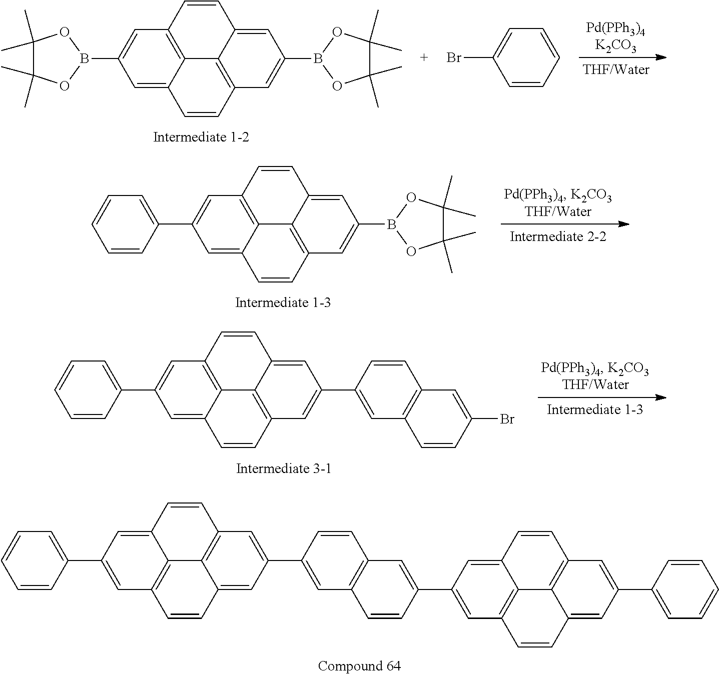

### Synthesis of Intermediate 1-3

Intermediate 1-2 was synthesized according to the method described in Chem. Commun., 2005, 2172-2174, the entire content of which is incorporated herein by reference. 6.81 g (15.0 mmol) of Intermediate 1-2, 2.34 g (15.0 mmol) of bromobenzene, 0.87 g (0.75 mmol) of Pd(PPh₃)₄ (tetrakis(triphenylphosphine)palladium(0)), and 6.21 g (45.0 mmol) of K₂CO₃ were mixed together with 80 mL of a mixed solution of THF/H₂O (2:1 by volume), and then stirred at about 75° C. for about 10 hours. The resultant mixture was cooled to room temperature, followed by three extractions with 40 mL of water and 40 mL of diethylether. The organic layer was collected and dried using magnesium sulfate to evaporate the solvent. The residue was separated and purified by silica gel column chromatography to obtain 5.21 g (80% Yield) of Intermediate 1-3.

### Synthesis of Intermediate 3-1

4.04 g (10.0 mmol) of Intermediate 1-3, 2.83 g (10.0 mmol) of Intermediate 2-2, 0.58 g (0.50 mmol) of Pd(PPh₃)₄ (tetrakis(triphenylphosphine)palladium(0)), and 3.84 g (30.0 mmol) of K₂CO₃ were mixed with 60 mL of a mixed solution of THF/H₂O (2:1 by volume), and stirred at about 75° C. for about 10 hours. The resultant mixture was cooled to room temperature, followed by three extractions with 40 mL of water and 40 mL of diethylether. The organic layer was collected and dried using magnesium sulfate to evaporate the solvent. The residue was separated and purified by silica gel column chromatography to obtain 4.05 g (84% Yield) of Intermediate 3-1.

### Synthesis of Compound 64

2.41 g (5.0 mmol) of Intermediate 3-1, 2.02 g (5.0 mmol) of Intermediate 1-3, 0.29 g (0.25 mmol) of Pd(PPh₃)₄ (tetrakis(triphenylphosphine)palladium(0)), and 2.07 g (15.0 mmol) of K₂CO₃ were mixed together with 50 mL of a mixed solution of THF/H₂O (2:1 by volume), and stirred at about 75° C. for about 10 hours. The resultant mixture was cooled to room temperature, followed by three extractions with 30 mL of water and 30 mL of diethylether. The organic layer was collected and dried using magnesium sulfate to evaporate the solvent. The residue was separated and purified by silica gel column chromatography to obtain 2.82 g (83% Yield) of Compound 64. This compound was identified using MS-FAB and ¹H NMR.

C₅₄H₃₂: (calc.) 680.25. (found) 680.26.

¹H NMR (CDCl₃, 400 MHz) δ (ppm) 8.35-8.33 (m, 4H), 8.29-8.28 (m, 4H), 8.25-8.23 (m, 2H), 8.05 (d, 1H), 8.03 (d, 1H), 8.00-7.97 (m, 3H), 7.95-7.94 (m, 3H), 7.92-7.91 (m, 3H), 7.89-7.88 (m, 1H), 7.77-7.71 (m, 4H), 7.48-7.40 (m, 6H)

### Synthesis Example 25

### Synthesis of Compound 66

2.68 g of Compound 66 (Yield 85%) was synthesized as in the method of synthesizing Compound 64, except that Intermediates 3-2 and 1-4 were used instead of Intermediates 3-1 and 1-3. This compound was identified using MS-FAB and ¹H NMR.

C₄₉H₂₉N: (calc.) 631.23. (found) 631.22.

¹H NMR (CDCl₃, 400 MHz) δ (ppm) 8.98-8.97 (m, 1H), 8.67-8.65 (m, 1H), 8.38-8.37 (m, 4H), 8.30-8.29 (m, 2H), 8.28-8.27 (m, 2H), 8.08-8.04 (m, 2H), 8.02-7.94 (m, 8H), 7.79-7.75 (m, 2H), 7.71-7.68 (m, 2H), 7.46-7.40 (m, 4H), 7.21-7.17 (m, 1H)

### Synthesis Example 26

### Synthesis of Compound 69

3.11 g of Compound 69 (Yield 78%) was synthesized as in the method of synthesizing Compound 64 of Synthesis Example 24, except that Intermediates 3-3 and 1-5 were used instead of Intermediates 3-1 and 1-3. This compound was identified using MS-FAB and ¹H NMR.

C₆₃H₄₀: (calc.) 796.31. (found) 796.30.

¹H NMR (CDCl₃, 400 MHz) δ (ppm) 8.36-8.35 (m, 2H), 8.30-8.29 (m, 2H), 8.26-8.24 (m, 1H), 8.23-8.22 (m, 1H), 8.21-8.20 (m, 1H), 8.15-8.14 (m, 2H), 8.09-8.07 (m, 1H), 8.06-8.05 (m, 1H), 8.05-8.00 (m, 2H), 7.97-7.92 (m, 6H), 7.87-7.84 (m, 1H), 7.3-7.81 (m, 2H), 7.79-7.74 (m, 4H), 7.70-7.65 (m, 3H), 7.63-7.59 (m, 2H), 7.56-7.50 (m, 2H), 7.30 (dd, 1H), 1.57 (s, 6H)

### Synthesis Example 27

### Synthesis of Compound 70

3.11 g of Compound 70 (Yield 78%) was synthesized as in the method of synthesizing Compound 64 of Synthesis Example 24, except that Intermediates 3-4 and 1-6 were used instead of Intermediates 3-1 and 1-3. This compound was identified using MS-FAB and ¹H NMR.

C₅₃H₂₉D: (calc.) 675.30. (found) 675.31.

¹H NMR (CDCl₃, 400 MHz) δ (ppm) 8.29-8.28 (m, 4H), 8.25-8.24 (m, 1H), 8.23-8.22 (m, 1H), 8.16-8.13 (m, 3H), 8.10-8.09 (m, 1H), 8.06-8.05 (m, 1H), 8.05-8.02 m, 1H), 8.00-7.96 (m, 3H), 7.94-7.91 (m, 2H), 7.85-7.84 (m, 1H), 7.82-7.81 (m, 1H), 7.76-7.73 (m, 2H), 7.62-7.59 (m, 1H), 7.47-7.44 (m, 1H), 1.58 (s, 6H)

### INTERMEDIATES

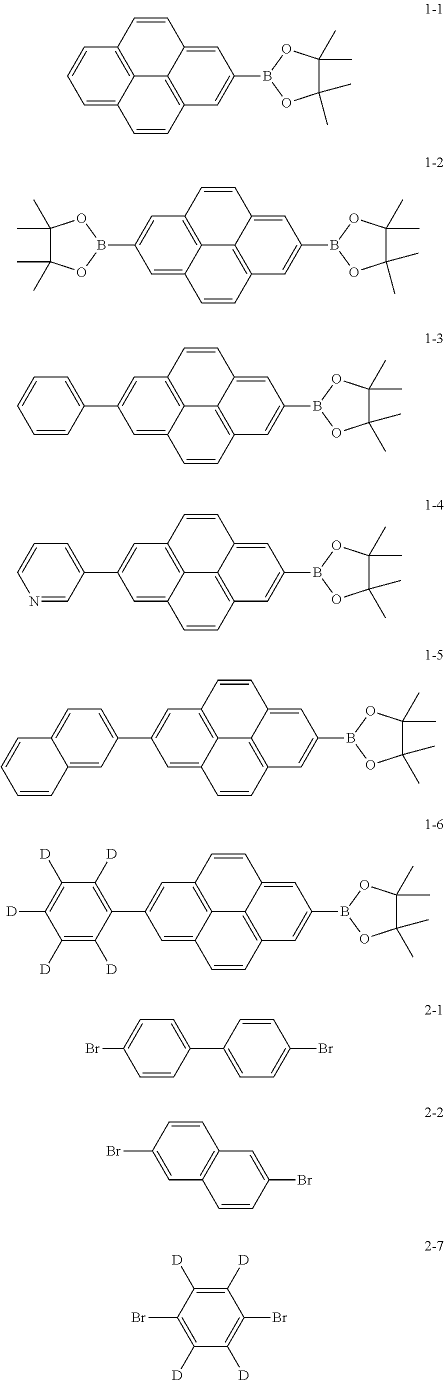

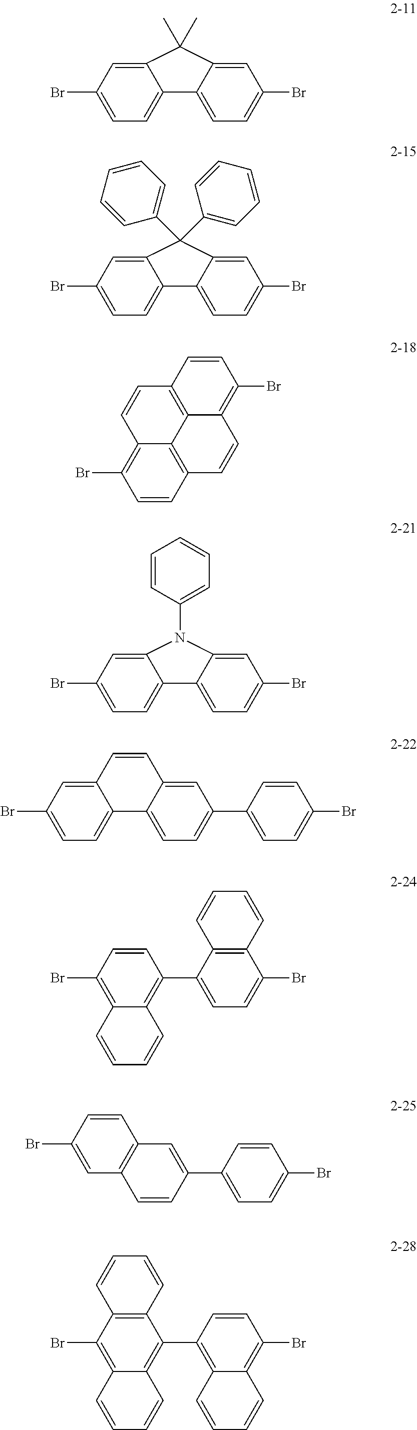

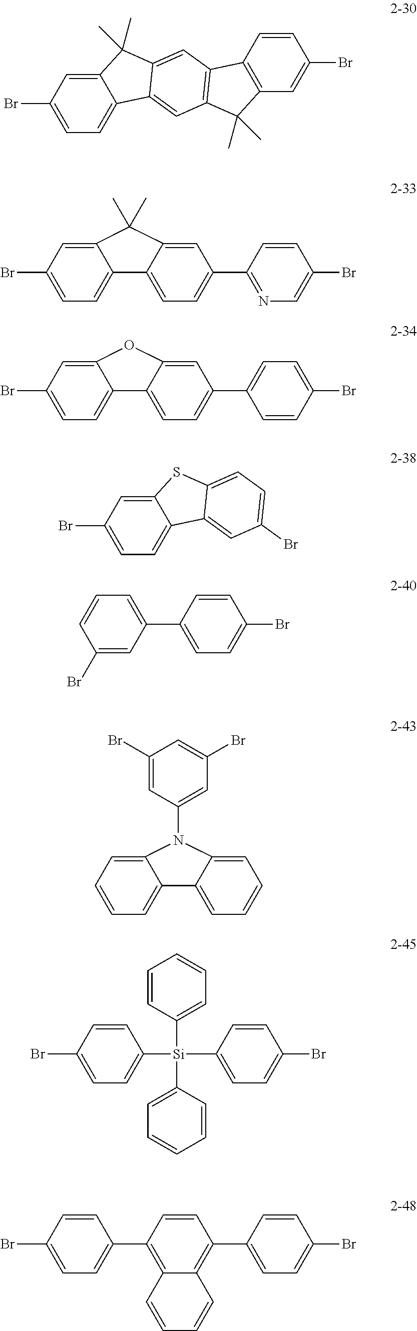

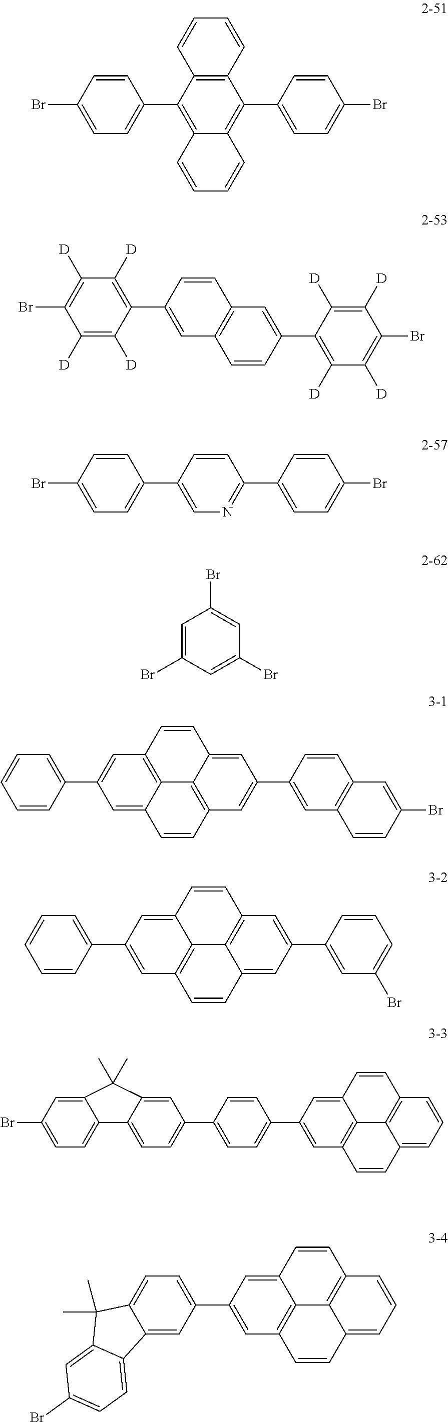

### Example 1

A 15 Ω/cm² (1200 Å) ITO glass substrate (available from Corning Co.) was cut to a size of 50 mm×50 mm×0.7 mm, ultrasonically washed with isopropyl alcohol for 5 minutes and then with pure water for 5 minutes, and washed again with UV ozone for 30 minutes. 2-TNATA was vacuum-deposited on the ITO glass substrate to form an HIL having a thickness of 600 Å on the anode, and then 4,4′-bis[N-(1-naphthyl)-N-phenylamino]biphenyl (NPS) was vacuum-deposited on the HIL to form a HTL having a thickness of 300 Å. 98 wt % of Compound 1 as a blue fluorescent host and 2 wt % of DPAVBi as a blue fluorescent dopant were deposited on the HTL to form an EML having a thickness of 300 Å. Alq₃ was vacuum-deposited on the EML to form an ETL having a thickness of 300 Å. LiF was vacuum-deposited on the ETL to form an EIL having a thickness of 10 Å and Al was vacuum-deposited on the EIL to form a cathode having a thickness of 3000 Å, thereby completing the manufacture of an organic light-emitting device.

### Example 2

An organic light-emitting device was manufactured as in Example 1, except that Compound 11 was used as a host in forming the EML instead of Compound 1.

### Example 3

An organic light-emitting device was manufactured as in Example 1, except that Compound 18 was used as a host in forming the EML instead of Compound 1.

### Example 4

An organic light-emitting device was manufactured as in Example 1, except that Compound 25 was used as a host in forming the EML instead of Compound 1.

### Example 6

An organic light-emitting device was manufactured as in Example 1, except that Compound 28 was used as a host in forming the EML instead of Compound 1.

### Example 6

An organic light-emitting device was manufactured as in Example 1, except that Compound 38 was used as a host in forming the EML instead of Compound 1.

### Example 7

An organic light-emitting device was manufactured as in Example 1 except that Compound 45 was used as a host in forming the EML instead of Compound 1.

### Example 8

An organic light-emitting device was manufactured as in Example 1, except that Compound 53 was used as a host in forming the EML instead of Compound 1.

### Example 9

An organic light-emitting device was manufactured as in Example 1, except that Compound 62 was used as a host in forming the EML instead of Compound 1.

### Example 10

An organic light-emitting device was manufactured as in Example 1, except that Compound 64 was used as a host in forming the EML instead of Compound 1.

### Example 11

An organic light-emitting device was manufactured as in Example 1, except that Compound 66 was used as a host in forming the EML instead of Compound 1.

### Comparative Example 1

An organic light-emitting device was manufactured as in Example 1, except that ADN was used as a host in forming the EML instead of Compound 1.

### Comparative Example 2

An organic light-emitting device was manufactured as in Example 1, except that compound A was used as a host in forming the EML instead of Compound 1.

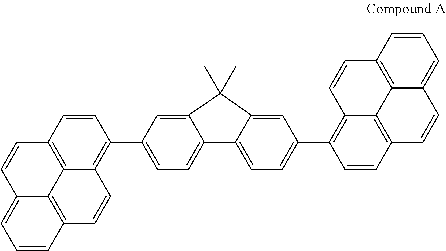 [SMILES: CC1(C)c2cc(-c3ccc4ccc5cccc6ccc3c4c56)ccc2-c2ccc(-c3ccc4ccc5cccc6ccc3c4c56)cc21]

### Comparative Example 3

An organic light-emitting device was manufactured as in Example 1, except that compound B was used as a host in forming the EML instead of Compound 1.

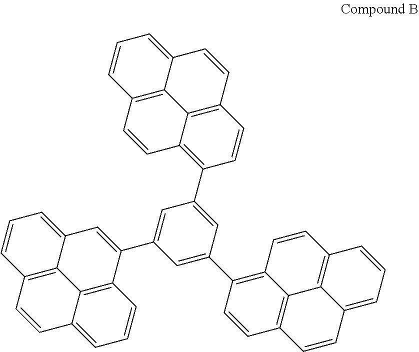 [SMILES: c1cc2ccc3ccc(-c4cc(-c5ccc6ccc7cccc8ccc5c6c78)cc(-c5cc6cccc7ccc8cccc5c8c76)c4)c4ccc(c1)c2c34]

### Evaluation Example

Driving voltages, current densities, luminance, efficiencies, emitting-light colors, and half-life spans of the organic light-emitting devices of Examples 1 to 11 and Comparative Examples 1 to 3 were measured using a PR650 (Spectroscan) Source Measurement Unit (available from Photo Research, Inc.). The analysis results are shown in Table 1 below.

TABLE 1

| | | | Driving | Current | | | | |
|---|---|---|---|---|---|---|---|---|
| | | EML | voltage | density | Luminance | Efficiency | Emission | Halfspan |
| | EML host | dopant | (V) | (mA/cm²) | (cd/m²) | (cd/A) | color | (hr)¹ |
| Example 1 | Compound 1 | DPAVBi | 6.21 | 50 | 3.040 | 6.08 | Blue | 302 |
| Example 2 | Compound 11 | DPAVBi | 6.38 | 50 | 3.060 | 6.12 | Blue | 280 |
| Example 3 | Compound 18 | DPAVBi | 6.29 | 50 | 3.205 | 6.41 | Blue | 322 |
| Example 4 | Compound 25 | DPAVBi | 6.13 | 50 | 3.115 | 6.23 | Blue | 312 |
| Example 5 | Compound 28 | DPAVBi | 6.25 | 50 | 3.135 | 6.27 | Blue | 317 |
| Example 6 | Compound 38 | DPAVBi | 6.38 | 50 | 3.165 | 6.33 | Blue | 289 |
| Example 7 | Compound 45 | DPAVBi | 6.36 | 50 | 3.190 | 6.38 | Blue | 337 |
| Example 8 | Compound 53 | DPAVBi | 6.33 | 50 | 3.130 | 6.26 | Blue | 319 |
| Example 9 | Compound 62 | DPAVBi | 6.42 | 50 | 3.080 | 6.16 | Blue | 295 |
| Example 10 | Compound 64 | DPAVBi | 6.18 | 50 | 3.105 | 6.21 | Blue | 308 |
| Example 11 | Compound 66 | DPAVBi | 6.34 | 50 | 3.185 | 6.37 | Blue | 298 |
| Comp. | ADN | DPAVBi | 7.35 | 50 | 2.065 | 4.13 | Blue | 145 |
| Example 1 | | | | | | | | |
| Comp. | Compound A | DPAVBi | 6.64 | 50 | 2.890 | 5.78 | Blue | 238 |
| Example 2 | | | | | | | | |
| Comp. | Compound B | DPAVBi | 6.68 | 50 | 2.855 | 5.71 | Blue | 231 |
| Example 3 | | | | | | | | |

¹half-lifetime at a current density of 100 mA/cm²

Referring to Table 1, the organic light-emitting devices of Examples 1 to 11 had better driving voltage, luminance, efficiency, and lifetime, as compared with the organic light-emitting devices of Comparative Examples 1 to 3.

As described above, according to one or more embodiments of the present invention, an organic light-emitting device including the condensed cyclic compound of Formula 1 above may have improved performance for example, low driving voltage, good luminance, high efficiency, and long lifetime.

While certain exemplary embodiments have been illustrated and described, those of ordinary skill in the art will understand that certain modification can be made to the described embodiments without departing from the spirit and scope of the present invention, as defined in the following claims. Additionally, descriptions of features or aspects within each embodiment should typically be considered as available for other similar features or aspects in other embodiments.

1. A condensed cyclic compound represented by Formula 1: 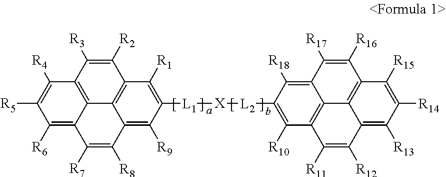
wherein, in Formula 1:
X is one of a silylene group, a substituted or unsubstituted C₆-C₆₀ arylene group, or a substituted or unsubstituted C₃-C₆₀ heteroarylene group;
L₁ and L₂ are each independently one of a substituted or unsubstituted C₆-C₆₀ arylene group, or a substituted or unsubstituted C₃-C₆₀ heteroarylene group;
a is an integer from 0 to 2, wherein when a is 2, the L₁s are identical to or different from each other;
b is an integer from 0 to 2, wherein when b is 2, the L₂s are identical to or different from each other; and
R₁ to R₁₈ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, —Si(R₂₁)(R₂₂)(R₂₃), or —N(R₂₄)(R₂₅), wherein R₂₁ to R₂₅ are each independently a substituted or unsubstituted C₁-C₆₀ alkyl group, a substituted or unsubstituted C₆-C₆₀ aryl group, or a substituted or unsubstituted C₂-C₆₀ heteroaryl group.

2. The condensed cyclic compound of claim 1, wherein X is a silylene group, a substituted or unsubstituted phenylene group, a substituted or unsubstituted naphthylene group, a substituted or unsubstituted phenanthrenylene group, a substituted or unsubstituted phenalenylene group, a substituted or unsubstituted pyrenylene group, a substituted or unsubstituted chrysenylene group, a substituted or unsubstituted anthrylene group, a substituted or unsubstituted pentalenylene group, a substituted or unsubstituted indenylene group, a substituted or unsubstituted azulenylene group, a substituted or unsubstituted heptalenylene group, a substituted or unsubstituted indacenylene group, a substituted or unsubstituted acenaphthylene group, a substituted or unsubstituted fluoranthenylene group, a substituted or unsubstituted triphenylenylene group, a substituted or unsubstituted naphthacenylene group, a substituted or unsubstituted picenylene group, a substituted or unsubstituted perylenylene group, a substituted or unsubstituted pentaphenylene group, a substituted or unsubstituted hexacenylene group, a substituted or unsubstituted fluorenylene group, a substituted or unsubstituted spiro-fluorenylene group, a substituted or unsubstituted carbazolylene group, a substituted or unsubstituted dibenzopuranylene group, a substituted or unsubstituted dibenzothiophenylene group, a substituted or unsubstituted pyridylene group, a substituted or unsubstituted pyridazinylene group, a substituted or unsubstituted triazinylene group, a substituted or unsubstituted pyrrolylene group, a substituted or unsubstituted pyrazolylene group, a substituted or unsubstituted imidazolylene group, a substituted or unsubstituted imidazolinylene group, a substituted or unsubstituted triazolylene group, a substituted or unsubstituted tetrazolylene group, a substituted or unsubstituted imidazopyridinylene group, a substituted or unsubstituted imidazopyrimidinylene group, a substituted or unsubstituted pyrazinylene group, a substituted or unsubstituted pyrimidinylene group, a substituted or unsubstituted indolylene group, a substituted or unsubstituted purinylene group, a substituted or unsubstituted quinolinylene group, a substituted or unsubstituted phthalazinylene group, a substituted or unsubstituted indolizinylene group, a substituted or unsubstituted naphthyridinylene group, a substituted or unsubstituted quinazolinylene group, a substituted or unsubstituted cinnolinylene group, a substituted or unsubstituted indazolylene group, a substituted or unsubstituted phenazinylene group, a substituted or unsubstituted phenanthridinylene group, a substituted or unsubstituted pyranylene group, a substituted or unsubstituted chromenylene group, a substituted or unsubstituted furanylene group, a substituted or unsubstituted benzofuranylene group, a substituted or unsubstituted thiophenylene group, a substituted or unsubstituted benzothiophenylene group, a substituted or unsubstituted isothiazolylene group, a substituted or unsubstituted benzoimidazolylene group, a substituted or unsubstituted isoxazolylene group, or a substituted or unsubstituted oxadiazolylene group.

3. The condensed cyclic compound of claim 1, wherein X is a group represented by one of Formulae 2A to 2P: 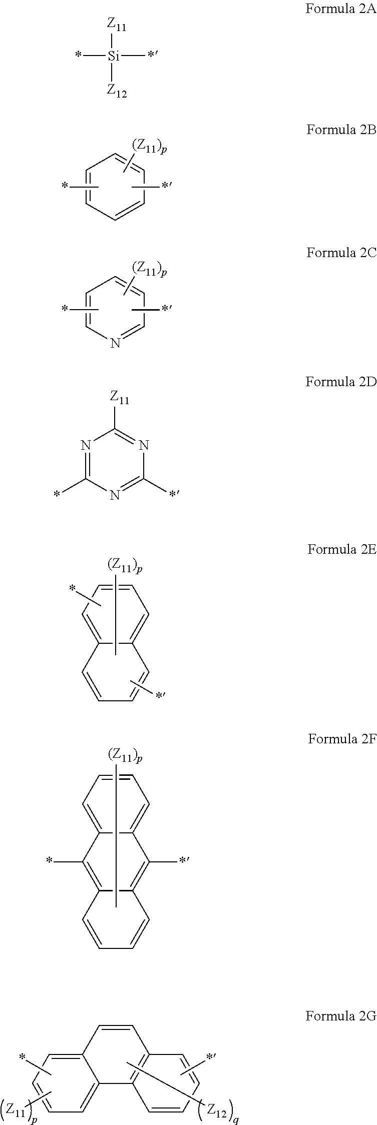 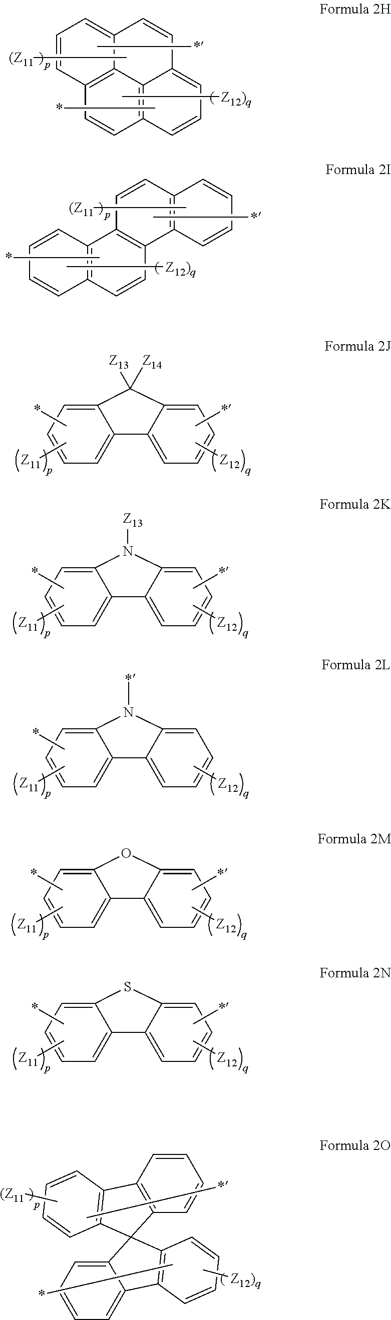 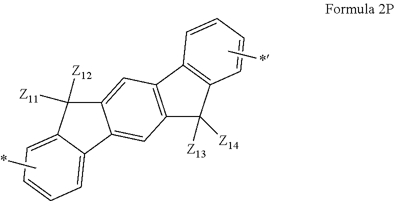
wherein, in Formulae 2A to 2P:
Z₁₁ to Z₁₄ are each independently a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, a C₂-C₂₀ heteroaryl group; a C₁-C₂₀ alkyl group or a C₁-C₂₀ alkoxy group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof; or a C₆-C₂₀ aryl group or a C₂-C₂₀ heteroaryl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, or a C₂-C₂₀ heteroaryl group;
* indicates a binding site with L₁ or a pyrenyl group; and
*′ indicates a binding site with L₂ or a pyrenyl group.

4. The condensed cyclic compound of claim 3, wherein Z₁₁ to Z₁₄ are each independently one of a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a propyl group, a butyl group, a pentyl group, a methoxy group, an ethoxy group, a propoxy group, a butoxy group, a pentoxy group, a phenyl group, a naphthyl group, an anthryl group, a phenanthrenyl group, a pyrenyl group, a fluorenyl group, a pyridinyl group, a pyrimidinyl group, a triazinyl group, a quinolyl group, or a carbazolyl group;
a methyl group, an ethyl group, a propyl group, a butyl group, a pentyl group, a methoxy group, an ethoxy group, a propoxy group, a butoxy group, or a pentoxy group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof; or
a phenyl group, a naphthyl group, an anthryl group, a phenanthrenyl group, a pyrenyl group, a fluorenyl group, a pyridinyl group, a pyrimidinyl group, a triazinyl group, a quinolyl group, or a carbazolyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, or a C₁-C₂₀ alkoxy group.

5. The condensed cyclic compound of claim 1, wherein X is a group represented by one of Formulae 3A to 3AI: 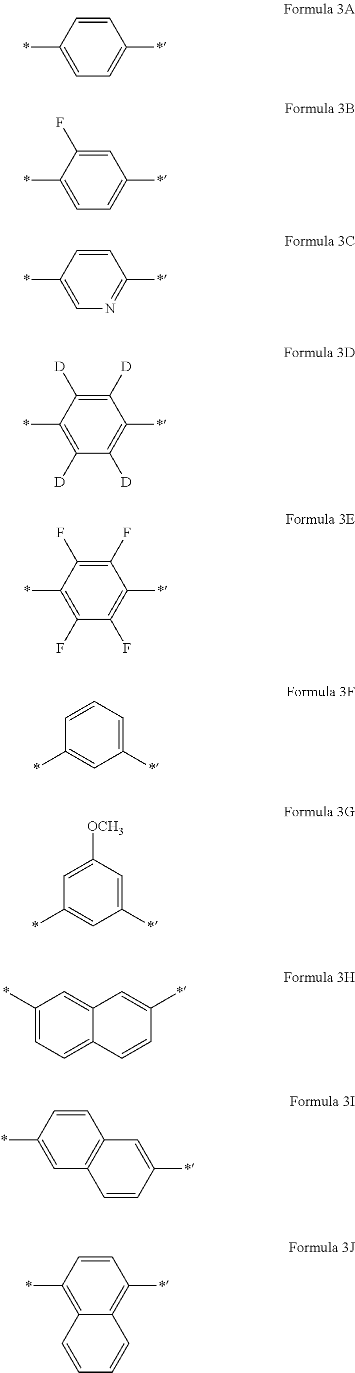 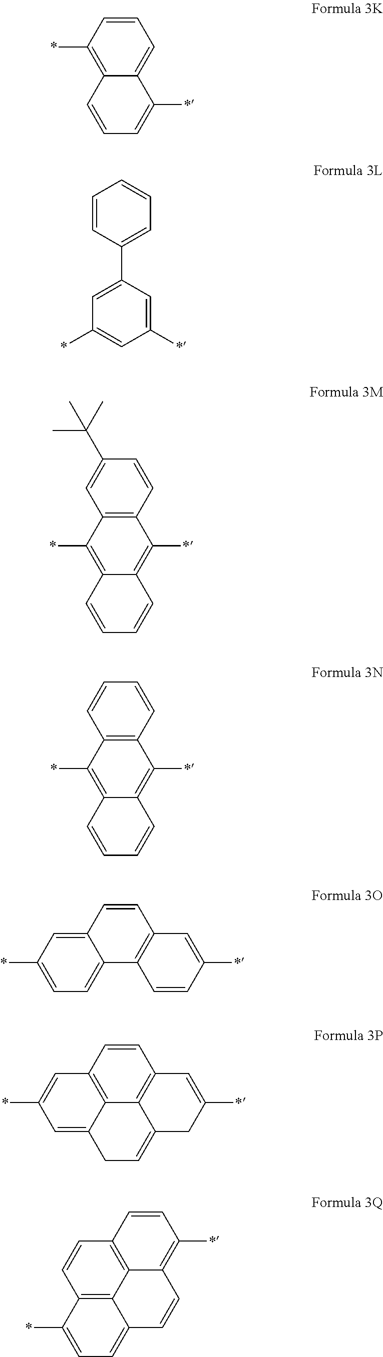 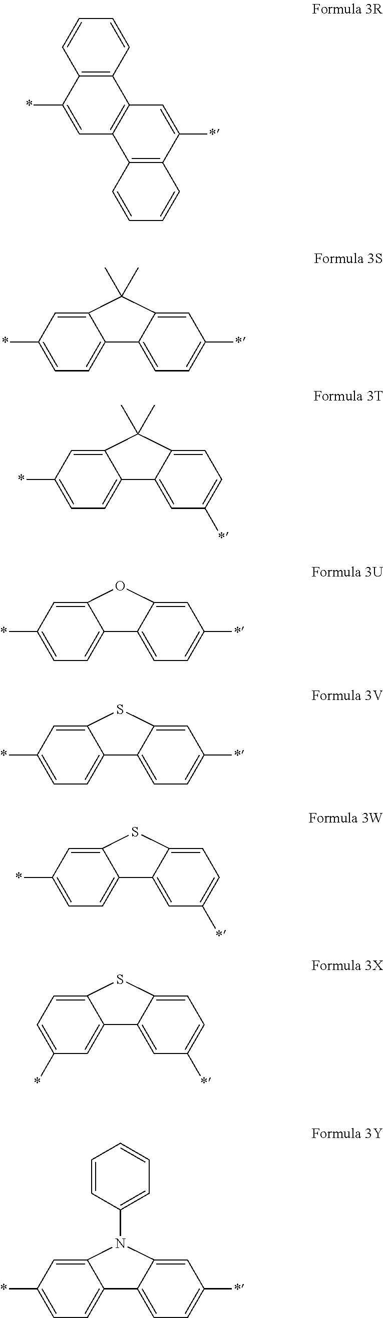 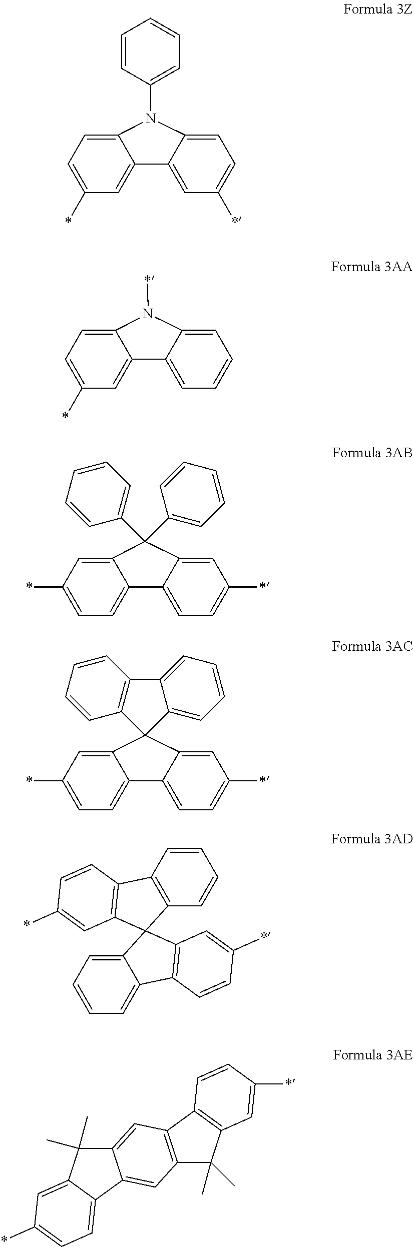 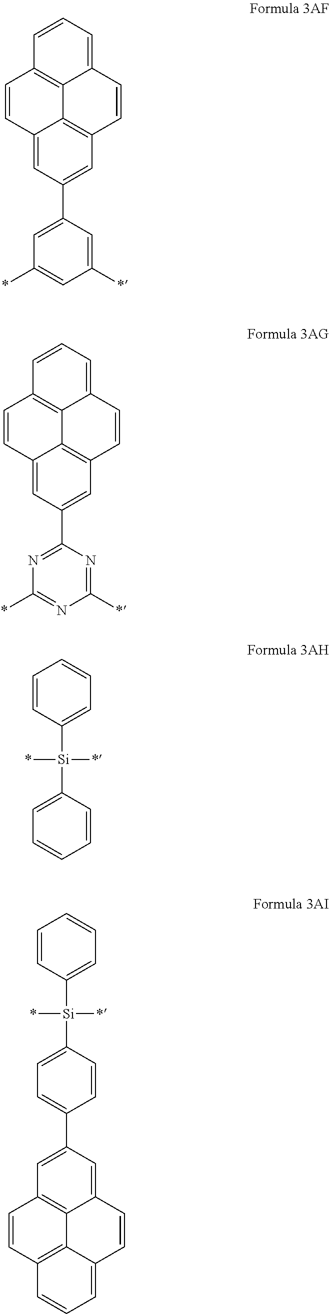
wherein * indicates a binding site with L₁ in Formula 1 or a pyrenyl group; and
*′ indicates a binding site with L₂ in Formula 1 or a pyrenyl group.

6. The condensed cyclic compound of claim 1, wherein L₁ and L₂ are each independently a substituted or unsubstituted phenylene group, a substituted or unsubstituted naphthylene group, a substituted or unsubstituted phenanthrenylene group, a substituted or unsubstituted phenalenylene group, a substituted or unsubstituted pyrenylene group, a substituted or unsubstituted chrysenylene group, a substituted or unsubstituted anthrylene group, a substituted or unsubstituted pentalenylene group, a substituted or unsubstituted indenylene group, a substituted or unsubstituted azulenylene group, a substituted or unsubstituted heptalenylene group, a substituted or unsubstituted indacenylene group, a substituted or unsubstituted acenaphthylene group, a substituted or unsubstituted fluoranthenylene group, a substituted or unsubstituted triphenylenylene group, a substituted or unsubstituted naphthacenylene group, a substituted or unsubstituted picenylene group, a substituted or unsubstituted perylenylene group, a substituted or unsubstituted pentaphenylene group, a substituted or unsubstituted hexacenylene group, a substituted or unsubstituted fluorenylene group, a substituted or unsubstituted carbazolylene group, a substituted or unsubstituted dibenzopuranylene group, a substituted or unsubstituted dibenzothiophenylene group, a substituted or unsubstituted pyridylene group, a substituted or unsubstituted pyridazinylene group, a substituted or unsubstituted triazinylene group, a substituted or unsubstituted pyrrolylene group, a substituted or unsubstituted pyrazolylene group, a substituted or unsubstituted imidazolylene group, a substituted or unsubstituted imidazolinylene group, a substituted or unsubstituted triazolylene group, a substituted or unsubstituted tetrazolylene group, a substituted or unsubstituted imidazopyridinylene group, a substituted or unsubstituted imidazopyrimidinylene group, a substituted or unsubstituted pyrazinylene group, a substituted or unsubstituted pyrimidinylene group, a substituted or unsubstituted indolylene group, a substituted or unsubstituted purinylene group, a substituted or unsubstituted quinolinylene group, a substituted or unsubstituted phthalazinylene group, a substituted or unsubstituted indolizinylene group, a substituted or unsubstituted naphthyridinylene group, a substituted or unsubstituted quinazolinylene group, a substituted or unsubstituted cinnolinylene group, a substituted or unsubstituted indazolylene group, a substituted or unsubstituted phenazinylene group, a substituted or unsubstituted phenanthridinylene group, a substituted or unsubstituted pyranylene group, a substituted or unsubstituted chromenylene group, a substituted or unsubstituted furanylene group, a substituted or unsubstituted benzofuranylene group, a substituted or unsubstituted thiophenylene group, a substituted or unsubstituted benzothiophenylene group, a substituted or unsubstituted isothiazolylene group, a substituted or unsubstituted benzoimidazolylene group, a substituted or unsubstituted isoxazolylene group, or a substituted or unsubstituted oxadiazolylene group.

7. The condensed cyclic compound of claim 1, wherein L₁ and L₂ are each independently a group represented by one of Formulae 4A to 4C: 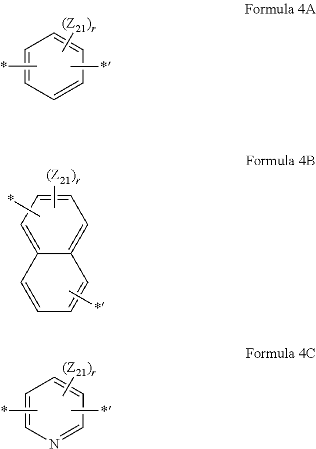
wherein, in Formulae 4A to 4C,
Z₂₁ is one of a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, a C₂-C₂₀ heteroaryl group; a C₁-C₂₀ alkyl group or a C₁-C₂₀ alkoxy group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof; a C₆-C₂₀ aryl group or a C₂-C₂₀ heteroaryl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₂₀ aryl group, or a C₂-C₂₀ heteroaryl group; and
* and *′ indicate binding sites.

8. The condensed cyclic compound of claim 1, wherein L₁ and L₂ are each independently a group represented by one of Formulae 5A to 5G: 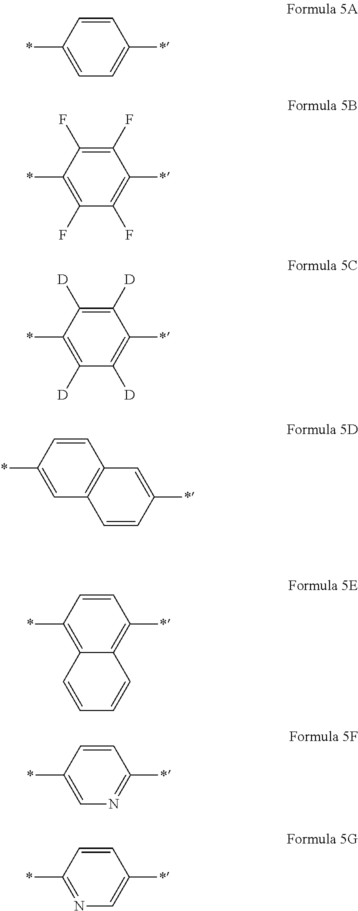
wherein, in Formulae 5A to 5G,
* indicates a binding site with a pyrenyl group; and
*′ indicates a binding site with X.

9. The condensed cyclic compound of claim 1, wherein R₁ to R₁₈ are each independently one of a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, or a C₁-C₁₀ alkoxy group, a phenyl group, a naphthyl group, an anthryl group, a fluorenyl group, a dibenzofuranyl group, or a dibenzothiophenyl group; or
a C₁-C₁₀ alkyl group, a C₁-C₁₀ alkoxy group, a phenyl group, a naphthyl group, an anthryl group, a fluorenyl group, a dibenzofuranyl group, or a dibenzothiophenyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, or a phosphoric acid group or a salt thereof.

10. The condensed cyclic compound of claim 1, wherein R₁ to R₁₈ are each independently one of a hydrogen atom, a deuterium atom, a halogen atom, a methyl group, an ethyl group, a propyl group, a butyl group, a methoxy group, an ethoxy group, a propoxy group, a butoxy group, or a pentoxy group.

11. The condensed cyclic compound of claim 1, wherein a=0 and b=0; or a=0 and b=1; or a=1 and b=0; or a=1 and b=1.

12. The condensed cyclic compound of claim 11, wherein a=0 and b=1; or a=1 and b=0; or a=1 and b=1.

13. The condensed cyclic compound of claim 1, wherein the condensed cyclic compound is a compound represented by one of Formulae 1 to 71:

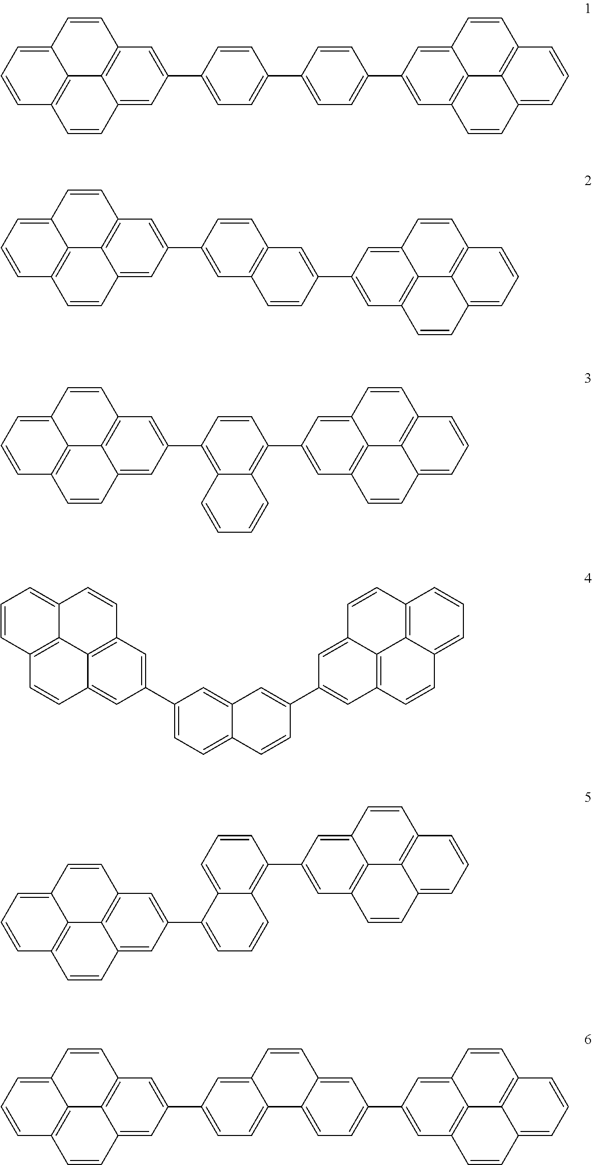

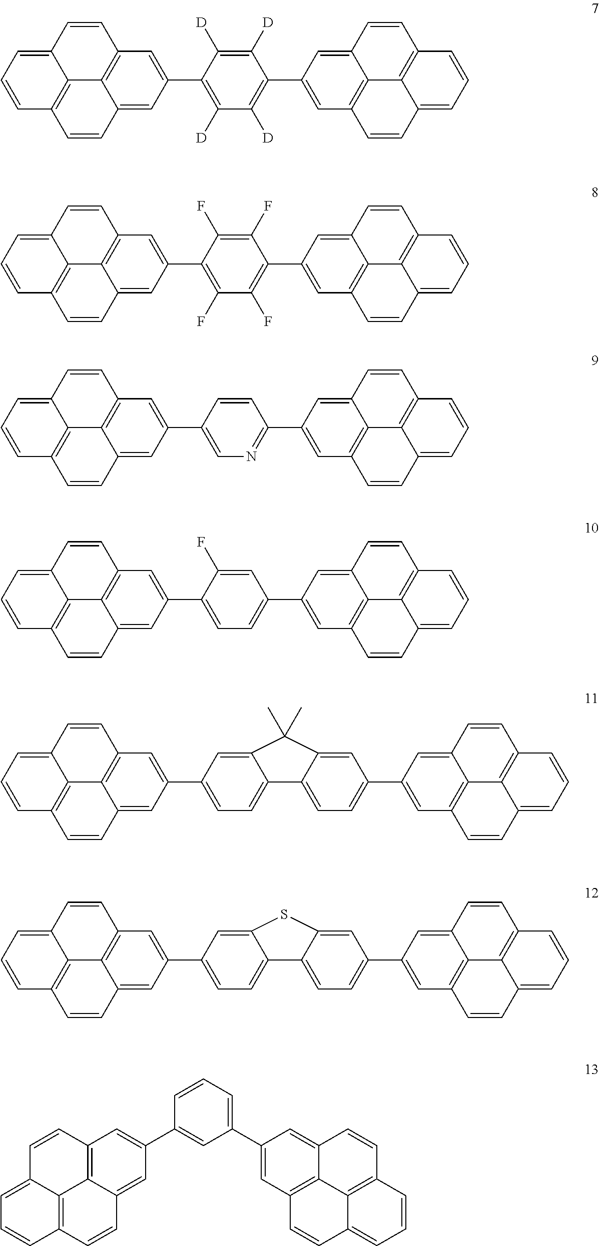

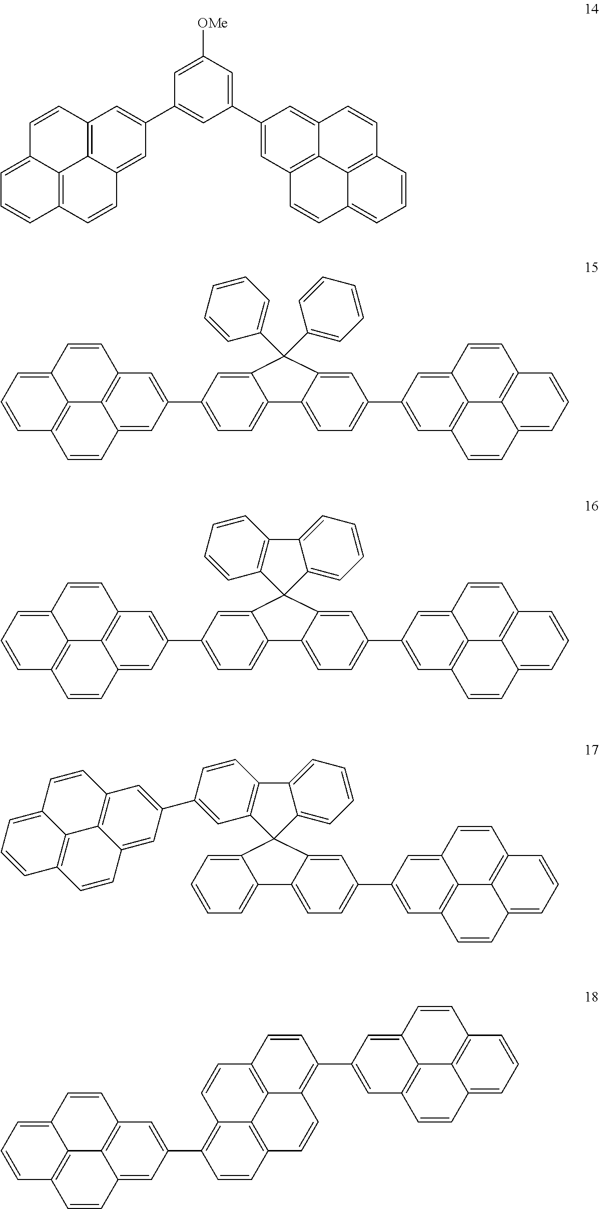

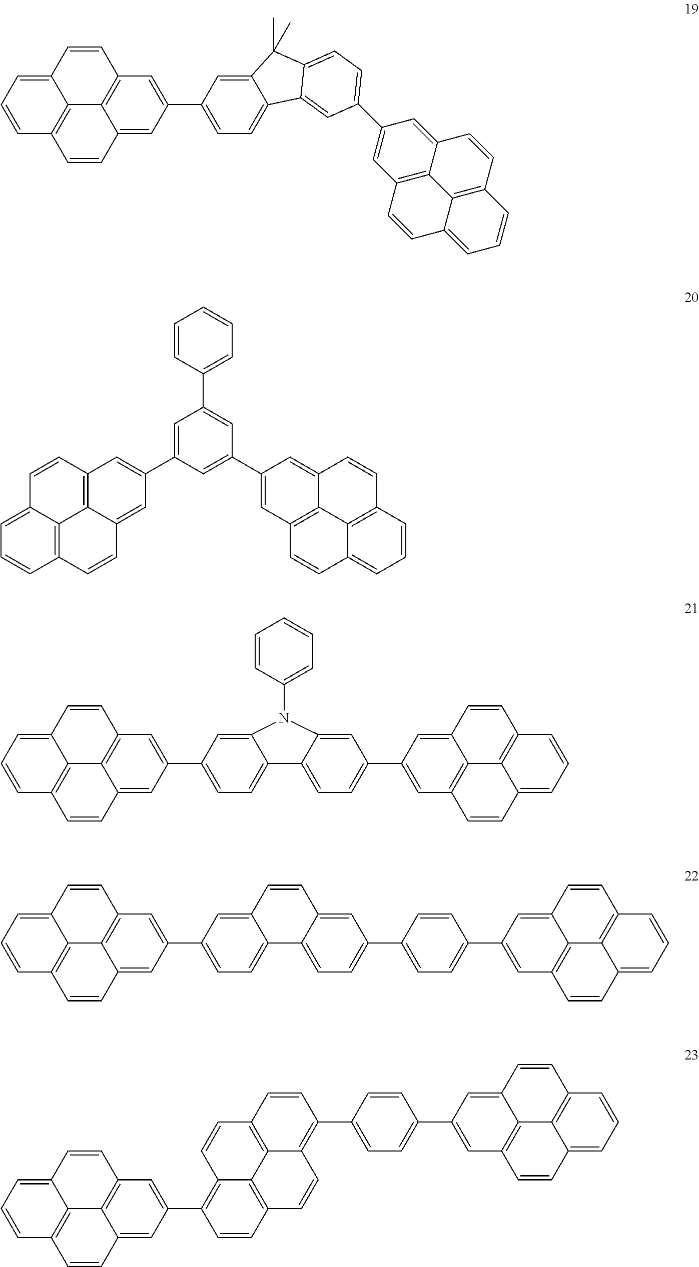

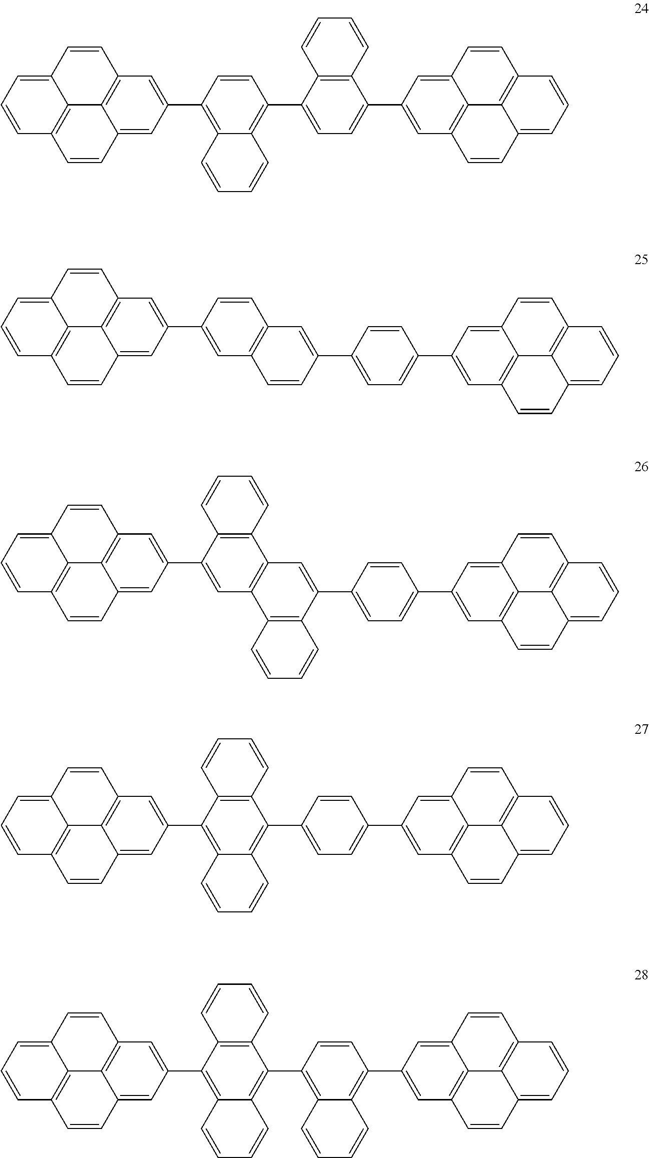

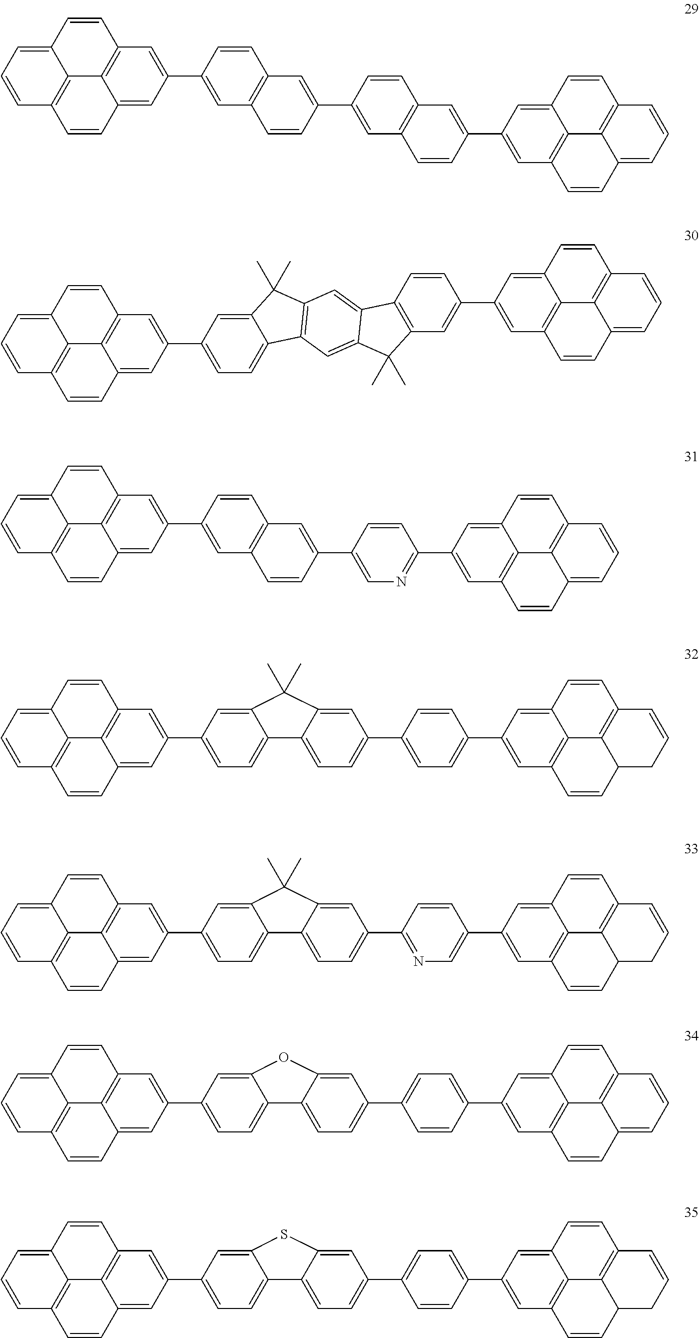

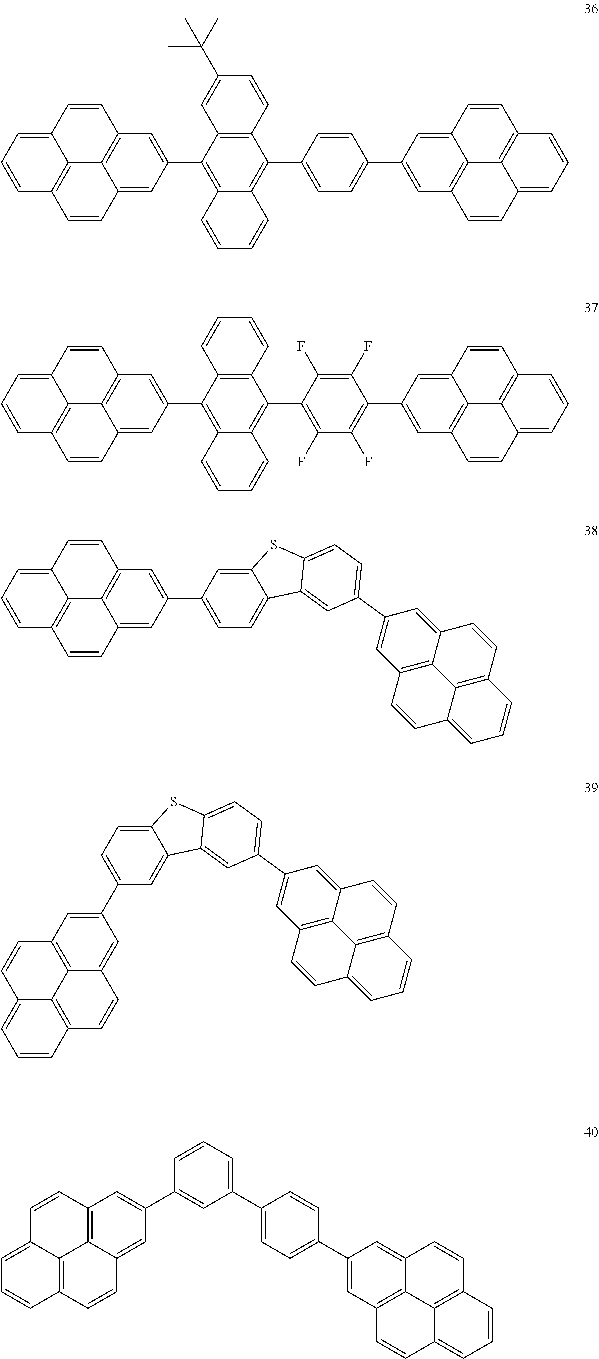

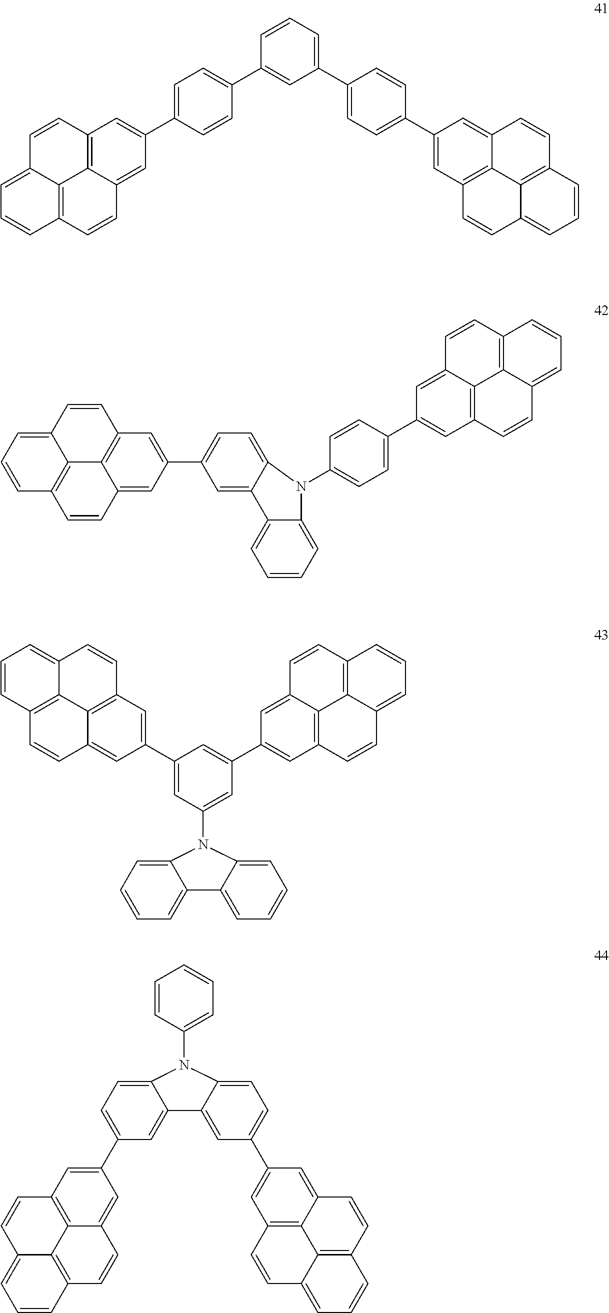

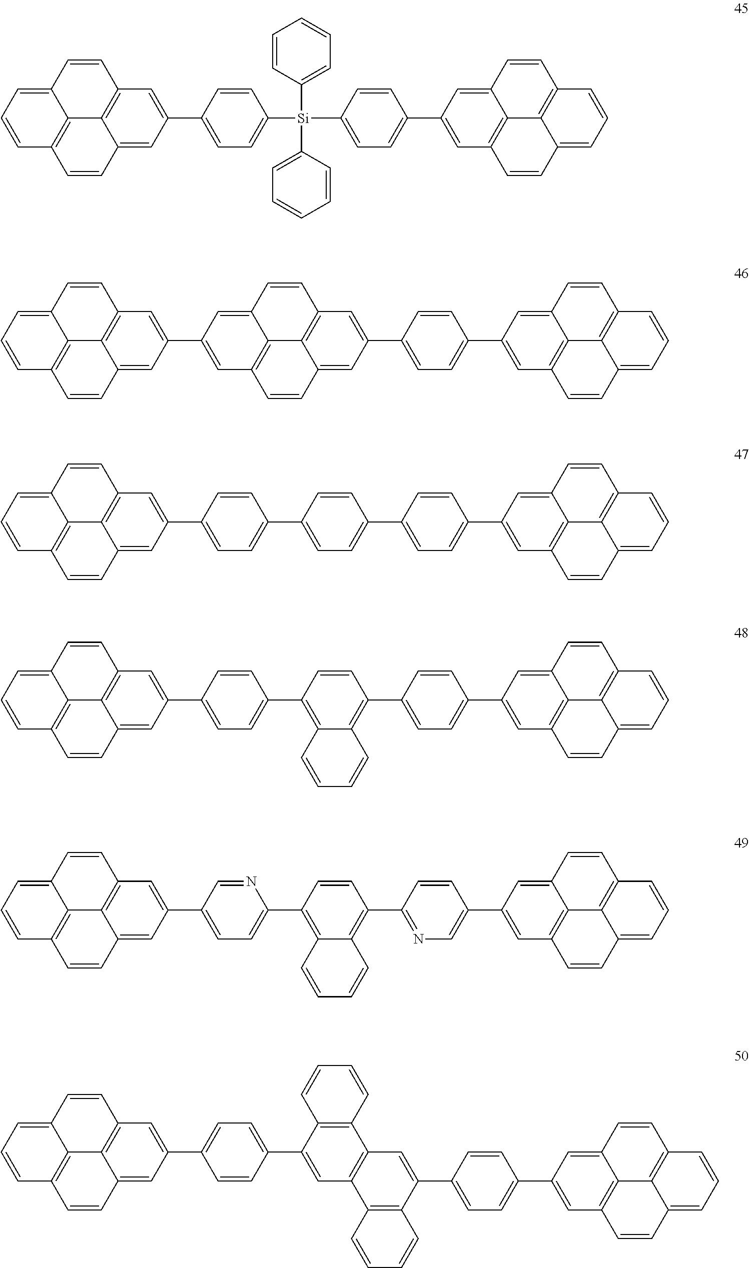

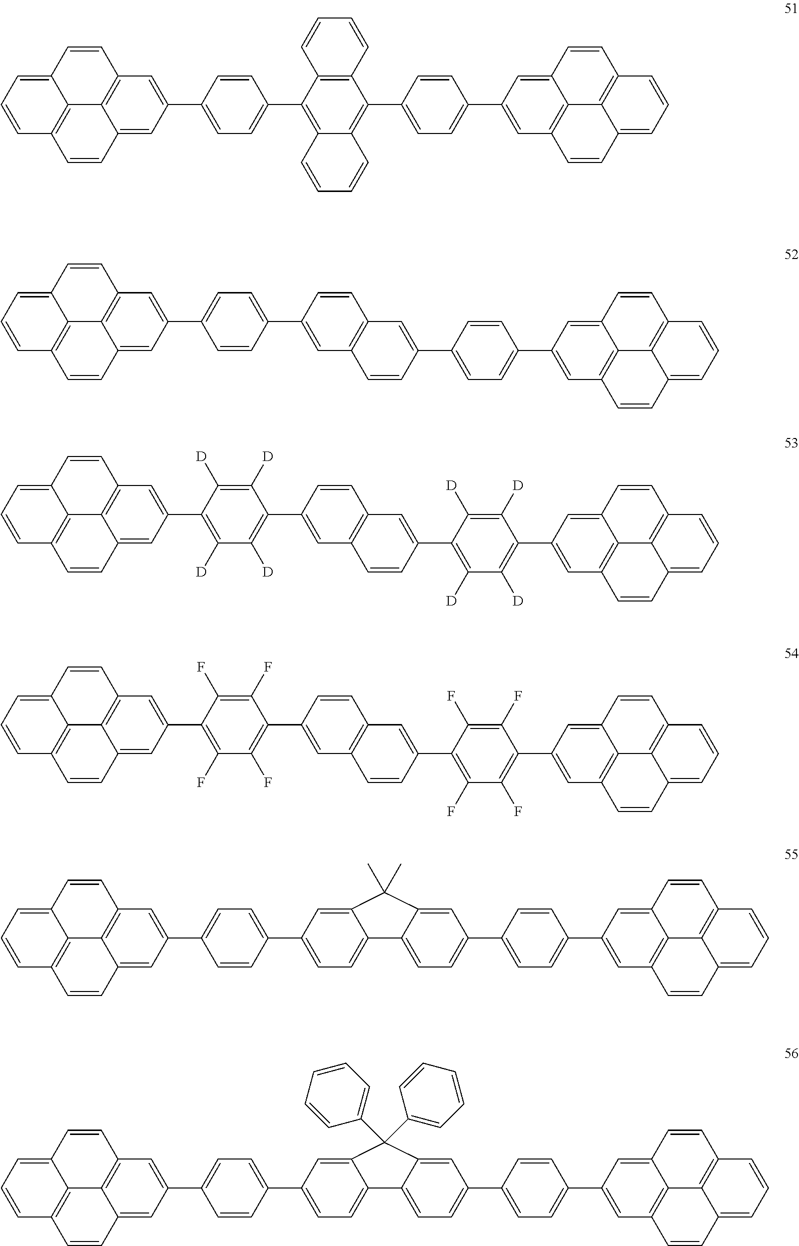

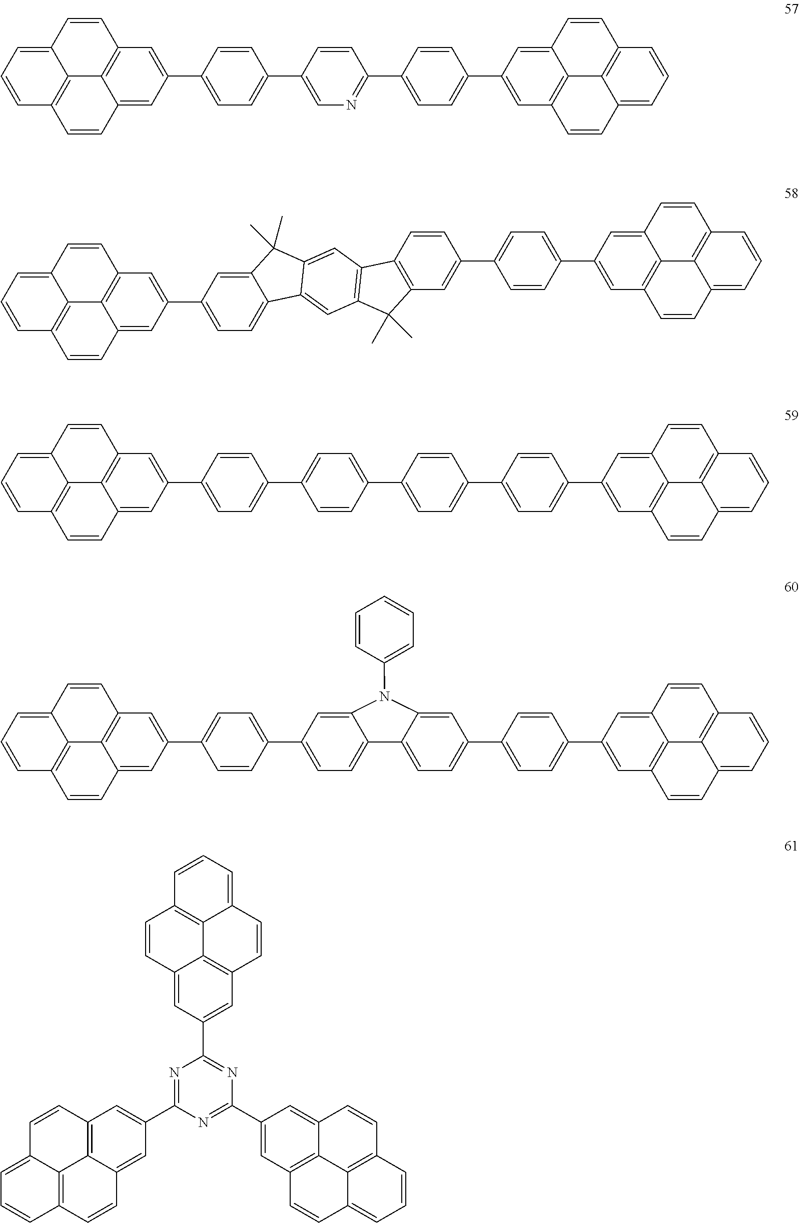

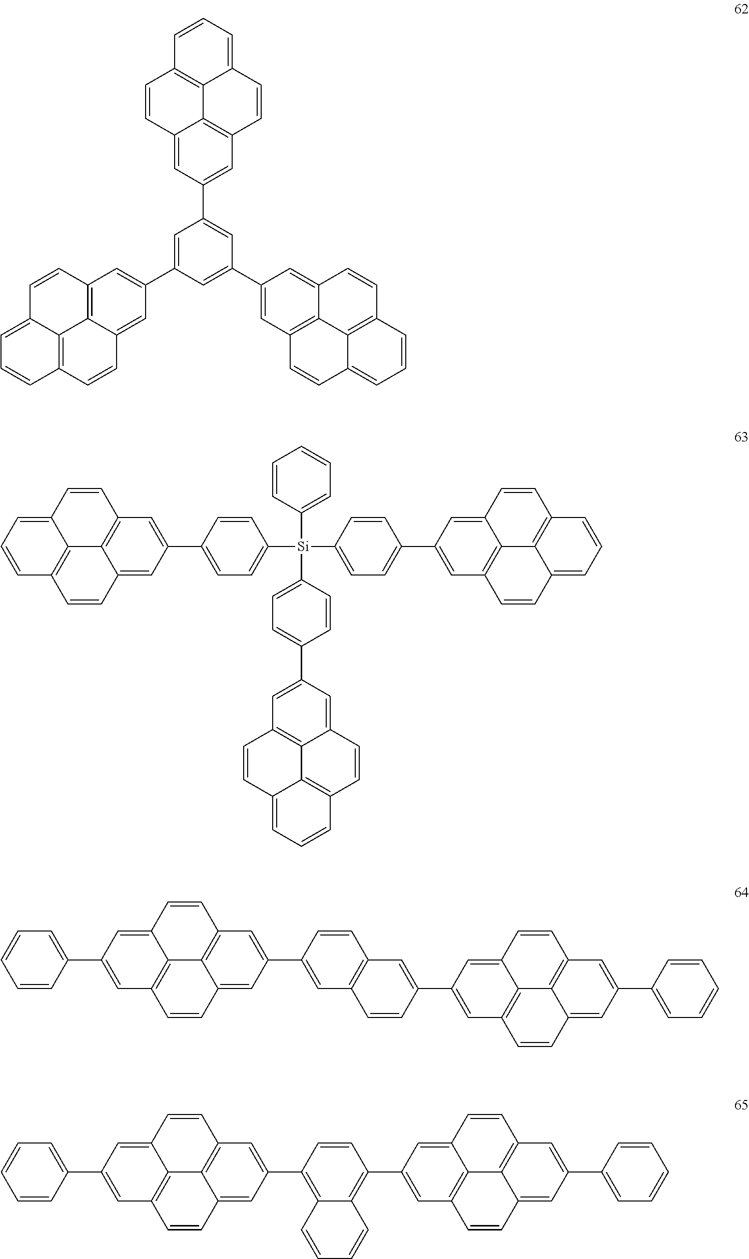

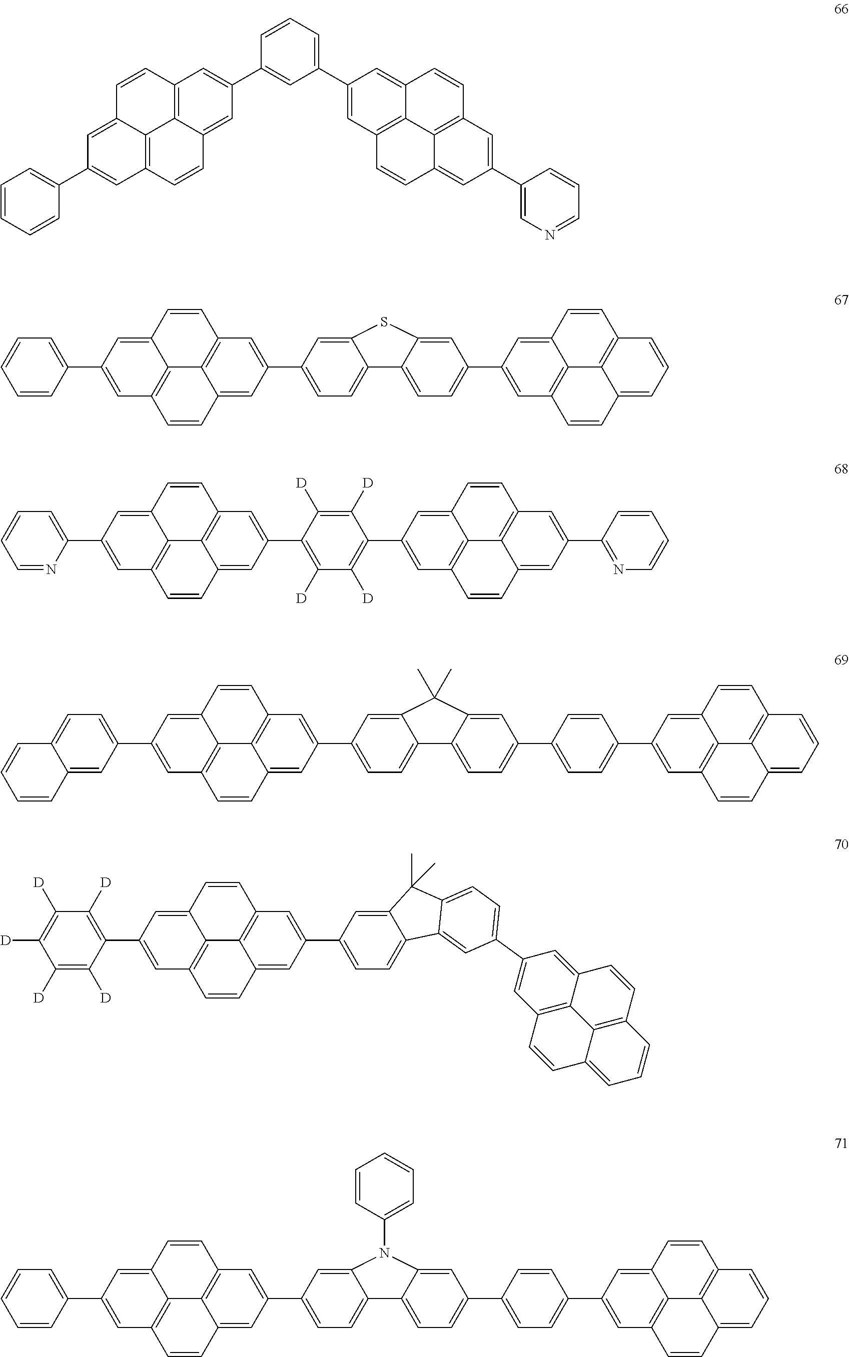

14. The condensed cyclic compound of claim 13, wherein the condensed cyclic compound is a compound represented by one of Formulae 1, 11, 18, 25, 28, 38, 45, 53, 62, 64, and 66:

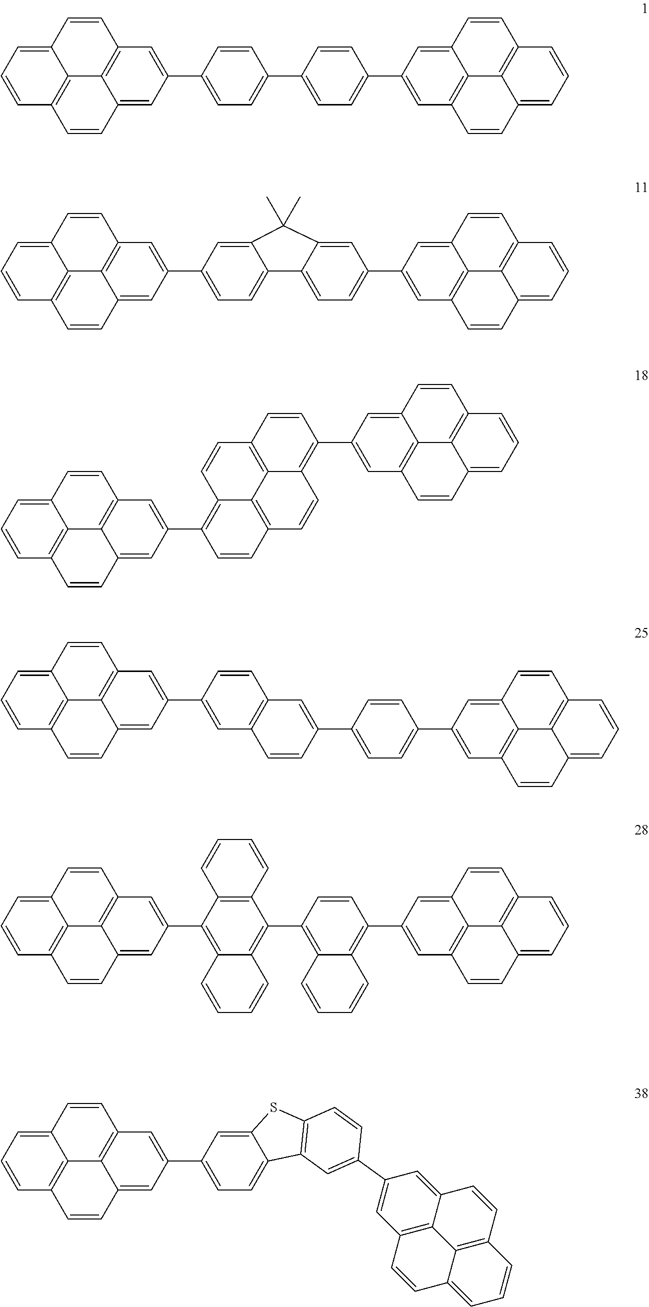

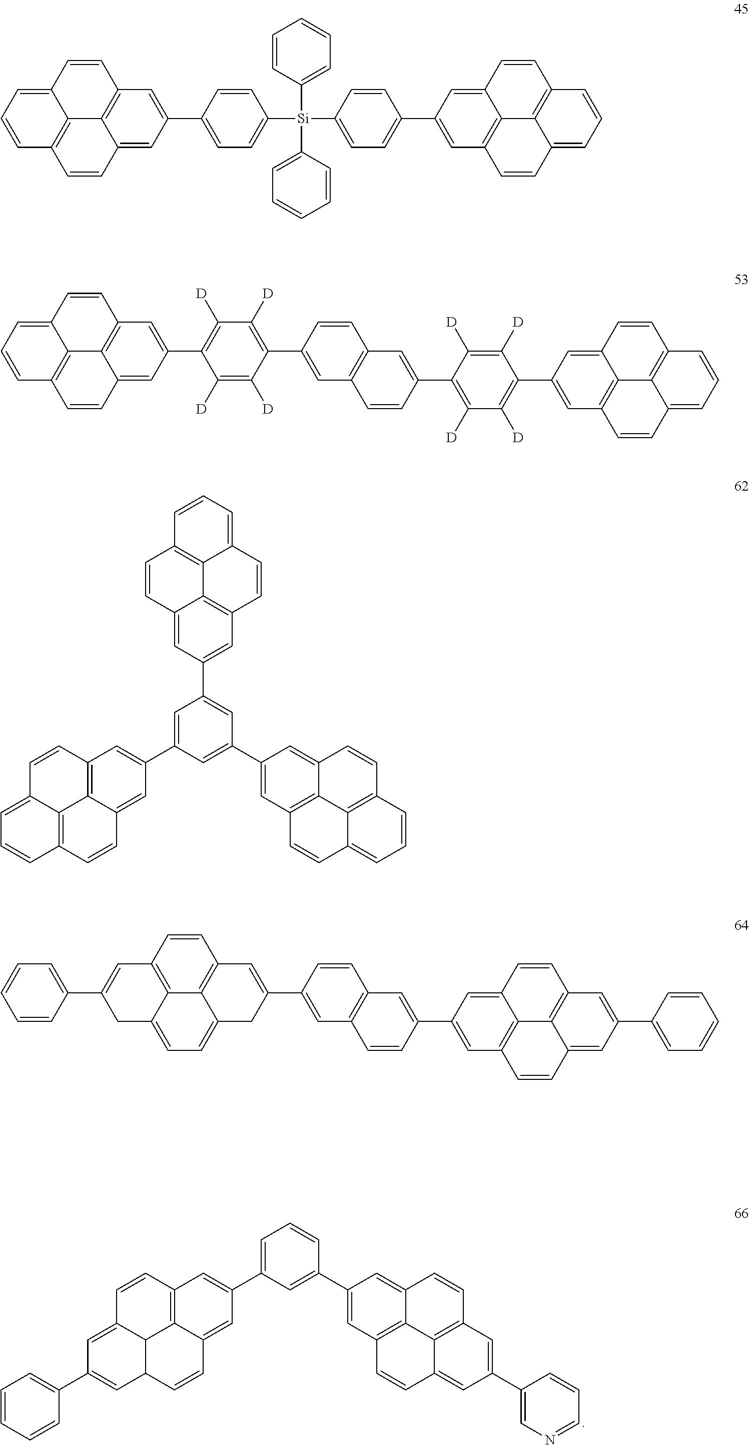

15. An organic light-emitting device comprising:
a substrate;
a first electrode on the substrate;
a second electrode facing the first electrode; and
an organic layer between the first electrode and the second electrode,
wherein the organic layer comprises at least one layer comprising the condensed cyclic compound of claim 1.

16. The organic light-emitting device of claim 15, wherein the organic layer comprises at least one of a hole injection layer, a hole transport layer, a hole injection and transport layer having both hole injection and hole transport capabilities, an emission layer, an electron injection layer, an electron transport layer, and an electron injection and transport layer having both electron injection and electron transport capabilities.

17. The organic light-emitting device of claim 16, wherein the organic layer comprises:
at least one of the emission layer, the electron injection layer, the electron transport layer, and the electron injection and transport layer, wherein at least one of the emission layer, the electron injection layer, the electron transport layer, and the electron injection and transport layer comprises the condensed cyclic compound.

18. The organic light-emitting device of claim 16, wherein the organic layer comprises the emission layer, and the emission layer comprises the condensed cyclic compound.

19. The organic light-emitting device of claim 18, wherein the condensed cyclic compound serves as a host.

20. The organic light-emitting device of claim 19, wherein the emission layer further comprises a fluorescent dopant.
